(19) United States
(12) Patent Application Publication
(10) Pub. No.: US 2025/0268090 A1
(43) Pub. Date: Aug. 21, 2025

(54) Display Device, Display Module, and Electronic Device

(71) Applicant: Semiconductor Energy Laboratory Co., Ltd., Kanagawa-ken (JP)

(72) Inventors: Toshiyuki ISA, Atsugi, Kanagawa (JP); Nozomu SUGISAWA, Isehara, Kanagawa (JP); Daiki NAKAMURA, Atsugi, Kanagawa (JP); Akihiro CHIDA, Isehara, Kanagawa (JP); Yasumasa YAMANE, Atsugi, Kanagawa (JP); Daigo SHIMADA, Atsugi, Kanagawa (JP); Hitomi SATO, Isehara, Kanagawa (JP)

(73) Assignee: Semiconductor Energy Laboratory Co., Ltd., Kanagawa-ken (JP)

(21) Appl. No.: 18/859,393

(22) PCT Filed: Apr. 17, 2023
(86) PCT No.: PCT/IB2023/053900

§ 371 Date: Oct. 23, 2024

(30) Foreign Application Priority Data
Apr. 29, 2022 (JP) 2022-075575
Nov. 30, 2022 (JP) 2022-191007

(51) Int. Cl. H10K 59/95; H10K 59/131; H10K 59/80

(52) U.S. Cl. CPC H10K 59/95; H10K 59/131; H10K 59/878

(57) ABSTRACT

A novel display device that is highly convenient, useful, or reliable is provided. The display device includes first to fourth light-emitting devices, and the first light-emitting device contains a light-emitting material and includes a first layer sandwiched between a first electrode and a second electrode and a second layer sandwiched between the first layer and the first electrode. The second light-emitting device contains a light-emitting material and includes a third layer sandwiched between a third electrode and a fourth electrode and a fourth layer sandwiched between the third layer and the third electrode, a first gap is positioned between the third electrode and the first electrode, and the fourth layer is continuous with the second layer over the first gap. The third light-emitting device contains a light-emitting material and includes a fifth layer sandwiched between a fifth electrode and a sixth electrode and a sixth layer sandwiched between the fifth layer and the fifth electrode, a second gap is positioned between the fifth electrode and the third electrode, and a third gap overlapping with the second gap is positioned between the sixth layer and the fourth layer.

### TECHNICAL FIELD

One embodiment of the present invention relates to a display device, a display module, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, specific examples of the technical field of one embodiment of the present invention disclosed in this specification include a semiconductor device, a display device, a light-emitting apparatus, a power storage device, a memory device, a method for driving any of them, and a method for manufacturing any of them.

### BACKGROUND ART

In recent years, higher-resolution display panels have been required. Examples of devices that require high-resolution display panels include a smartphone, a tablet terminal, and a laptop computer. Furthermore, higher resolution has been required for a stationary display device such as a television device or a monitor device along with an increase in definition. An example of a device required to have the highest resolution is a device for virtual reality (VR) or augmented reality (AR).

Typical examples of a display device that can be used for a display panel include a liquid crystal display device, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure in which a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

Patent Document 2 discloses a display device for VR using an organic EL device.

### REFERENCES

### Patent Documents

[Patent Document 1] Japanese Published Patent Application No. 2002-324673

[Patent Document 2] PCT International Publication No. 2018/087625

### SUMMARY OF THE INVENTION

### Problems to be Solved by the Invention

An object of one embodiment of the present invention is to provide a novel display device that is highly convenient, useful, or reliable. Another object is to provide a novel display module that is highly convenient, useful, or reliable. Another object is to provide a novel electronic device that is highly convenient, useful, or reliable. Another object is to provide a novel display device, a novel display module, a novel electronic device, or a novel semiconductor device.

Note that the description of these objects does not preclude the existence of other objects. One embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

(1) One embodiment of the present invention is a display device including a first light-emitting device, a second light-emitting device, a third light-emitting device, and a fourth light-emitting device.

The first light-emitting device includes a first electrode, a first layer, a second layer, and a second electrode. The first layer is sandwiched between the first electrode and the second electrode, and the first layer contains a first light-emitting material. The second layer is sandwiched between the first layer and the first electrode.

The second light-emitting device includes a third electrode, a third layer, a fourth layer, and a fourth electrode. The third electrode is adjacent to the first electrode, a first gap is positioned between the third electrode and the first electrode, the third layer is sandwiched between the third electrode and the fourth electrode, and the third layer contains a second light-emitting material. The fourth layer is sandwiched between the third layer and the third electrode, and the fourth layer is continuous with the second layer over the first gap.

The third light-emitting device includes a fifth electrode, a fifth layer, a sixth layer, and a sixth electrode. The fifth electrode is adjacent to the third electrode, a second gap is positioned between the fifth electrode and the third electrode, the fifth layer is sandwiched between the fifth electrode and the sixth electrode, and the fifth layer contains a third light-emitting material. The sixth layer is sandwiched between the fifth layer and the fifth electrode, a third gap is positioned between the sixth layer and the fourth layer, and the third gap overlaps with the second gap.

The fourth light-emitting device includes a seventh electrode, a seventh layer, an eighth layer, and an eighth electrode. The seventh electrode is adjacent to the fifth electrode, a fourth gap is positioned between the seventh electrode and the fifth electrode, the seventh layer is sandwiched between the seventh electrode and the eighth electrode, and the seventh layer contains a fourth light-emitting material. The eighth layer is sandwiched between the seventh layer and the seventh electrode, a fifth gap is positioned between the eighth layer and the sixth layer, and the fifth gap overlaps with the fourth gap.

(2) Another embodiment of the present invention is the above display device in which the first light-emitting device has a current efficiency higher than or equal to 1 cd/A and lower than 10 cd/A, the second light-emitting device has a current efficiency higher than or equal to 1 cd/A and lower than 10 cd/A, the third light-emitting device has a current efficiency higher than or equal to 10 cd/A and lower than 100 cd/A, and the fourth light-emitting device has a current efficiency higher than or equal to 10 cd/A and lower than 100 cd/A.

(3) Another embodiment of the present invention is the above display device in which the first light-emitting device has a light emission start voltage in a range higher than or equal to 3 V and lower than 4 V, the second light-emitting device has a light emission start voltage in a range higher than or equal to 3 V and lower than 4 V, the third light-emitting device has a light emission start voltage in a range higher than or equal to 2 V and lower than 3 V, and the fourth light-emitting device has a light emission start voltage in a range higher than or equal to 2 V and lower than 3 V.

(4) Another embodiment of the present invention is the above display device in which the first layer contains the first light-emitting material emitting fluorescent light, the third layer contains the second light-emitting material emitting fluorescent light, the fifth layer contains the third light-emitting material emitting phosphorescent light, and the seventh layer contains the fourth light-emitting material emitting phosphorescent light.

(5) Another embodiment of the present invention is the above display device in which the first light-emitting material has an emission spectrum having a maximum peak in a range greater than or equal to 380 nm and less than or equal to 480 nm, the second light-emitting material has an emission spectrum having a maximum peak in a range greater than or equal to 380 nm and less than or equal to 480 nm, the third light-emitting material has an emission spectrum having a maximum peak in a range greater than or equal to 500 nm and less than or equal to 550 nm, and the fourth light-emitting material has an emission spectrum having a maximum peak in a range greater than or equal to 600 nm and less than or equal to 780 nm.

(6) Another embodiment of the present invention is the above display device in which the first gap, the second gap, and the fourth gap are each larger than or equal to 0.1 μm and smaller than or equal to 15 μm.

Thus, occurrence of a phenomenon in which, when one of the first light-emitting device, the second light-emitting device, the third light-emitting device, and the fourth light-emitting device emits light, the others emit light at unintended luminance can be inhibited. The first light-emitting device, the second light-emitting device, the third light-emitting device, and the fourth light-emitting device can independently emit light. Occurrence of a crosstalk phenomenon between the light-emitting devices can be inhibited. The color gamut that can be expressed by the display device can be widened. The resolution of the display device can be increased. The aperture ratio of a pixel of the display device can be increased. A film separation phenomenon during the fabrication process of the display device can be prevented. For example, a phenomenon in which the first layer or the third layer is separated during the fabrication process of the display device can be prevented. As a result, a novel display device that is highly convenient, useful, or reliable can be provided.

(7) Another embodiment of the present invention is the above display device including a first insulating film, a conductive film, and a second insulating film.

The first insulating film overlaps with the conductive film, and the first electrode, the third electrode, and the fifth electrode are sandwiched between the first insulating film and the conductive film. The conductive film includes the second electrode, the fourth electrode, and the sixth electrode.

The second insulating film is sandwiched between the conductive film and the first insulating film, the second insulating film overlaps with the first gap, the second insulating film overlaps with the second gap, and the second insulating film fills the third gap.

The second insulating film has a first opening portion, a second opening portion, and a third opening portion. The first opening portion overlaps with the first electrode, the second opening portion overlaps with the third electrode, and the third opening portion overlaps with the fifth electrode.

Accordingly, the third gap can be filled with the second insulating film. Moreover, a step due to the third gap can be reduced so as to be close to a flat plane. A phenomenon in which a cut or a split due to the step is generated in a conductive film 552 can be inhibited. As a result, a novel display device that is highly convenient, useful, or reliable can be provided.

(8) Another embodiment of the present invention is a display module including any one of the above-described display devices and at least one of a connector and an integrated circuit.

(9) Another embodiment of the present invention is an electronic device including any one of the above-described display devices and at least one of a battery, a camera, a speaker, and a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

According to one embodiment of the present invention, a novel display device that is highly convenient, useful, or reliable can be provided. Another embodiment of the present invention can provide a novel display module that is highly convenient, useful, or reliable. Another embodiment of the present invention can provide a novel electronic device that is highly convenient, useful, or reliable. A novel display device can be provided. A novel display module can be provided. A novel electronic device can be provided.

Note that the description of these effects does not preclude the existence of other effects. One embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1C are diagrams illustrating a structure of a display device of an embodiment.

FIG. 2A and FIG. 2B are diagrams illustrating structures of a display device of an embodiment.

FIG. 3A to FIG. 3D are diagrams illustrating structures of a display device of an embodiment.

FIG. 4A and FIG. 4B are diagrams showing a structure of a light-emitting device of an embodiment.

FIG. 5A and FIG. 5B are diagrams illustrating structures of a light-emitting device of an embodiment.

FIG. 6A to FIG. 6C are diagrams illustrating a structure of a display device of an embodiment.

FIG. 7 is a diagram illustrating a structure of a display device of an embodiment.

FIG. 8 is a diagram illustrating a structure of a display module of an embodiment.

FIG. 9A and FIG. 9B are diagrams each illustrating a structure of a display device of an embodiment.

FIG. 10 is a diagram illustrating a structure of a display device of an embodiment.

FIG. 11 is a diagram illustrating a structure of a display device of an embodiment.

FIG. 12 is a diagram illustrating a structure of a display device of an embodiment.

FIG. 13 is a diagram illustrating a structure of a display device of an embodiment.

FIG. 14 is a diagram illustrating a structure of a display device of an embodiment.

FIG. 15 is a diagram illustrating a structure of a display module of an embodiment.

FIG. 16A to FIG. 16C are diagrams illustrating structures of a display device of an embodiment.

FIG. 17 is a diagram illustrating a structure of a display device of an embodiment.

FIG. 18 is a diagram illustrating a structure of a display device of an embodiment.

FIG. 19 is a diagram illustrating a structure of a display device of an embodiment.

FIG. 20 is a diagram illustrating a structure of a display device of an embodiment.

FIG. 21 is a diagram illustrating a structure of a display device of an embodiment.

FIG. 22A to FIG. 22D are diagrams illustrating examples of electronic devices of an embodiment.

FIG. 23A to FIG. 23F are diagrams illustrating examples of electronic devices of an embodiment.

FIG. 24A to FIG. 24G are diagrams illustrating examples of electronic devices of an embodiment.

FIG. 25A and FIG. 25B are diagrams illustrating a structure of a display device of an example.

FIG. 26 is an electron micrograph showing a structure of a display device of an example.

FIG. 27A and FIG. 27B are electron micrographs showing a structure of a display device of an example.

FIG. 28A and FIG. 28B are electron micrographs showing a structure of a display device of an example.

FIG. 29A to FIG. 29D are diagrams illustrating a structure of a display device of an example.

FIG. 30 is a graph showing luminance distribution in a minute region of a display device of an example.

FIG. 31 is a graph showing emission spectra of a display device of an example.

FIG. 32 is a graph showing luminance distribution in a minute region of a display device of an example.

FIG. 33 is a graph showing emission spectra of a display device of an example.

FIG. 34 is a graph showing luminance distribution in a minute region of a display device of an example.

FIG. 35 is a graph showing emission spectra of a display device of an example.

FIG. 36A and FIG. 36B are diagrams illustrating structures of a display device of an example.

FIG. 37 is a graph showing the current density-luminance characteristics of light-emitting devices of an example.

FIG. 38 is a graph showing the luminance-current efficiency characteristics of light-emitting devices of an example.

FIG. 39 is a graph showing the voltage-luminance characteristics of light-emitting devices of an example.

FIG. 40 is a graph showing the voltage-current characteristics of light-emitting devices of an example.

FIG. 41 is a graph showing emission spectra of light-emitting devices of an example.

FIG. 42A is a photograph showing a display state of a display device of an example, and FIG. 42B is a photograph showing arrangement of pixels.

FIG. 43 is a photograph showing arrangement of pixels in a display device of an example.

FIG. 44 is a photograph showing a color gamut that can be expressed by a display device of an example.

FIG. 45 is a photograph showing emission spectra of a display device of an example.

FIG. 46 is a graph showing the voltage-luminance characteristics of light-emitting devices of an example.

FIG. 47 is a graph showing the voltage-current density characteristics of light-emitting devices of an example.

FIG. 48 is a graph showing normalized luminance changes over time of light-emitting devices of an example.

### MODE FOR CARRYING OUT THE INVENTION

A display device of one embodiment of the present invention includes a first light-emitting device, a second light-emitting device, a third light-emitting device, and a fourth light-emitting device. The first light-emitting device includes a first electrode, a first layer, a second layer, and a second electrode. The first layer is sandwiched between the first electrode and the second electrode, and the first layer contains a first light-emitting material. The second layer is sandwiched between the first layer and the first electrode. The second light-emitting device includes a third electrode, a third layer, a fourth layer, and a fourth electrode. The third electrode is adjacent to the first electrode, a first gap is positioned between the third electrode and the first electrode, the third layer is sandwiched between the third electrode and the fourth electrode, and the third layer contains a second light-emitting material. The fourth layer is sandwiched between the third layer and the third electrode, and the fourth layer is continuous with the second layer over the first gap. The third light-emitting device includes a fifth electrode, a fifth layer, a sixth layer, and a sixth electrode. The fifth electrode is adjacent to the third electrode, a second gap is positioned between the fifth electrode and the third electrode, the fifth layer is sandwiched between the fifth electrode and the sixth electrode, and the fifth layer contains a third light-emitting material. The sixth layer is sandwiched between the fifth layer and the fifth electrode, a third gap is positioned between the sixth layer and the fourth layer, and the third gap overlaps with the second gap. The fourth light-emitting device includes a seventh electrode, a seventh layer, an eighth layer, and an eighth electrode. The seventh electrode is adjacent to the fifth electrode, a fourth gap is positioned between the seventh electrode and the fifth electrode, the seventh layer is sandwiched between the seventh electrode and the eighth electrode, and the seventh layer contains a fourth light-emitting material. The eighth layer is sandwiched between the seventh layer and the seventh electrode, a fifth gap is positioned between the eighth layer and the sixth layer, and the fifth gap overlaps with the fourth gap.

Thus, occurrence of a phenomenon in which, when one of the first light-emitting device, the second light-emitting device, the third light-emitting device, and the fourth light-emitting device emits light, the others emit light at unintended luminance can be inhibited. The first light-emitting device, the second light-emitting device, the third light-emitting device, and the fourth light-emitting device can independently emit light. Occurrence of a crosstalk phenomenon between the light-emitting devices can be inhibited. The color gamut that can be expressed by the display device can be widened. The resolution of the display device can be increased. The aperture ratio of a pixel of the display device can be increased. A film separation phenomenon during the fabrication process of the display device can be prevented. For example, a phenomenon in which the first layer or the third layer is separated during the fabrication process of the display device can be prevented. As a result, a novel display device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

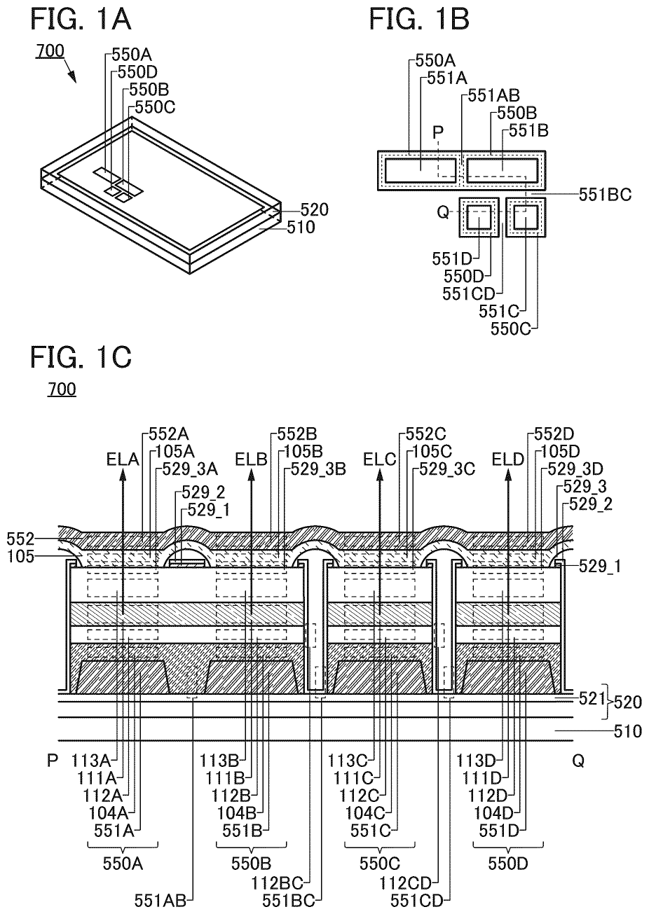

In this embodiment, a structure of a display device 700 of one embodiment of the present invention will be described with reference to FIG. 1 to FIG. 3.

FIG. 1A is a perspective view illustrating the structure of the display device 700 of one embodiment of the present invention. FIG. 1B is a top view illustrating part of the display device 700, and FIG. 1C is a cross-sectional view taken along the cutting line P-Q in FIG. 1B.

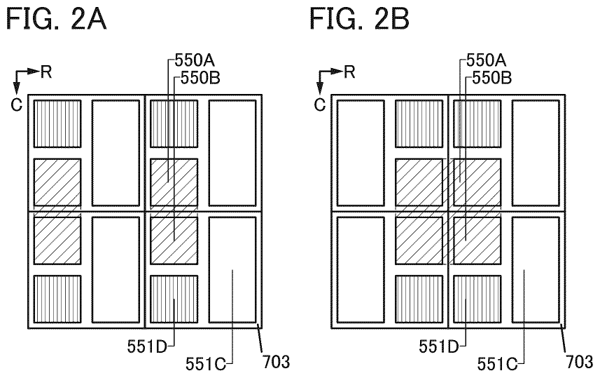

FIG. 2A and FIG. 2B are top views each illustrating part of the display device 700 of one embodiment of the present invention.

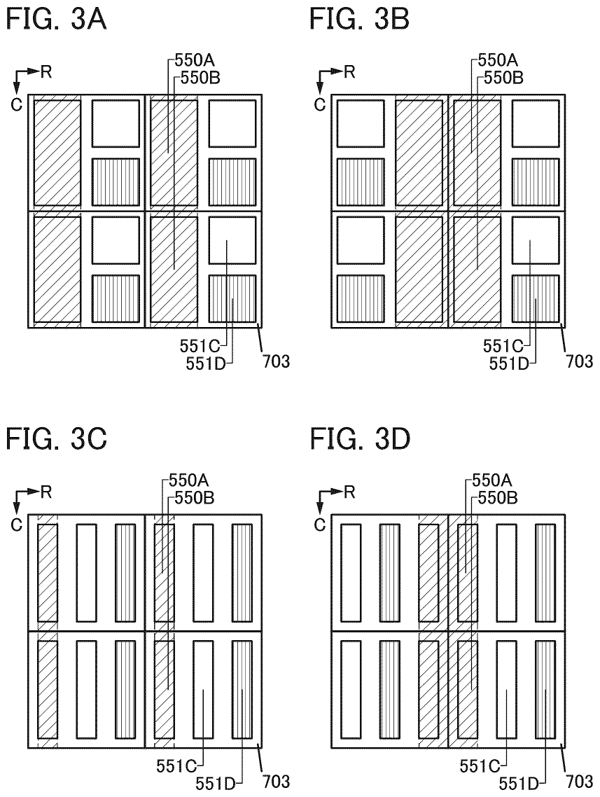

FIG. 3A to FIG. 3D are top views each illustrating part of the display device 700 of one embodiment of the present invention.

### <Structure Example 1 of Display Device 700>

The display device 700 described in this embodiment includes a substrate 510 and a functional layer 520 (see FIG. 1A). The display device 700 includes a light-emitting device 550A, a light-emitting device 550B, a light-emitting device 550C, and a light-emitting device 550D (see FIG. 1A and FIG. 1B).

The functional layer 520 includes an insulating film 521, and the light-emitting device 550A, the light-emitting device 550B, the light-emitting device 550C, and the light-emitting device 550D are formed over the insulating film 521 (see FIG. 1C). The functional layer 520 is sandwiched between the substrate 510 and the light-emitting device 550A.

### <<Structure Example of Light-Emitting Device 550A>>

The light-emitting device 550A includes an electrode 551A, a layer 111A, a layer 112A, and an electrode 552A. The light-emitting device 550A also includes a layer 113A. Note that the details of a structure applicable to the light-emitting device 550A will be described in Embodiment 2 to Embodiment 6.

For example, a light-emitting device having a current efficiency higher than or equal to 1 cd/A and lower than 10 cd/A can be used as the light-emitting device 550A. For another example, a light-emitting device having a light emission start voltage in a range higher than or equal to 3 V and lower than 4 V can be used as the light-emitting device 550A. In this specification, a light emission start voltage refers to the minimum voltage for obtaining a luminance higher than or equal to 10 cd/m².

### <<Structure Example of Layer 111A>>

The layer 111A is sandwiched between the electrode 551A and the electrode 552A, and the layer 111A contains a light-emitting material EMA. For example, the light-emitting material EMA that emits fluorescent light can be used for the layer 111A.

A light-emitting material having an emission spectrum with a maximum peak in a range greater than or equal to 380 nm and less than or equal to 480 nm can be used as the light-emitting material EMA, for example.

The layer 112A is sandwiched between the layer 111A and the electrode 551A.

### <<Structure Example of Light-Emitting Device 550B>>

The light-emitting device 550B includes an electrode 551B, a layer 111B, a layer 112B, and an electrode 552B. The light-emitting device 550B also includes a layer 113B. Note that the details of a structure applicable to the light-emitting device 550B will be described in Embodiment 2 to Embodiment 6.

The electrode 551B is adjacent to the electrode 551A, and a gap 551AB is positioned between the electrode 551B and the electrode 551A. Note that the gap 551AB is larger than or equal to 0.1 μm and smaller than or equal to 15 μm.

In the case where the end portion of the electrode 551B has a slope shape (also referred to as a tapered shape), the length of a portion where the electrode 551B is closest to the electrode 551A corresponds to the length of the gap 551AB. For example, the lower end portion of the electrode 551B is closest to the lower end portion of the electrode 551A (see FIG. 1C). In that case, the distance between the lower end portion of the electrode 551B and the lower end portion of the electrode 551A corresponds to the length of the gap 551AB.

In the case where the electrode 551B is formed over a conductive film supplied with the same potential as the electrode 551B and the electrode 551A is formed over another conductive film supplied with the same potential as the electrode 551A, the length of a portion where the electrode 551B or the conductive film is closest to the electrode 551A or the another conductive film corresponds to the length of the gap 551AB. For example, in the case where the electrode 551B is formed over a conductive film functioning as a wiring and the electrode 551A is formed over another conductive film functioning as a wiring, the distance between the conductive film and the another conductive film corresponds to the length of the gap 551AB. For another example, in the case where the electrode 551B is formed over a conductive film functioning as a reflective film and the electrode 551A is formed over another conductive film functioning as a reflective film, the distance between the conductive film and the another conductive film corresponds to the length of the gap 551AB.

For example, a light-emitting device having a current efficiency higher than or equal to 1 cd/A and lower than 10 cd/A can be used as the light-emitting device 550B. For another example, a light-emitting device having a light emission start voltage in a range higher than or equal to 3 V and lower than 4 V can be used as the light-emitting device 550B. Thus, occurrence of a phenomenon in which, when one of the light-emitting device 550A and the light-emitting device 550B emits light, the other emits light at unintended luminance can be inhibited.

### <<Structure Example of Layer 111B>>

The layer 111B is sandwiched between the electrode 551B and the electrode 552B, and the layer 111B contains a light-emitting material EMB. For example, the light-emitting material EMB that emits fluorescent light can be used for the layer 111B.

A light-emitting material having an emission spectrum with a maximum peak in a range greater than or equal to 380 nm and less than or equal to 480 nm can be used as the light-emitting material EMB, for example. Thus, light emitted from the light-emitting device 550A and the light-emitting device 550B is in a region with a low luminosity factor. When one of the light-emitting device 550A and the light-emitting device 550B emits light, light emitted from the other is hardly recognized.

The layer 112B is sandwiched between the layer 111B and the electrode 551B, and the layer 112B is continuous with the layer 112A over the gap 551AB.

### <<Structure Example of Light-Emitting Device 550C>>

The light-emitting device 550C includes an electrode 551C, a layer 111C, a layer 112C, and an electrode 552C. The light-emitting device 550C also includes a layer 113C. Note that the details of a structure applicable to the light-emitting device 550C will be described in Embodiment 2 to Embodiment 6.

The electrode 551C is adjacent to the electrode 551B, and a gap 551BC is positioned between the electrode 551C and the electrode 551B. Note that the gap 551BC is larger than or equal to 0.1 μm and smaller than or equal to 15 μm.

For example, a light-emitting device having a current efficiency higher than or equal to 10 cd/A and lower than 100 cd/A can be used as the light-emitting device 550C. For another example, a light-emitting device having a light emission start voltage in a range higher than or equal to 2 V and lower than 3 V can be used as the light-emitting device 550C. Thus, occurrence of a phenomenon in which the light-emitting device 550C emits light at unintended luminance when the light-emitting device 550B emits light can be inhibited.

### <<Structure Example of Layer 111C>>

The layer 111C is sandwiched between the electrode 551C and the electrode 552C, and the layer 111C contains a light-emitting material EMC. For example, the light-emitting material EMC that emits phosphorescent light can be used for the layer 111C.

A light-emitting material having an emission spectrum with a maximum peak in a range greater than or equal to 500 nm and less than or equal to 550 nm can be used as the light-emitting material EMC, for example.

The layer 112C is sandwiched between the layer 111C and the electrode 551C, and a gap 112BC is positioned between the layer 112C and the layer 112B. The gap 112BC overlaps with the gap 551BC. Thus, the layer 112C can be separated from the layer 112B. In addition, occurrence of a phenomenon in which carriers flow from the layer 112B to the layer 112C when the light-emitting device 550B emits light can be inhibited. Moreover, occurrence of a phenomenon in which the light-emitting device 550C emits light at unintended luminance when the light-emitting device 550B emits light can be inhibited.

Note that the gap 112BC is positioned between the layer 112C and the layer 112B. Meanwhile, no gap is positioned between the layer 112B and the layer 112A, and the layer 112B is continuous with the layer 112A. Thus, the gap 551AB can be narrower than the gap 551BC overlapping with the gap 112BC. In addition, the distance between a light-emitting device A and a light-emitting device B can be shorter than the distance between a light-emitting device C and its adjacent light-emitting device. Moreover, the aperture ratios of the light-emitting device B and the light-emitting device A can be higher than those of the other light-emitting devices.

### <<Structure Example of Light-Emitting Device 550D>>

The light-emitting device 550D includes an electrode 551D, a layer 111D, a layer 112D, and an electrode 552D. The light-emitting device 550D also includes a layer 113D. Note that the details of a structure applicable to the light-emitting device 550D will be described in Embodiment 2 to Embodiment 6.

The electrode 551D is adjacent to the electrode 551C, and a gap 551CD is positioned between the electrode 551D and the electrode 551C. Note that the gap 551CD is larger than or equal to 0.1 μm and smaller than or equal to 15 μm.

For example, a light-emitting device having a current efficiency higher than or equal to 10 cd/A and lower than 100 cd/A can be used as the light-emitting device 550D. For another example, a light-emitting device having a light emission start voltage in a range higher than or equal to 2 V and lower than 3 V can be used as the light-emitting device 550D. Thus, occurrence of a phenomenon in which the light-emitting device 550D emits light at unintended luminance when the light-emitting device 550C emits light can be inhibited.

### <<Structure Example of Layer 111D>>

The layer 111D is sandwiched between the electrode 551D and the electrode 552D, and the layer 111D contains a light-emitting material EMD. For example, the light-emitting material EMD that emits phosphorescent light can be used for the layer 111D.

A light-emitting material having an emission spectrum with a maximum peak in a range greater than or equal to 600 nm and less than or equal to 780 nm can be used as the light-emitting material EMD, for example.

The layer 112D is sandwiched between the layer 111D and the electrode 551D, and a gap 112CD is positioned between the layer 112D and the layer 112C. The gap 112CD overlaps with the gap 551CD. Thus, the layer 112D can be separated from the layer 112C. In addition, occurrence of a phenomenon in which carriers flow from the layer 112C to the layer 112D when the light-emitting device 550C emits light can be inhibited. Moreover, occurrence of a phenomenon in which the light-emitting device 550D emits light at unintended luminance when the light-emitting device 550C emits light can be inhibited.

Thus, occurrence of a phenomenon in which, when one of the light-emitting device 550A, the light-emitting device 550B, the light-emitting device 550C, and the light-emitting device 550D emits light, the others emit light at unintended luminance can be inhibited. The light-emitting device 550A, the light-emitting device 550B, the light-emitting device 550C, and the light-emitting device 550D can independently emit light. Occurrence of a crosstalk phenomenon between the light-emitting devices can be inhibited. The color gamut that can be expressed by the display device can be widened. The resolution of the display device can be increased. The aperture ratio of a pixel of the display device can be increased. A film separation phenomenon during the fabrication process of the display device can be prevented. For example, a phenomenon in which the layer 111A or the layer 111B is separated during the fabrication process of the display device can be prevented. As a result, a novel display device that is highly convenient, useful, or reliable can be provided.

### <Structure Example 2 of Display Device 700>

The display device 700 described in this embodiment includes an insulating film 521, the conductive film 552, and an insulating film 529_3 (see FIG. 1C). The display device 700 further includes a layer 105, a film 529_1, and a film 529_2.

### <<Structure Example of Insulating Film 521>>

The insulating film 521 overlaps with the conductive film 552, and the electrode 551A, the electrode 551B, and the electrode 551C are sandwiched between the insulating film 521 and the conductive film 552.

### <<Structure Example of Conductive Film 552>>

The conductive film 552 includes the electrode 552A, the electrode 552B, and the electrode 552C. The conductive film 552 further includes the electrode 552D.

A conductive material can be used for the conductive film 552, for example. Specifically, a single layer or a stack using a material containing a metal, an alloy, or a conductive compound can be used for the conductive film 552. Note that a structure example that can be employed for the conductive film 552 will be described in detail in Embodiment 4.

### <<Structure Example of Layer 105>>

The layer 105 includes a layer 105A, a layer 105B, a layer 105C, and a layer 105D. For the layer 105, a material that facilitates carrier injection from the electrode 552A, the electrode 552B, and the electrode 552C can be used. A material having an electron-injection property can be used for the layer 105, for example. Note that a structure example that can be employed for the layer 105 will be described in detail in Embodiment 4.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure. Note that a device having the MML (metal maskless) structure can be manufactured without using a metal mask, and thus can break through the resolution limit due to alignment accuracy of the metal mask. Furthermore, the manufacturing facilities for metal masks and washing process for metal masks can be unnecessary. In addition, the MML structure is suitable for mass production.

### <<Structure Example of Film 529_1>>

The film 529_1 has a plurality of opening portions; one of the opening portions overlaps with the electrode 551A and the electrode 551B, another opening portion overlaps with the electrode 551C, and another opening portion overlaps with the electrode 551D. The film 529_1 also has an opening portion overlapping with the gap 551BC and an opening portion overlapping with the gap 551CD. For example, a film containing a metal, a metal oxide, an organic material, or an inorganic insulating material can be used as the film 529_1. Specifically, a light-blocking metal film can be used. This can block light emitted in the processing process to inhibit occurrence of a phenomenon in which the characteristics of the light-emitting devices are degraded by the light.

### <<Structure Example of Film 529_2>>

The film 529_2 has opening portions; one of the opening portions overlaps with the electrode 551A and the electrode 551B, another opening portion overlaps with the electrode 551C, and another opening portion overlaps with the electrode 551D. The film 529_2 overlaps with the gap 551BC and the gap 551CD.

The film 529_2 includes regions in contact with a layer 104A, a layer 104B, a layer 104C, and a layer 104D. Note that the layer 104B is continuous with the layer 104A.

The film 529_2 includes regions in contact with the layer 112A, the layer 112B, the layer 112C, and the layer 112D. Note that the layer 112B is continuous with the layer 112A.

The film 529_2 includes regions in contact with the layer 111A, the layer 111B, the layer 111C, and the layer 111D. Note that the layer 111B is continuous with the layer 111A.

The film 529_2 includes regions in contact with the layer 113A, the layer 113B, the layer 113C, and the layer 113D. Note that the layer 113B is continuous with the layer 113A.

The film 529_2 includes a region in contact with the insulating film 521. The film 529_2 can be formed by an atomic layer deposition (ALD) method, for example. Thus, a film with good coverage can be formed. Specifically, a metal oxide film or the like can be used as the film 529_2. For example, aluminum oxide can be used.

### <<Structure Example of Insulating Film 529_3>>

The insulating film 529_3 is sandwiched between the conductive film 552 and the insulating film 521.

The insulating film 529_3 overlaps with the gap 551AB, and the insulating film 529_3 overlaps with the gap 551BC. The insulating film 529_3 overlaps with the gap 551CD. The insulating film 529_3 fills the gap 112BC. The insulating film 529_3 fills the gap 112CD.

The insulating film 529_3 has an opening portion 529_3A, an opening portion 529_3B, and an opening portion 529_3C. The opening portion 529_3A overlaps with the electrode 551A, the opening portion 529_3B overlaps with the electrode 551B, and the opening portion 529_3C overlaps with the electrode 551C.

The insulating film 529_3 can be formed using a photosensitive resin, for example. Specifically, an acrylic resin or the like can be used.

Thus, the gap 112BC can be filled with the insulating film 529_3. Moreover, a step due to the gap 112BC can be reduced so as to be close to a flat plane. A phenomenon in which a cut or a split due to the step is generated in the conductive film 552 can be inhibited. As a result, a novel display device that is highly convenient, useful, or reliable can be provided.

Note that part or the whole of the structure that can be employed for the light-emitting device 550D can be removed from the gap 551CD by a photolithography method, for example.

Specifically, in a first step, a first stack of films to be the layer 104D, the layer 112D, the layer 111D, and the layer 113D later is formed over the gap 551CD.

In a second step, a second film to be the film 529_1 later is formed over the first stack of films.

In a third step, an opening portion overlapping with the gap 551CD is formed in the second film by a photolithography method.

In a fourth step, part of the first stack of films is removed using the second film as a resist. For example, the first stack of films is removed from a region overlapping with the gap 551CD by a dry etching method. Specifically, the first stack of films can be removed from the gap 551CD using an oxygen-containing gas. Accordingly, a groove-like structure is formed in the first stack of films. In addition, the layer 104D, the layer 112D, the layer 111D, and the layer 113D are formed.

In a fifth step, a third film to be the film 529_2 later is formed over the second film by an atomic layer deposition method (ALD), for example.

In a sixth step, the insulating film 529_3 is formed using a photosensitive polymer, for example. Thus, the insulating film 529_3 fills the gap 551CD. The opening portion 529_3A, the opening portion 529_3B, the opening portion 529_3C, and an opening portion 529_3D are formed in the insulating film 529_3.

In a seventh step, an opening portion overlapping with the electrode 551A, an opening portion overlapping with the electrode 551B, an opening portion overlapping with the electrode 551C, and the opening portion overlapping with the electrode 551C are formed in the third film and the second film by an etching method, whereby the film 529_2 and the film 529_1 are formed.

In an eighth step, the layer 105D is formed over the layer 113D, and the electrode 552D is formed over the layer 105D.

### <Structure Example 3 of Display Device 700>

The display device 700 described in this embodiment includes a pixel set 703. The pixel set 703 is adjacent to a plurality of different pixel sets (see FIG. 2A, FIG. 2B, and FIG. 3A to FIG. 3D).

For example, the different pixel set is adjacent to the pixel set 703 in a row direction (a direction indicated by an arrow R in the figure). In addition, the different pixel set is adjacent to the pixel set 703 in a column direction (a direction indicated by an arrow C in the figure). Note that the column direction is a direction intersecting with the row direction.

The pixel set 703 includes the light-emitting device 550A, the light-emitting device 550B, the light-emitting device 550C, and the light-emitting device 550D.

### <<Example 1 of Pixel Set 703>>

As described above, the light-emitting device 550A includes the layer 112A, and the light-emitting device 550B includes the layer 112B. The layer 112B is continuous with the layer 112A. The continuous layer 112B is indicated by oblique hatching in the figure (see FIG. 2A). In other words, the two light-emitting devices share the layer 112B and the layer continuous with the layer 112B. This can prevent a film separation phenomenon during the fabrication process of the display device.

Note that the light-emitting device 550A can be used as a light-emitting device in the different pixel set adjacent in the column direction, for example. A gap is positioned between the layer 112B and the layer 112C in the light-emitting device 550C adjacent to the light-emitting device 550B.

### <<Example 2 of Pixel Set 703>>

As described above, the light-emitting device 550A includes the layer 112A, and the light-emitting device 550B includes the layer 112B. The layer 112B is continuous with the layer 112A. The continuous layer 112B is indicated by oblique hatching in the figure (see FIG. 2B). The layer 112B is also continuous with layers in other light-emitting devices adjacent in the row direction. In other words, four light-emitting devices share the layer 112B and the layers continuous with the layer 112B. This can prevent a film separation phenomenon during the fabrication process of the display device.

Note that the light-emitting device 550A can be used as a light-emitting device in the different pixel set adjacent in the column direction, for example. A gap is positioned between the layer 112B and the layer 112C in the light-emitting device 550C adjacent to the light-emitting device 550B.

### <<Example 3 of Pixel Set 703>>

As described above, the light-emitting device 550A includes the layer 112A, and the light-emitting device 550B includes the layer 112B. The layer 112B is continuous with the layer 112A. The continuous layer 112B is indicated by oblique hatching in the figures (see FIG. 3A and FIG. 3C). Three or more light-emitting devices arranged in the column direction can include the layer 112B and layers continuous with the layer 112B. In other words, the three or more light-emitting devices share the layer 112B and the layers continuous with the layer 112B. This can prevent a film separation phenomenon during the fabrication process of the display device.

Note that the light-emitting device 550A can be used as a light-emitting device in the different pixel set adjacent in the column direction, for example. A gap is positioned between the layer 112B and the layer 112C in the light-emitting device 550C adjacent to the light-emitting device 550B.

### <<Example 4 of Pixel Set 703>>

As described above, the light-emitting device 550A includes the layer 112A, and the light-emitting device 550B includes the layer 112B. The layer 112B is continuous with the layer 112A. The continuous layer 112B is indicated by oblique hatching in the figures (see FIG. 3B and FIG. 3D). Three or more light-emitting devices arranged in the column direction can include the layer 112B and layers continuous with the layer 112B. The layer 112B is also continuous with layers in other light-emitting devices adjacent in the row direction. In other words, four or more light-emitting devices share the layer 112B and the layers continuous with the layer 112B. This can prevent a film separation phenomenon during the fabrication process of the display device.

Note that the light-emitting device 550A can be used as a light-emitting device in the different pixel set adjacent in the column direction, for example. A gap is positioned between the layer 112B and the layer 112C in the light-emitting device 550C adjacent to the light-emitting device 550B.

Note that this embodiment can be combined with any of the other embodiments described in this specification as appropriate.

### Embodiment 2

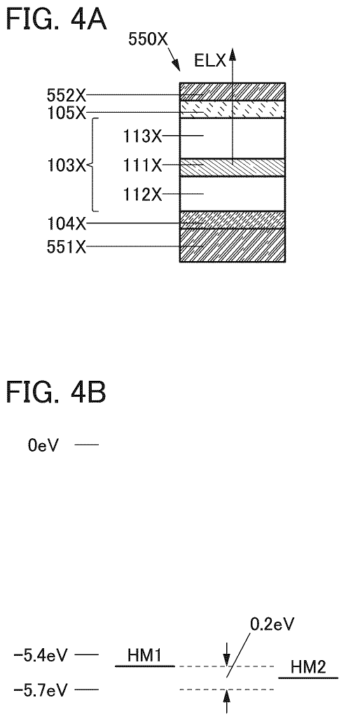

In this embodiment, a structure of a light-emitting device 550X of one embodiment of the present invention will be described with reference to FIG. 4A and FIG. 4B.

FIG. 4A is a cross-sectional view illustrating the structure of the light-emitting device 550X of one embodiment of the present invention, and FIG. 4B is a diagram showing energy levels of materials used for the light-emitting device 550X of one embodiment of the present invention.

The structure of the light-emitting device 550X described in this embodiment can be employed for the display device of one embodiment of the present invention. Note that the description of the structure of the light-emitting device 550X can be applied to the light-emitting device 550A. Specifically, the description of the structure of the light-emitting device 550X can be referred to for the description of the light-emitting device 550A by replacing “X” in the reference numerals with “A”. Similarly, the structure of the light-emitting device 550X can be employed for the light-emitting device 550B, the light-emitting device 550C, or the light-emitting device 550D by replacing “X” with “B”, “C”, or “D”.

### <Structure Example of Light-Emitting Device 550X>

The light-emitting device 550X described in this embodiment includes an electrode 551X, an electrode 552X, and a unit 103X. The electrode 552X overlaps with the electrode 551X, and the unit 103X is sandwiched between the electrode 552X and the electrode 551X.

### <Structure Example of Unit 103X>

The unit 103X has a single-layer structure or a stacked-layer structure. For example, the unit 103X includes a layer 111X, a layer 112X, and a layer 113X (see FIG. 4A). The unit 103X has a function of emitting light ELX.

The layer 111X is sandwiched between the layer 113X and the layer 112X, the layer 113X is sandwiched between the electrode 552X and the layer 111X, and the layer 112X is sandwiched between the layer 111X and the electrode 551X.

For example, a layer selected from functional layers such as a light-emitting layer, a hole-transport layer, an electron-transport layer, and a carrier-blocking layer can be used in the unit 103X. Moreover, a layer selected from functional layers such as a hole-injection layer, an electron-injection layer, an exciton-blocking layer, and a charge-generation layer can be used in the unit 103X.

### <<Structure Example of Layer 112X>>

A material having a hole-transport property can be used for the layer 112X, for example. The layer 112X can be referred to as a hole-transport layer. A material having a wider band gap than a light-emitting material contained in the layer 111X is preferably used for the layer 112X. In that case, energy transfer from excitons generated in the layer 111X to the layer 112X can be inhibited.

### [Material Having Hole-Transport Property]

A material having a hole mobility higher than or equal to 1×10⁻⁶ cm²/Vs can be suitably used as the material having a hole-transport property.

As the material having a hole-transport property, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds have high reliability, have high hole-transport properties, and contribute to a reduction in driving voltage.

As the compound having an aromatic amine skeleton, for example, 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), or the like can be used.

As the compound having a carbazole skeleton, for example, 1,3-bis(N-carbazolyl)benzene (abbreviation: mCP), 4,4′-di(N-carbazolyl) biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As the compound having a thiophene skeleton, for example, 4,4′,4″-(benzene-1,3,5-triyl)tri (dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As the compound having a furan skeleton, for example, 4,4′,4″-(benzene-1,3,5-triyl)tri (dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

### <<Structure Example of Layer 113X>>

A material having an electron-transport property, a material having an anthracene skeleton, or a mixed material can be used for the layer 113X, for example. The layer 113X can be referred to as an electron-transport layer. Note that a material having a wider band gap than the light-emitting material contained in the layer 111X is preferably used for the layer 113X. In that case, energy transfer from excitons generated in the layer 111X to the layer 113X can be inhibited.

### [Material Having Electron-Transport Property]

A material having an electron mobility higher than or equal to 1×10⁻⁷ cm²/Vs and lower than or equal to 5×10⁻⁵ cm²/Vs in a condition where the square root of the electric field strength V/cm is 600 can be suitably used as the material having an electron-transport property. Thus, the electron-transport property in the electron-transport layer can be suppressed. Alternatively, the amount of electrons injected into the light-emitting layer can be controlled. Alternatively, the light-emitting layer can be prevented from having excess electrons.

For example, a metal complex or an organic compound having a I-electron deficient heteroaromatic ring skeleton can be used as the material having an electron-transport property.

As the metal complex, for example, bis(10-hydroxybenzo[h]quinolinato) beryllium (II) (abbreviation: BeBq₂), bis(2-methyl-8-quinolinolato) (4-phenylphenolato)aluminum (III) (abbreviation: BAlq), bis(8-quinolinolato) zinc (II) (abbreviation: Znq), bis[2-(2-benzoxazolyl)phenolato]zinc (II) (abbreviation: ZnPBO), bis[2-(2-benzothiazolyl)phenolato]zinc (II) (abbreviation: ZnBTZ), or the like can be used.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton or the heterocyclic compound having a pyridine skeleton has high reliability and thus is preferable. In addition, the heterocyclic compound having a diazine (pyrimidine or pyrazine) skeleton has a high electron-transport property and thus can reduce the driving voltage.

As the heterocyclic compound having a polyazole skeleton, for example, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or the like can be used.

As the heterocyclic compound having a diazine skeleton, for example, 2-[3-(dibenzothiophen-4-yl)phenyl]dibenzo[f,h]quinoxaline (abbreviation: 2mDBTPDBq-II), 2-[3′-(dibenzothiophen-4-yl) biphenyl-3-yl]dibenzo[f,h]quinoxaline (abbreviation: 2mDBTBPDBq-II), 2-[3′-(9H-carbazol-9-yl) biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used.

As the heterocyclic compound having a pyridine skeleton, for example, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used.

As the heterocyclic compound having a triazine skeleton, for example, 2-[3′-(9,9-dimethyl-9H-fluoren-2-yl) biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), or the like can be used.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, a pyrazole ring, an imidazole ring, an oxazole ring, a thiazole ring, or the like can be suitably used as the heterocyclic skeleton.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, a pyrazine ring, a pyrimidine ring, a pyridazine ring, or the like can be suitably used as the heterocyclic skeleton.

### [Structure Example of Mixed Material]

A material in which a plurality of kinds of substances are mixed can be used for the layer 113X. Specifically, a mixed material that contains a substance having an electron-transport property and any of an alkali metal, an alkali metal compound, and an alkali metal complex can be used for the layer 113X. Note that it is further preferable that the HOMO level of the material having an electron-transport property be higher than or equal to −6.0 eV.

The mixed material can be suitably used for the layer 113X in combination with a structure using a composite material, which is described later, for a layer 104X. For example, a composite material of a substance having an electron-accepting property and a material having a hole-transport property can be used for the layer 104X. Specifically, a composite material of a substance having an electron-accepting property and a substance having a relatively deep HOMO level HM1, which is higher than or equal to −5.7 eV and lower than or equal to −5.4 eV, can be used for the layer 104X (see FIG. 4B). Using the mixed material for the layer 113X in combination with the structure using such a composite material for the layer 104X leads to an increase in the reliability of the light-emitting device.

Furthermore, a structure using a material having a hole-transport property for the layer 112X is preferably combined with the structure using the mixed material for the layer 113X and the composite material for the layer 104X. For example, a substance having a HOMO level HM2, which is within the range of −0.2 eV to 0 eV from the relatively deep HOMO level HM1, can be used for the layer 112X (see FIG. 4B). As a result, the reliability of the light-emitting device can be increased. Note that in this specification and the like, the structure of the above light-emitting device is referred to as a Recombination-Site Tailoring Injection structure (ReSTI structure) in some cases.

The concentration of the alkali metal, the alkali metal compound, or the alkali metal complex preferably differs in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. A complex of a monovalent metal ion, especially a complex of lithium, is particularly preferable, and Liq is further preferable.

### <<Structure Example 1 of Layer 111X>>

A light-emitting material or a light-emitting material and a host material can be used for the layer 111X, for example. The layer 111X can be referred to as a light-emitting layer. The layer 111X is preferably provided in a region where holes and electrons are recombined. In that case, energy generated by recombination of carriers can be efficiently converted into light and emitted.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having a reflective property to the layer 111X be adjusted and the layer 111X be provided in an appropriate position in accordance with an emission wavelength. Thus, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is provided in an appropriate position between electrodes or the like, and thus a microcavity structure (microcavity) can be formed.

For example, a fluorescent substance, a phosphorescent substance, or a substance exhibiting thermally activated delayed fluorescence (TADF) (also referred to as a TADF material) can be used as the light-emitting material. Thus, energy generated by recombination of carriers can be released as the light ELX from the light-emitting material (see FIG. 4A).

### [Fluorescent Substance]

A fluorescent substance can be used for the layer 111X. For example, any of the following fluorescent substances can be used for the layer 111X. Note that without being limited to the following ones, any of a variety of known fluorescent substances can be used for the layer 111X.

Specifically, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl) biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl) perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N,N-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b; 6,7-b′]bisbenzofuran (abbreviation: 3,10PCA2Nbf (IV)-02), or 3,10-bis[N-(dibenzofuran-3-yl)-N-phenylamino]naphtho[2,3-b; 6,7-b′]bisbenzofuran (abbreviation: 3,10FrA2Nbf (IV)-02).

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

In addition, it is possible to use, for example, N-[4-(9,10-diphenyl-2-anthryl)phenyl]-N,N′,N′-triphenyl-1,4-phenylenediamine (abbreviation: 2DPAPPA), N,N,N′,N′,N″,N″,N″′,N″′-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), 9,10-bis-(biphenyl-2-yl)-2-[N-(9-phenyl-carbazol-3-yl)-N-phenyl-amino]-anthracene (abbreviation: 2PCABPhA), N-(9,10-diphenyl-2-anthryl)-N,N′,N′-triphenyl-1,4-phenylenediamine (abbreviation: 2DPAPA), 9,10-bis(2-biphenyl)-2-(N,N′,N′-triphenyl-1,4-phenylenediamine-N-yl) anthracene (abbreviation: 2DPABPhA), 9,10-bis(2-biphenyl)-2-[N-(4-(9H) carbazol-9-yl)phenyl-N-phenylamino]anthracene (abbreviation: 2YGABPhA), N,N,9-triphenylanthracen-9-amine (abbreviation: DPhAPhA), coumarin 545T, N,N′-diphenylquinacridone (abbreviation: DPQd), rubrene, or 5,12-bis(1,1′-biphenyl-4-yl)-6,11-diphenyltetracene (abbreviation: BPT).

Furthermore, it is possible to use, for example, 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl) ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl) acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene) propanedinitrile (abbreviation: BisDCM), or 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM).

### [Phosphorescent Substance]

A phosphorescent substance can be used for the layer 111X. For example, any of the following phosphorescent substances can be used for the layer 111X. Note that without being limited to the following ones, any of a variety of known phosphorescent substances can be used for the layer 111X.

For the layer 111X, it is possible to use, for example, an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, or a platinum complex.

### [Phosphorescent Substance (Blue)]

As the organometallic iridium complex having a 4H-triazole skeleton or the like, for example, tris {2-[5-(2-methylphenyl)-4-(2,6-dimethylphenyl)-4H-1,2,4-triazol-3-yl-κN2]phenyl-κC}iridium (III) (abbreviation: [Ir(mpptz-dmp)₃]), tris(5-methyl-3,4-diphenyl-4H-1,2,4-triazolato) iridium (III) (abbreviation: [Ir(Mptz)₃]), tris[4-(3-biphenyl)-5-isopropyl-3-phenyl-4H-1,2,4-triazolato]iridium (III) (abbreviation: [Ir(iPrptz-3b)₃]), or the like can be used.

As the organometallic iridium complex having a 1H-triazole skeleton or the like, for example, tris[3-methyl-1-(2-methylphenyl)-5-phenyl-1H-1,2,4-triazolato]iridium (III) (abbreviation: [Ir(Mptz1-mp)₃]), tris(1-methyl-5-phenyl-3-propyl-1H-1,2,4-triazolato]iridium (III) (abbreviation: [Ir(Prptz1-Me)₃]), or the like can be used.

As the organometallic iridium complex having an imidazole skeleton or the like, for example, fac-tris[1-(2,6-diisopropylphenyl)-2-phenyl-1H-imidazole]iridium (III) (abbreviation: [Ir(iPrpim)₃]), tris[3-(2,6-dimethylphenyl)-7-methylimidazo[1,2-f]phenanthridinato]iridium (III) (abbreviation: [Ir(dmpimpt-Me)₃]), or the like can be used.

As the organometallic iridium complex having a phenylpyridine derivative with an electron-withdrawing group as a ligand, or the like, for example, bis[2-(4′,6′-difluorophenyl)pyridinato-N,C^{2′}]iridium (III) tetrakis(1-pyrazolyl) borate (abbreviation: FIr6), bis[2-(4′,6′-difluorophenyl)pyridinato-N,C^{2′}]iridium (III) picolinate (abbreviation: FIrpic), bis {2-[3′,5′-bis(trifluoromethyl)phenyl]pyridinato-N,C^{2′}}iridium (III) picolinate (abbreviation: [Ir(CF₃ppy)₂ (pic)]), bis[2-(4′,6′-difluorophenyl)pyridinato-N,C^{2′}]iridium (III) acetylacetonate (abbreviation: FIracac), or the like can be used.

Note that these are compounds exhibiting blue phosphorescent light and are compounds having an emission wavelength peak at 440 nm to 520 nm.

### [Phosphorescent Substance (Green)]

As the organometallic iridium complex having a pyrimidine skeleton or the like, for example, tris(4-methyl-6-phenylpyrimidinato) iridium (III) (abbreviation: [Ir(mppm)₃]), tris(4-1-butyl-6-phenylpyrimidinato) iridium (III) (abbreviation: [Ir(tBuppm)₃]), (acetylacetonato)bis(6-methyl-4-phenylpyrimidinato) iridium (III) (abbreviation: [Ir(mppm)₂ (acac)]), (acetylacetonato)bis(6-tert-butyl-4-phenylpyrimidinato) iridium (III) (abbreviation: [Ir(tBuppm)₂ (acac)]), (acetylacetonato)bis[6-(2-norbornyl)-4-phenylpyrimidinato]iridium (III) (abbreviation: [Ir(nbppm)₂ (acac)]), (acetylacetonato)bis[5-methyl-6-(2-methylphenyl)-4-phenylpyrimidinato]iridium (III) (abbreviation: [Ir(mpmppm)₂ (acac)]), (acetylacetonato)bis(4,6-diphenylpyrimidinato) iridium (III) (abbreviation: [Ir(dppm)₂ (acac)]), or the like can be used.

As the organometallic iridium complex having a pyrazine skeleton or the like, for (acetylacetonato)bis(3,5-dimethyl-2-phenylpyrazinato) iridium (III) (abbreviation: example, [Ir(mppr-Me)₂ (acac)]), (acetylacetonato)bis(5-isopropyl-3-methyl-2-phenylpyrazinato) iridium (III) (abbreviation: [Ir(mppr-iPr)₂ (acac)]), or the like can be used.

As the organometallic iridium complex having a pyridine skeleton or the like, for example, tris(2-phenylpyridinato-N,C^{2′}) iridium (III) (abbreviation: [Ir(ppy)₃]), bis(2-phenylpyridinato-N,C^{2′}) iridium (III) acetylacetonate (abbreviation: [Ir(ppy)₂ (acac)]), bis(benzo[h]quinolinato) iridium (III) acetylacetonate (abbreviation: [Ir(bzq)₂ (acac)]), tris(benzo[h]quinolinato) iridium (III) (abbreviation: [Ir(bzq)₃]), tris(2-phenylquinolinato-N,C^{2′}) iridium (III) (abbreviation: [Ir(pq)₃]), bis(2-phenylquinolinato-N,C^{2′}) iridium (III) acetylacetonate (abbreviation: [Ir(pq)₂ (acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium (III) (abbreviation: [Ir(5mppy-d₃)₂ (mbfpypy-d₃)]), [2-d₃-methyl-(2-pyridinyl-κN)benzofuro[2,3-b]pyridine-κC]bis[2-(2-pyridinyl-κN)phenyl-κC]iridium (III) (abbreviation: [Ir(ppy)₂ (mbfpypy-d₃)]), or the like can be used.

An example of the rare earth metal complex is tris(acetylacetonato) (monophenanthroline) terbium (III) (abbreviation: [Tb(acac)₃ (Phen)]).

Note that these are compounds mainly exhibiting green phosphorescent light and have an emission wavelength peak at 500 nm to 600 nm. An organometallic iridium complex having a pyrimidine skeleton excels particularly in reliability or emission efficiency.

### [Phosphorescent Substance (Red)]

As the organometallic iridium complex having a pyrimidine skeleton or the like, for example, (diisobutyrylmethanato)bis[4,6-bis(3-methylphenyl)pyrimidinato]iridium (III) (abbreviation: [Ir(5mdppm)₂ (dibm)]), bis[4,6-bis(3-methylphenyl)pyrimidinato](dipivaloylmethanato) iridium (III) (abbreviation: [Ir(5mdppm)₂ (dpm)]), bis[4,6-di(naphthalen-1-yl)pyrimidinato](dipivaloylmethanato) iridium (III) (abbreviation: [Ir(dnpm)₂ (dpm)]), or the like can be used.

As the organometallic iridium complex having a pyrazine skeleton or the like, for example, (acetylacetonato)bis(2,3,5-triphenylpyrazinato) iridium (III) (abbreviation: [Ir(tppr)₂ (acac)]), bis(2,3,5-triphenylpyrazinato) (dipivaloylmethanato) iridium (III) (abbreviation: [Ir(tppr)₂ (dpm)]), (acetylacetonato)bis[2,3-bis(4-fluorophenyl) quinoxalinato]iridium (III) (abbreviation: [Ir(Fdpq)₂ (acac)]), or the like can be used.

As the organometallic iridium complex having a pyridine skeleton or the like, for example, tris(1-phenylisoquinolinato-N,C^{2′}) iridium (III) (abbreviation: [Ir(piq)₃]), bis(1-phenylisoquinolinato-N, (2′) iridium (III) acetylacetonate (abbreviation: [Ir(piq)₂ (acac)]), or the like can be used.

As the rare earth metal complex or the like, for example, tris(1,3-diphenyl-1,3-propanedionato) (monophenanthroline) europium (III) (abbreviation: [Eu (DBM)₃ (Phen)]), tris[1-(2-thenoyl)-3,3,3-trifluoroacetonato](monophenanthroline) europium (III) (abbreviation: [Eu (TTA)₃ (Phen)]), or the like can be used.

As the platinum complex or the like, for example, 2,3,7,8,12,13,17,18-octaethyl-21H,23H-porphyrin platinum (II) (abbreviation: PtOEP) or the like can be used.

Note that these are compounds exhibiting red phosphorescent light and have an emission peak at 600 nm to 700 nm. Furthermore, from the organometallic iridium complex having a pyrazine skeleton, red light emission with chromaticity suitably used for display devices can be obtained.

### [Substance Exhibiting Thermally Activated Delayed Fluorescence (TADF)]

A TADF material can be used for the layer 111X. When a TADF material is used as a light-emitting substance, the S1 level of the host material is preferably higher than the S1 level of the TADF material. In addition, the T1 level of the host material is preferably higher than the T1 level of the TADF material.

For example, any of the TADF materials exemplified below can be used as the light-emitting material. Note that without being limited thereto, any of a variety of known TADF materials can be used.

In the TADF material, the difference between the S1 level and the T1 level is small, and reverse intersystem crossing (upconversion) from the triplet excited state into the singlet excited state can be achieved by a little thermal energy. Thus, the singlet excited state can be efficiently generated from the triplet excited state. In addition, the triplet excitation energy can be converted into light.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

For example, a fullerene, a derivative thereof, an acridine, a derivative thereof, an eosin derivative, or the like can be used as the TADF material. Furthermore, porphyrin containing a metal such as magnesium (Mg), zinc (Zn), cadmium (Cd), tin (Sn), platinum (Pt), indium (In), or palladium (Pd) can also be used as the TADF material.

Specifically, any of the following materials whose structural formulae are shown below can be used: a protoporphyrin-tin fluoride complex (SnF₂ (Proto IX)), a mesoporphyrin-tin fluoride complex (SnF₂ (Meso IX)), a hematoporphyrin-tin fluoride complex (SnF₂ (Hemato IX)), a coproporphyrin tetramethyl ester-tin fluoride complex (SnF₂ (Copro III-4Me)), an octaethylporphyrin-tin fluoride complex (SnF₂ (OEP)), an etioporphyrin-tin fluoride complex (SnF₂ (Etio I)), an octaethylporphyrin-platinum chloride complex (PtCl₂OEP), and the like.

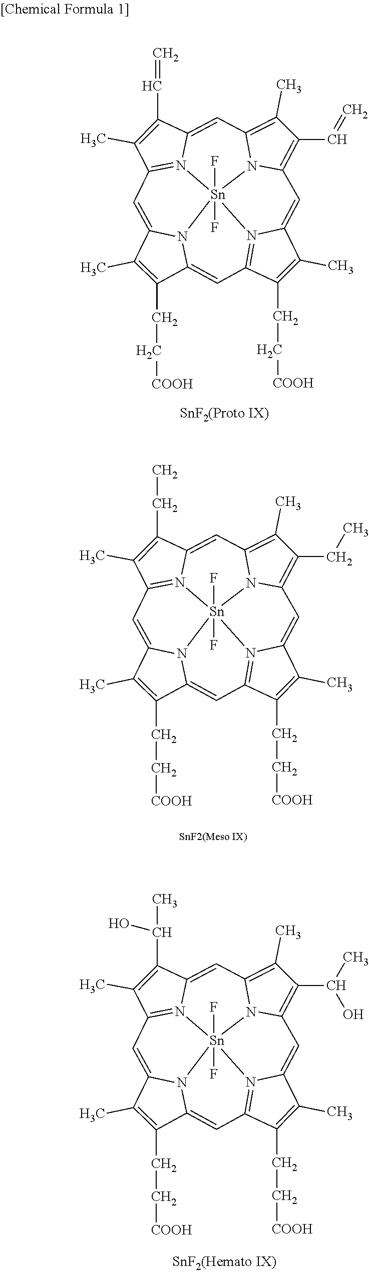

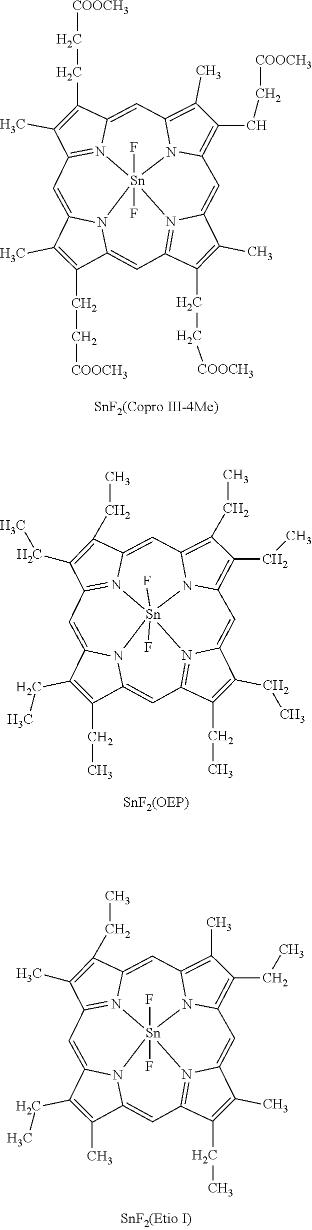

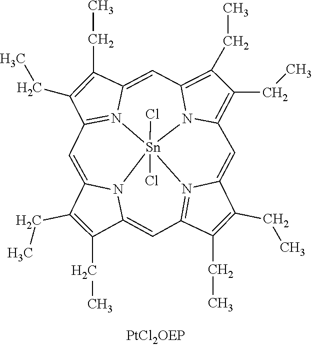

Furthermore, a heterocyclic compound including one or both of a π-electron rich heteroaromatic ring and a T-electron deficient heteroaromatic ring can be used as the TADF material, for example.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

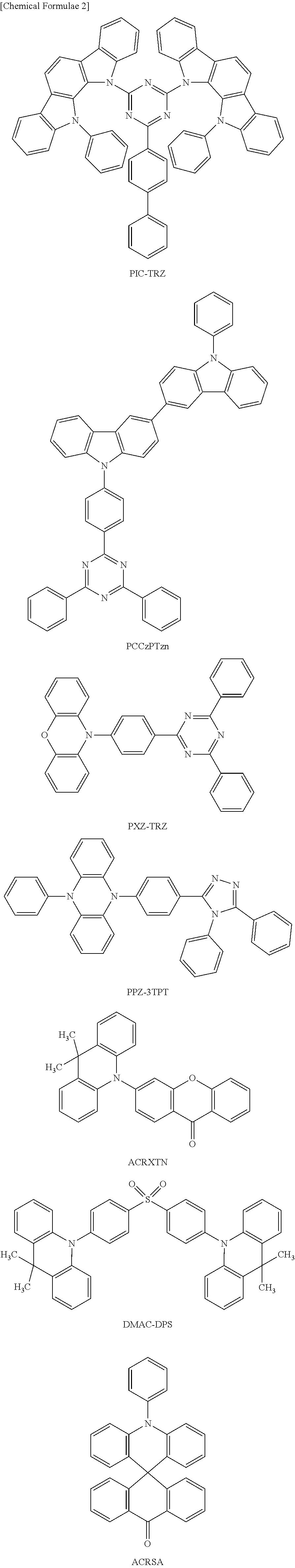

Such a heterocyclic compound is preferable because of having a high electron-transport property and a high hole-transport property owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting properties and reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### <<Structure Example 2 of Layer 111X>>

A material having a carrier-transport property can be used as the host material. For example, a material having a hole-transport property, a material having an electron-transport property, a substance exhibiting thermally activated delayed fluorescence (TADF), a material having an anthracene skeleton, or a mixed material can be used as the host material. A material having a wider band gap than the light-emitting material contained in the layer 111X is preferably used as the host material. In that case, energy transfer from excitons generated in the layer 111X to the host material can be inhibited.

### [Material Having Hole-Transport Property]

A material having a hole mobility higher than or equal to 1× 10⁻⁶ cm²/Vs can be suitably used as the material having a hole-transport property. For example, the material having a hole-transport property that can be used for the layer 112X can be used for the layer 111X.

### [Material Having Electron-Transport Property]

A metal complex or an organic compound having a π-electron deficient heteroaromatic ring skeleton can be used as the material having an electron-transport property. For example, the material having an electron-transport property that can be used for the layer 113X can be used for the layer 111X.

### [Material Having Anthracene Skeleton]

An organic compound having an anthracene skeleton can be used as the host material. An organic compound having an anthracene skeleton is particularly suitable in the case where a fluorescent substance is used as a light-emitting substance. In that case, a light-emitting device with high emission efficiency and high durability can be obtained.

As the organic compound having an anthracene skeleton, an organic compound having a diphenylanthracene skeleton, in particular, a 9,10-diphenylanthracene skeleton is chemically stable and thus is preferable. The host material preferably has a carbazole skeleton, in which case the hole-injection and hole-transport properties are improved. In particular, the host material preferably has a dibenzocarbazole skeleton, in which case the HOMO level thereof is shallower than that of carbazole by approximately 0.1 eV, so that holes enter the host material easily, the hole-transport property is improved, and the heat resistance is increased. Note that in terms of the hole-injection and hole-transport properties, a benzofluorene skeleton or a dibenzofluorene skeleton may be used instead of a carbazole skeleton.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, it is possible to use 6-[3-(9,10-diphenyl-2-anthryl)phenyl]-benzo[b]naphtho[1,2-d]furan (abbreviation: 2mBnfPPA), 9-phenyl-10-[4′-(9-phenyl-9H-fluoren-9-yl) biphenyl-4-yl]anthracene (abbreviation: FLPPA), 9-(1-naphthyl)-10-[4-(2-naphthyl)phenyl]anthracene (abbreviation: αN-BNP Anth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), or 3-[4-(1-naphthyl)-phenyl]-9-phenyl-9H-carbazole (abbreviation: PCPN).

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than the S1 level of the fluorescent substance in order that high emission efficiency can be achieved. Furthermore, the T1 level of the TADF material is preferably higher than the S1 level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier transport or carrier recombination.

Here, the luminophore refers to an atomic group (skeleton) that causes light emission in a fluorescent substance. The luminophore is preferably a skeleton having a π bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### [Structure Example 1 of Mixed Material]

A material in which a plurality of kinds of substances are mixed can be used as the host material. For example, a material having an electron-transport property and a material having a hole-transport property can be used as the mixed material. The weight ratio between the material having a hole-transport property and the material having an electron-transport property contained in the mixed material may be (the material having a hole-transport property/the material having an electron-transport property)=(1/19) or more and (19/1) or less. Accordingly, the carrier-transport property of the layer 111X can be easily adjusted. In addition, a recombination region can be easily controlled.

### [Structure Example 2 of Mixed Material]

A material mixed with a phosphorescent substance can be used as the host material. When a fluorescent substance is used as the light-emitting substance, the phosphorescent substance can be used as an energy donor for supplying excitation energy to the fluorescent substance.

### [Structure Example 3 of Mixed Material]

A mixed material containing a material forming an exciplex can be used as the host material. For example, a material forming an exciplex whose emission spectrum overlaps with the wavelength of the absorption band on the lowest energy side of the light-emitting substance can be used as the host material. This enables smooth energy transfer and improves emission efficiency. Alternatively, the driving voltage can be reduced. With such a structure, light emission can be efficiently obtained by ExTET (Exciplex-Triplet Energy Transfer), which is energy transfer from the exciplex to the light-emitting substance (phosphorescent material).

A phosphorescent substance can be used as at least one of the materials forming an exciplex. Accordingly, reverse intersystem crossing can be used. Alternatively, triplet excitation energy can be efficiently converted into singlet excitation energy.

A combination of a material having an electron-transport property and a material having a hole-transport property whose HOMO level is higher than or equal to the HOMO level of the material having an electron-transport property is preferable for forming an exciplex. Alternatively, the LUMO level of the material having a hole-transport property is preferably higher than or equal to the LUMO level of the material having an electron-transport property. In that case, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

Note that this embodiment can be combined with any of the other embodiments described in this specification as appropriate.

### Embodiment 3

In this embodiment, the structure of the light-emitting device 550X of one embodiment of the present invention will be described with reference to FIG. 4A and FIG. 4B.

The structure of the light-emitting device 550X described in this embodiment can be employed for the display device of one embodiment of the present invention. Note that the description of the structure of the light-emitting device 550X can be applied to the light-emitting device 550A. Specifically, the description of the structure of the light-emitting device 550X can be referred to for the description of the light-emitting device 550A by replacing “X” in the reference numerals with “A”. Similarly, the structure of the light-emitting device 550X can be employed for the light-emitting device 550B, the light-emitting device 550C, or the light-emitting device 550D by replacing “X” with “B”, “C”, or “D”.

### <Structure Example of Light-Emitting Device 550X>

The light-emitting device 550X described in this embodiment includes the electrode 551X, the electrode 552X, the unit 103X, and the layer 104X. The electrode 552X overlaps with the electrode 551X, and the unit 103X is sandwiched between the electrode 551X and the electrode 552X. The layer 104X is sandwiched between the electrode 551X and the unit 103X. For example, the structure described in Embodiment 2 can be employed for the unit 103X.

### <Structure Example of Electrode 551X>

A conductive material can be used for the electrode 551X, for example. Specifically, a single layer or a stack using a film containing a metal, an alloy, or a conductive compound can be used for the electrode 551X.

A film that efficiently reflects light can be used for the electrode 551X, for example. Specifically, a film of an alloy containing silver, copper, and the like, a film of an alloy containing silver, palladium, and the like, or a film of a metal such as aluminum can be used for the electrode 551X.

For example, a metal film that transmits part of light and reflects the other part of light can be used for the electrode 551X. Thus, a microcavity structure (microcavity) can be provided in the light-emitting device 550X. Alternatively, light with a predetermined wavelength can be extracted more efficiently than other light. Alternatively, light with a narrow spectral half-width can be extracted. Alternatively, light of a bright color can be extracted.

A film having a visible-light-transmitting property can be used for the electrode 551X, for example. Specifically, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### <<Structure Example 1 of Layer 104X>>

A material having a hole-injection property can be used for the layer 104X, for example. The layer 104X can be referred to as a hole-injection layer.

For example, a material having a hole mobility lower than or equal to 1×10⁻³ cm²/Vs when the square root of the electric field strength V/cm is 600 can be used for the layer 104X. A film having an electrical resistivity greater than or equal to 1×10⁴ Ω·cm and less than or equal to 1×10⁷ Ω·cm can be used as the layer 104X. The electrical resistivity of the layer 104X is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example 2 of Layer 104X>>

Specifically, a substance having an electron-accepting property can be used for the layer 104X. Alternatively, a composite material containing a plurality of kinds of substances can be used for the layer 104X. This can facilitate the injection of holes from the electrode 551X, for example. Alternatively, the driving voltage of the light-emitting device 550X can be reduced.

### [Substance Having Electron-Accepting Property]

An organic compound or an inorganic compound can be used as the substance having an electron-accepting property. The substance having an electron-accepting property can extract electrons from an adjacent hole-transport layer or a material having a hole-transport property by application of an electric field.

For example, a compound having an electron-withdrawing group (a halogen group or a cyano group) can be used as the substance having an electron-accepting property. Note that an organic compound having an electron-accepting property is easily evaporated, which facilitates film formation. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylen-1,3,4,5,6,8,9,10-octafluoro-7H-pyren-2-ylidene) malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferable.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′, α″-1,2,3-cyclopropanetriylidenetris[2,3,4,5,6-pentafluorobenzeneacetonitrile], or the like can be used.

For the substance having an electron-accepting property, a transition metal oxide such as a molybdenum oxide, a vanadium oxide, a ruthenium oxide, a tungsten oxide, or a manganese oxide can be used.

It is possible to use any of the following materials: phthalocyanine-based compounds such as phthalocyanine (abbreviation: H₂Pc); phthalocyanine-based complex compounds such as copper phthalocyanine (abbreviation: CuPc); and compounds having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

It is also possible to use a high molecule such as poly(3,4-ethylenedioxythiophene)/polystyrenesulfonic acid (abbreviation: PEDOT/PSS), for example.

### [Structure Example 1 of Composite Material]

For example, a composite material containing a substance having an electron-accepting property and a material having a hole-transport property can be used for the layer 104X. Accordingly, not only a material having a high work function but also a material having a low work function can be used for the electrode 551X. Alternatively, a material used for the electrode 551X can be selected from a wide range of materials regardless of its work function.

For the material having a hole-transport property in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility higher than or equal to 1×10⁻⁶ cm²/Vs can be suitably used as the material having a hole-transport property in the composite material. For example, a material having a hole-transport property that can be used for the layer 112X can be used for the composite material.

A substance having a relatively deep HOMO level can be suitably used for the material having a hole-transport property in the composite material. Specifically, the HOMO level is preferably higher than or equal to −5.7 eV and lower than or equal to −5.4 eV. Accordingly, hole injection to the unit 103X can be facilitated. Hole injection to the layer 112X can be facilitated. The reliability of the light-emitting device 550X can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl) biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl) anthracene (abbreviation: t-BuDNA), 2-tert-butyl-9,10-di(1-naphthyl) anthracene, 9,10-bis(3,5-diphenylphenyl) anthracene (abbreviation: DPPA), 2-tert-butyl-9,10-bis(4-phenylphenyl) anthracene (abbreviation: t-BuDBA), 9,10-di(2-naphthyl) anthracene (abbreviation: DNA), 9,10-diphenylanthracene (abbreviation: DPAnth), 2-tert-butylanthracene (abbreviation: t-BuAnth), 9,10-bis(4-methyl-1-naphthyl) anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl) anthracene, 2,3,6,7-tetramethyl-9,10-di(2-naphthyl) anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl) perylene, pentacene, or coronene can be used.

As the aromatic hydrocarbon having a vinyl group, for example, 4,4′-bis(2,2-diphenylvinyl) biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl) methacrylamide](abbreviation: PTPDMA), or poly[N,N-bis(4-butylphenyl)-N,N-bis(phenyl)benzidine](abbreviation: Poly-TPD) can be used.

Furthermore, a substance having any of a carbazole skeleton, a dibenzofuran skeleton, a dibenzothiophene skeleton, and an anthracene skeleton can be suitably used as the material having a hole-transport property in the composite material, for example. Moreover, a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group can be used as the material having a hole-transport property in the composite material. With the use of a substance having an N,N-bis(4-biphenyl)amino group, the reliability of the light-emitting device 550X can be increased.

Examples of the above-described materials include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf (6)), N,N-bis(4-biphenyl)benzo[b]naphtho[1,2-d]furan-8-amine (abbreviation: BBABnf (8)), N,N-bis(4-(abbreviation: BBABnf (II) (4)), N,N-bis[4-biphenyl)benzo[b]naphtho[2,3-d]furan-4-amine (dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6; l′-binaphthyl-2-yl)triphenylamine (abbreviation: BBAαNβNB), 4,4′-diphenyl-4″-(7; 1′-binaphthyl-2-yl)triphenylamine (abbreviation: BBAαNβNB-03), 4,4′-diphenyl-4″-(7-phenyl) naphthyl-2-yl)triphenylamine (abbreviation: BBAPβNB-03), 4,4′-diphenyl-4″-(6; 2′-binaphthyl-2-yl)triphenylamine (abbreviation: BBA (βN2) B), 4,4′-diphenyl-4″-(7; 2′-binaphthyl-2-yl)triphenylamine (abbreviation: BBA (βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl) biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBilBP-02), 4-[4′-(carbazol-9-yl) biphenyl-4-yl]-4′-(2-naphthyl)-4″-phenyltriphenylamine (abbreviation: YGTBiBNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF (4)), N-(biphenyl-2-yl)-N-(9,9-dimethyl-9H-fluoren-2-yl)-9,9′-spirobi[9H-fluoren]-4-amine (abbreviation: OFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### [Structure Example 2 of Composite Material]

For example, a composite material containing a substance having an electron-accepting property, a material having a hole-transport property, and a fluoride of an alkali metal or a fluoride of an alkaline earth metal can be used as the material having a hole-injection property. In particular, a composite material in which the proportion of fluorine atoms is higher than or equal to 20% can be suitably used. Thus, the refractive index of the layer 104X can be reduced. A layer with a low refractive index can be formed inside the light-emitting device 550X. Alternatively, the external quantum efficiency of the light-emitting device 550X can be improved.

Note that this embodiment can be combined with any of the other embodiments described in this specification as appropriate.

### Embodiment 4

In this embodiment, the structure of the light-emitting device 550X of one embodiment of the present invention will be described with reference to FIG. 4A and FIG. 4B.

The structure of the light-emitting device 550X described in this embodiment can be employed for the display device of one embodiment of the present invention. Note that the description of the structure of the light-emitting device 550X can be applied to the light-emitting device 550A. Specifically, the description of the structure of the light-emitting device 550X can be referred to for the description of the light-emitting device 550A by replacing “X” in the reference numerals with “A”. Similarly, the structure of the light-emitting device 550X can be employed for the light-emitting device 550B, the light-emitting device 550C, or the light-emitting device 550D by replacing “X” with “B”, “C”, or “D”.

### <Structure Example of Light-Emitting Device 550X>

The light-emitting device 550X described in this embodiment includes the electrode 551X, the electrode 552X, the unit 103X, and a layer 105X. The electrode 552X includes a region overlapping with the electrode 551X, and the unit 103X includes a region sandwiched between the electrode 551X and the electrode 552X. The layer 105X includes a region sandwiched between the unit 103X and the electrode 552X. For example, the structure described in Embodiment 2 can be employed for the unit 103X.

### <Structure Example of Electrode 552X>

A conductive material can be used for the electrode 552X, for example. Specifically, a single layer or a stack using a material containing a metal, an alloy, or a conductive compound can be used for the electrode 552X.

For example, the material that can be used for the electrode 551X described in Embodiment 3 can be used for the electrode 552X. In particular, a material having a lower work function than the electrode 551X can be suitably used for the electrode 552X. Specifically, a material having a work function lower than or equal to 3.8 eV is preferable.

For example, an element belonging to Group 1 of the periodic table, an element belonging to Group 2 of the periodic table, a rare earth metal, or an alloy containing any of these elements can be used for the electrode 552X.

Specifically, lithium (Li), cesium (Cs), or the like; magnesium (Mg), calcium (Ca), strontium (Sr), or the like; europium (Eu), ytterbium (Yb), or the like; or an alloy containing any of these such as an alloy of magnesium and silver or an alloy of aluminum and lithium can be used for the electrode 552X.

### <<Structure Example of Layer 105X>>

A material having an electron-injection property can be used for the layer 105X, for example. The layer 105X can be referred to as an electron-injection layer.

Specifically, a substance having an electron-donating property can be used for the layer 105X. Alternatively, a material in which a substance having an electron-donating property and a material having an electron-transport property are combined can be used for the layer 105X. Alternatively, electride can be used for the layer 105X. This can facilitate injection of electrons from the electrode 552X, for example. Alternatively, not only a material having a low work function but also a material having a high work function can be used for the electrode 552X. Alternatively, a material used for the electrode 552X can be selected from a wide range of materials regardless of its work function. Specifically, Al, Ag, ITO, indium oxide-tin oxide containing silicon or silicon oxide, or the like can be used for the electrode 552X. Alternatively, the driving voltage of the light-emitting device 550X can be reduced.

### [Substance Having Electron-Donating Property]

For example, an alkali metal, an alkaline earth metal, a rare earth metal, or a compound thereof (an oxide, a halide, a carbonate, or the like) can be used as the substance having an electron-donating property. Alternatively, an organic compound such as tetrathianaphthacene (abbreviation: TTN), nickelocene, or decamethylnickelocene can be used as the substance having an electron-donating property.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material in which a plurality of kinds of substances are combined can be used as the material having an electron-injection property. For example, a substance having an electron-donating property and a material having an electron-transport property can be used as the composite material.

### [Material Having Electron-Transport Property]

A material having an electron mobility higher than or equal to 1×10⁻⁷ cm²/Vs and lower than or equal to 5×10⁻⁵ cm²/Vs in a condition where the square root of the electric field strength V/cm is 600 can be suitably used as the material having an electron-transport property. Accordingly, the amount of electrons injected into the light-emitting layer can be controlled. Alternatively, the light-emitting layer can be prevented from having excess electrons.

A metal complex or an organic compound having a π-electron deficient heteroaromatic ring skeleton can be used as the material having an electron-transport property. For example, the material having an electron-transport property that can be used for the layer 113X can be used for the layer 105X.

### [Structure Example 2 of Composite Material]

A material including a fluoride of an alkali metal in a microcrystalline state and a material having an electron-transport property can be used as the composite material. Alternatively, a material including a fluoride of an alkaline earth metal in a microcrystalline state and a material having an electron-transport property can be used as the composite material. In particular, a composite material including a fluoride of an alkali metal or a fluoride of an alkaline earth metal at higher than or equal to 50 wt % can be suitably used. Alternatively, a composite material including an organic compound having a bipyridine skeleton can be suitably used. In that case, the refractive index of the layer 105X can be reduced. Alternatively, the external quantum efficiency of the light-emitting device 550X can be improved.

### [Structure Example 3 of Composite Material]

For example, a composite material containing a first organic compound having an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound having an unshared electron pair interacts with the first metal and thus can form a singly occupied molecular orbital (SOMO). Furthermore, in the case where electrons are injected from the electrode 552X into the layer 105X, a barrier therebetween can be lowered.

For the layer 105X, it is possible to use a composite material in which the spin density measured by an electron spin resonance method (ESR) is preferably higher than or equal to 1×10¹⁶ spins/cm³, further preferably higher than or equal to 5×10¹⁶ spins/cm³, still further preferably higher than or equal to 1×10¹⁷ spins/cm³.

### [Organic Compound Having Unshared Electron Pair]

For example, a material having an electron-transport property can be used as the organic compound having an unshared electron pair. For example, a compound having an electron deficient heteroaromatic ring can be used. Specifically, a compound having at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the lowest unoccupied molecular orbital (LUMO) level of the organic compound having an unshared electron pair is preferably higher than or equal to −3.6 eV and lower than or equal to −2.3 eV. In general, the HOMO level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(2-naphthyl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl) biphenyl-3-yl]-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound having an unshared electron pair. Note that NBPhen has a higher glass transition temperature (Tg) than BPhen and thus has high heat resistance.

Alternatively, for example, copper phthalocyanine can be used as the organic compound having an unshared electron pair. The number of electrons of the copper phthalocyanine is an odd number.

### [First Metal]

In the case where the number of electrons of the first organic compound having an unshared electron pair is an even number, for example, a composite material of a metal that belongs to an odd-numbered group in the periodic table and the first organic compound can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, and aluminum (Al) and indium (In), which are metals belonging to Group 13, are elements belonging to odd-numbered groups in the periodic table. Note that elements belonging to Group 11 have lower melting points than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

In the case where the number of electrons of the first organic compound having an unshared electron pair is an odd number, a composite material of the first metal that belongs to an even-numbered group in the periodic table and the first organic compound can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed, or the like can be used as the material having an electron-injection property.

Note that this embodiment can be combined with any of the other embodiments described in this specification as appropriate.

### Embodiment 5

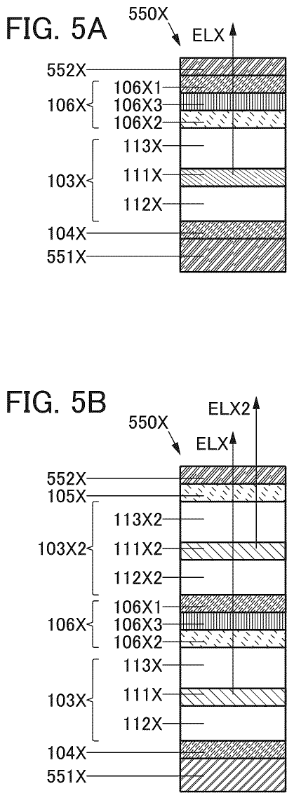

In this embodiment, the structure of the light-emitting device 550X of one embodiment of the present invention will be described with reference to FIG. 5A.

FIG. 5A is a cross-sectional view illustrating the structure of the light-emitting device of one embodiment of the present invention.

The structure of the light-emitting device 550X described in this embodiment can be employed for the display device of one embodiment of the present invention. Note that the description of the structure of the light-emitting device 550X can be applied to the light-emitting device 550A. Specifically, the description of the structure of the light-emitting device 550X can be referred to for the description of the light-emitting device 550A by replacing “X” in the reference numerals with “A”. Similarly, the structure of the light-emitting device 550X can be employed for the light-emitting device 550B, the light-emitting device 550C, or the light-emitting device 550D by replacing “X” with “B”, “C”, or “D”.

### <Structure Example of Light-Emitting Device 550X>

The light-emitting device 550X described in this embodiment includes the electrode 551X, the electrode 552X, the unit 103X, and an intermediate layer 106X (see FIG. 5A). The electrode 552X includes a region overlapping with the electrode 551X, and the unit 103X includes a region sandwiched between the electrode 551X and the electrode 552X. The intermediate layer 106X includes a region sandwiched between the electrode 552X and the unit 103X.

### <<Structure Example 1 of Intermediate Layer 106X>>

The intermediate layer 106X has a function of supplying electrons to the anode side and supplying holes to the cathode side when voltage is applied. The intermediate layer 106X can be referred to as a charge-generation layer.

A material having a hole-injection property that can be used for the layer 104X described in Embodiment 3 can be used for the intermediate layer 106X, for example. Specifically, a composite material can be used for the intermediate layer 106X.

For another example, a stacked film in which a film containing the composite material and a film containing a material having a hole-transport property are stacked can be used as the intermediate layer 106X. Note that the film containing a material having a hole-transport property is sandwiched between the film containing the composite material and the cathode.

### <<Structure Example 2 of Intermediate Layer 106X>>

A stacked film in which a layer 106X1 and a layer 106X2 are stacked can be used as the intermediate layer 106X. The layer 106X1 includes a region sandwiched between the unit 103X and the electrode 552X, and the layer 106X2 includes a region sandwiched between the unit 103X and the layer 106X1.

### <<Structure Example of Layer 106X1>>

For example, a material having a hole-injection property that can be used for the layer 104X described in Embodiment 3 can be used for the layer 106X1. Specifically, a composite material can be used for the layer 106X1. A film having an electrical resistivity greater than or equal to 1×10⁴ Ω·cm and less than or equal to 1×10⁷ Ω·cm can be used as the layer 106X1. The electrical resistivity of the layer 106X1 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example of Layer 106X2>>

For example, a material that can be used for the layer 105X described in Embodiment 4 can be used for the layer 106X2.

### <<Structure Example 3 of Intermediate Layer 106X>>

A stacked film in which the layer 106X1, the layer 106X2, and a layer 106X3 are stacked can be used as the intermediate layer 106X. The layer 106X3 includes a region sandwiched between the layer 106X1 and the layer 106X2.

### <<Structure Example of Layer 106X3>>

For example, a material having an electron-transport property can be used for the layer 106X3. The layer 106X3 can be referred to as an electron-relay layer. With the use of the layer 106X3, a layer that is in contact with the anode side of the layer 106X3 can be distanced from a layer that is in contact with the cathode side of the layer 106X3. It is possible to reduce interaction between the layer in contact with the anode side of the layer 106X3 and the layer in contact with the cathode side of the layer 106X3. Electrons can be smoothly supplied to the layer in contact with the anode side of the layer 106X3.

A substance whose LUMO level is positioned between the LUMO level of a substance having an electron-accepting property contained in the layer 106X1 and the LUMO level of a substance contained in the layer 106X2 can be suitably used for the layer 106X3.

For example, a material that has a LUMO level higher than or equal to −5.0 eV, preferably higher than or equal to −5.0 eV and lower than or equal to −3.0 eV can be used for the layer 106X3.

Specifically, a phthalocyanine-based material can be used for the layer 106X3. For example, copper phthalocyanine (abbreviation: CuPc) or a metal complex having a metal-oxygen bond and an aromatic ligand can be used for the layer 106X3.

Note that this embodiment can be combined with any of the other embodiments described in this specification as appropriate.

### Embodiment 6

In this embodiment, the structure of the light-emitting device 550X of one embodiment of the present invention will be described with reference to FIG. 5B.

FIG. 5B is a cross-sectional view illustrating a structure of the light-emitting device of one embodiment of the present invention, which is different from the structure illustrated in FIG. 5A.

The structure of the light-emitting device 550X described in this embodiment can be employed for the display device of one embodiment of the present invention. Note that the description of the structure of the light-emitting device 550X can be applied to the light-emitting device 550A. Specifically, the description of the structure of the light-emitting device 550X can be referred to for the description of the light-emitting device 550A by replacing “X” in the reference numerals with “A”. Similarly, the structure of the light-emitting device 550X can be employed for the light-emitting device 550B, the light-emitting device 550C, or the light-emitting device 550D by replacing “X” with “B”, “C”, or “D”.

### <Structure Example of Light-Emitting Device 550X>

The light-emitting device 550X described in this embodiment includes the electrode 551X, the electrode 552X, the unit 103X, the intermediate layer 106X, and a unit 103X2 (see FIG. 5B).

The unit 103X is sandwiched between the electrode 552X and the electrode 551X, and the intermediate layer 106X is sandwiched between the electrode 552X and the unit 103X.

The unit 103X2 is sandwiched between the electrode 552X and the intermediate layer 106X. The unit 103X2 has a function of emitting light ELX2.

In other words, the light-emitting device 550X includes the stacked units between the electrode 551X and the electrode 552X. Note that the number of stacked units is not limited to two, and three or more units can be stacked. A structure including the stacked units sandwiched between the electrode 551X and the electrode 552X and the intermediate layer 106X sandwiched between the units is referred to as a stacked light-emitting device or a tandem light-emitting device in some cases.

This structure can provide light emission at high luminance while the current density is kept low. Alternatively, the reliability can be improved. Alternatively, the driving voltage can be reduced as compared with other structures with the same luminance. Alternatively, the power consumption can be reduced.

### <<Structure Example 1 of Unit 103X2>>

The unit 103X2 includes a layer 111X2, a layer 112X2, and a layer 113X2. The layer 111X2 is sandwiched between the layer 112X2 and the layer 113X2.

The structure that can be employed for the unit 103X can be employed for the unit 103X2. For example, the same structure as the unit 103X can be employed for the unit 103X2.

### <<Structure Example 2 of Unit 103X2>>

A structure different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. Accordingly, a light-emitting device that emits light of a desired color can be provided. For example, a light-emitting device that emits white light can be provided.

### <<Structure Example of Intermediate Layer 106X>>

The intermediate layer 106X has a function of supplying electrons to one of the unit 103X and the unit 103X2 and supplying holes to the other. For example, the intermediate layer 106X described in Embodiment 5 can be used.

### <Method for Fabricating Light-Emitting Device 550X>

For example, each layer of the electrode 551X, the electrode 552X, the unit 103X, the intermediate layer 106X, and the unit 103X2 can be formed by a dry process, a wet process, an evaporation method, a droplet discharge method, a coating method, a printing method, or the like. Different methods can be used to form the components.

Specifically, the light-emitting device 550X can be fabricated with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. An indium oxide-zinc oxide film can be formed by a sputtering method using a target obtained by adding, to indium oxide, zinc oxide at higher than or equal to 1 wt % and lower than or equal to 20 wt %. An indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 7

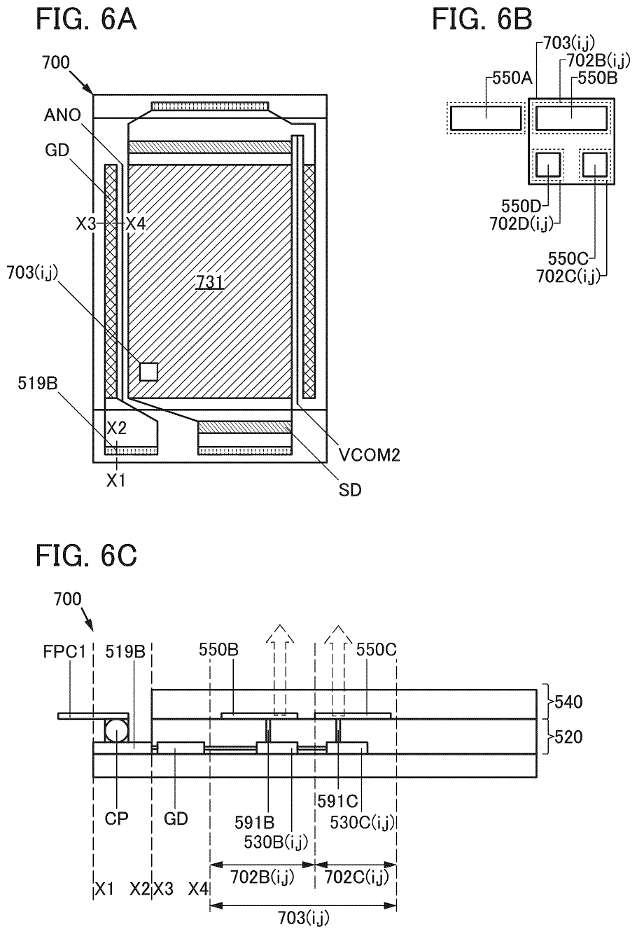

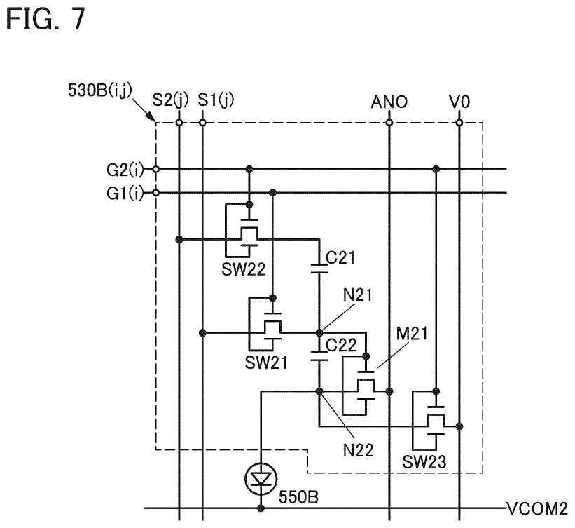

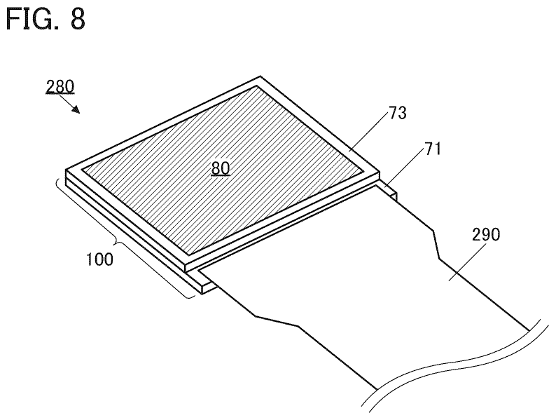

In this embodiment, a structure of a device of one embodiment of the present invention will be described with reference to FIG. 6 and FIG. 7.

FIG. 6 is a diagram illustrating the structure of the device of one embodiment of the present invention. FIG. 6A is a top view of the device of one embodiment of the present invention, and FIG. 6B is a top view illustrating part of FIG. 6A. FIG. 6C is a cross-sectional view taken along the cutting line X1-X2 and the cutting line X3-X4 in FIG. 6A and a cross-sectional view of a pixel set 703 (i,j).

FIG. 7 is a circuit diagram illustrating the structure of the device of one embodiment of the present invention.

Note that in this specification, an integer variable of 1 or more is sometimes used in reference numerals. For example, (p) where p is an integer variable of 1 or more is sometimes used in part of a reference numeral that specifies any of p components at a maximum. For another example, (m,n) where m and n are each an integer variable of 1 or more is sometimes used in part of a reference numeral that specifies any of m×n components at a maximum.

### <Structure Example 1 of Display Device 700>

The display device 700 of one embodiment of the present invention includes a region 731 (see FIG. 6A). The region 731 includes the pixel set 703 (i,j).

<<Structure Example 1 of Pixel Set 703 (i,j)>>

The pixel set 703 (i,j) includes a pixel 702B (i,j), a pixel 702C (i,j), and a pixel 702D (i,j) (see FIG. 6B and FIG. 6C).

The pixel 702B (i,j) includes a pixel circuit 530B (i,j) and the light-emitting device 550B. The light-emitting device 550B is electrically connected to the pixel circuit 530B (i,j).

For example, the light-emitting device described in any of Embodiment 2 to Embodiment 6 can be used as the light-emitting device 550B.

The pixel 702C (i,j) includes the pixel circuit 530B (i,j) and the light-emitting device 550B, and the light-emitting device 550B is electrically connected to a pixel circuit 530C (i,j). Similarly, the pixel 702D (i,j) includes the light-emitting device 550D.

Note that the display device 700 includes the light-emitting device 550A, and the light-emitting device 550A is adjacent to the light-emitting device 550B (see FIG. 6B). The structure of the display device 700 described in Embodiment 1 can be employed for the light-emitting device 550A, the light-emitting device 550B, the light-emitting device 550C, and the light-emitting device 550D, for example.

### <Structure Example 2 of Display Device 700>

The display device 700 of one embodiment of the present invention includes a functional layer 540 and the functional layer 520 (see FIG. 6C). The functional layer 540 overlaps with the functional layer 520.

The functional layer 540 includes the light-emitting device 550B.

The functional layer 520 includes the pixel circuit 530B (i,j) and a wiring (see FIG. 6C). The pixel circuit 530B (i,j) is electrically connected to the wiring. For example, a conductive film provided in an opening portion 591B in the functional layer 520 can be used for the wiring, and the wiring electrically connects a terminal 519B to the pixel circuit 530B (i,j). Note that a conductive material CP electrically connects the terminal 519B to a flexible printed circuit FPC1. For another example, a conductive film provided in an opening portion 591C in the functional layer 520 can be used for the wiring.

### <Structure Example 3 of Display Device 700>

The display device 700 of one embodiment of the present invention includes a driver circuit GD and a driver circuit SD (see FIG. 6A).

### <<Structure Example of Driver Circuit GD>>

The driver circuit GD supplies a first selection signal and a second selection signal.

### <<Structure Example of Driver Circuit SD>>

The driver circuit SD supplies a first control signal and a second control signal.

### <<Structure Example 1 of Wiring>>

As wirings, a conductive film G1 (i), a conductive film G2 (i), a conductive film S1 (j), a conductive film S2 (j), a conductive film ANO, a conductive film VCOM2, and a conductive film VO are included (see FIG. 7).

The conductive film G1 (i) is supplied with the first selection signal, and the conductive film G2 (i) is supplied with the second selection signal.

The conductive film S1 (j) is supplied with the first control signal, and the conductive film S2 (j) is supplied with the second control signal.

<<Structure Example 1 of Pixel Circuit 530B (i,j)>>

The pixel circuit 530B (i,j) is electrically connected to the conductive film G1 (i) and the conductive film S1 (j). The conductive film G1 (i) supplies the first selection signal, and the conductive film S1 (j) supplies the first control signal.

The pixel circuit 530B (i,j) drives the light-emitting device 550B in response to the first selection signal and the first control signal. The light-emitting device 550B emits light.

One electrode of the light-emitting device 550B is electrically connected to the pixel circuit 530B (i,j), and the other electrode is electrically connected to the conductive film VCOM2.

<<Structure Example 2 of Pixel Circuit 530B (i,j)>>

The pixel circuit 530B (i,j) includes a switch SW21, a switch SW22, a transistor M21, a capacitor C21, and a node N21.

The transistor M21 includes a gate electrode electrically connected to the node N21, a first electrode electrically connected to the light-emitting device 550B, and a second electrode electrically connected to the conductive film ANO.

The switch SW21 includes a first terminal electrically connected to the node N21, a second terminal electrically connected to the conductive film S1 (j), and a gate electrode having a function of controlling the conduction state or the non-conduction state on the basis of the potential of the conductive film G1 (i).

The switch SW22 includes a first terminal electrically connected to the conductive film S2 (j) and a gate electrode having a function of controlling the conduction state or the non-conduction state on the basis of the potential of the conductive film G2 (i).

The capacitor C21 includes a conductive film electrically connected to the node N21 and a conductive film electrically connected to a second electrode of the switch SW22.

Thus, an image signal can be stored in the node N21. Alternatively, the potential of the node N21 can be changed using the switch SW22. Alternatively, the intensity of light emitted from the light-emitting device 550B can be controlled with the potential of the node N21. As a result, a novel device that is highly convenient, useful, or reliable can be provided.

<<Structure Example 3 of Pixel Circuit 530B (i,j)>>

The pixel circuit 530B (i,j) includes a switch SW23, a node N22, and a capacitor C22.

The switch SW23 includes a first terminal electrically connected to the conductive film VO, a second terminal electrically connected to the node N22, and a gate electrode having a function of controlling the conduction state or the non-conduction state on the basis of the potential of the conductive film G2 (i).

The capacitor C22 includes a conductive film electrically connected to the node N21 and a conductive film electrically connected to the node N22.

Note that the first electrode of the transistor M21 is electrically connected to the node N22.

Note that this embodiment can be combined with any of the other embodiments described in this specification as appropriate.

### Embodiment 8

In this embodiment, a display module of one embodiment of the present invention will be described.

### <Display Module>

FIG. 8 is a perspective view illustrating a structure of a display module 280.

The display module 280 includes a display device 100A and an FPC 290 or a connector. The FPC 290 is supplied with a data signal, a power supply potential, or the like from the outside and supplies the data signal, the power supply potential, or the like to the display device 100A. An IC may be mounted on the FPC 290. Note that a connector is a mechanical component for electrical connection through a conductor, and the conductor can electrically connect a display device 100 to a component to be connected. For example, the FPC 290 can be used as the conductor. The connector can detach the display device 100A from the connected component.

### <<Display Device 100A>>

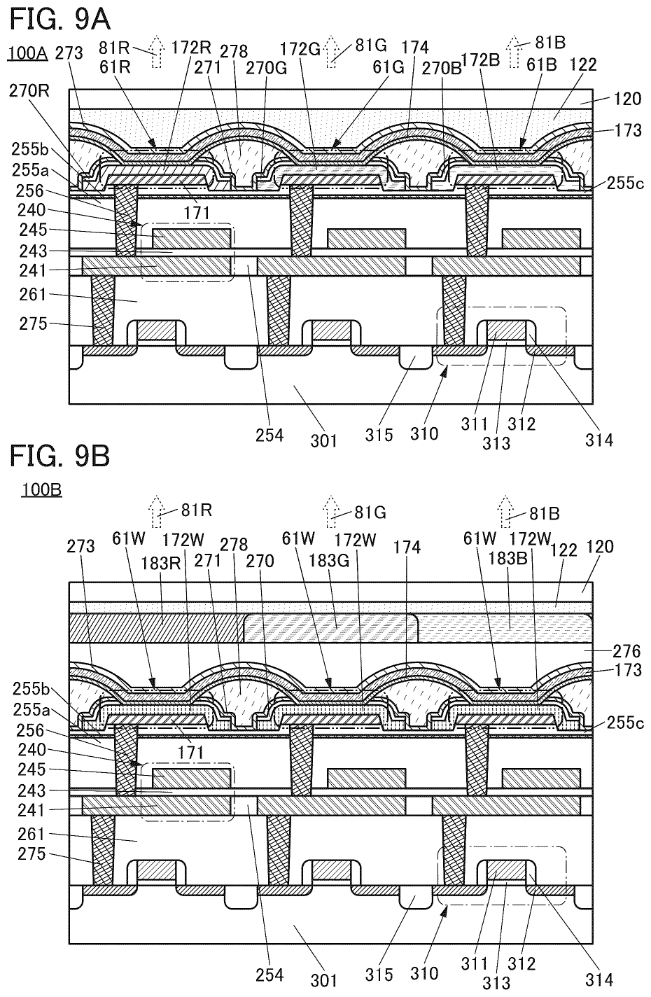

FIG. 9A is a cross-sectional view illustrating a structure of the display device 100A. The display device 100A can be used as the display device 100 of the display module 280, for example. A substrate 301 corresponds to a substrate 71 in FIG. 8.

The display device 100A includes the substrate 301, a transistor 310, an element isolation layer 315, an insulating layer 261, a capacitor 240, an insulating layer 255a, an insulating layer 255b, a light-emitting device 61R, a light-emitting device 61G, and a light-emitting device 61B. The insulating layer 261 is provided over a substrate 301A, and the transistor 310 is positioned between the substrate 301 and the insulating layer 261. The insulating layer 255a is provided over the insulating layer 261, the capacitor 240 is positioned between the insulating layer 261 and the insulating layer 255a, and the insulating layer 255a is positioned between the light-emitting device 61R and the capacitor 240, between the light-emitting device 61G and the capacitor 240, and between the light-emitting device 61B and the capacitor 240.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that the regions function as a source and a drain. The side surface of the conductive layer 311 is covered with the insulating layer 314.

The element isolation layer 315 is embedded in the substrate 301 and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

### [Insulating Film 255]

An insulating layer 255 includes the insulating layer 255a, the insulating layer 255b, and an insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting device 61R, the light-emitting device 61G, and the light-emitting device 61B are provided over the insulating layer 255c. For example, the light-emitting device described in Embodiment 1 can be used as any of the light-emitting device 61R, the light-emitting device 61G, and the light-emitting device 61B.

The light-emitting device 61R includes a conductive layer 171 and an EL layer 172R, and the EL layer 172R covers the top surface and the side surface of the conductive layer 171. A sacrificial layer 270R is positioned over the EL layer 172R. The light-emitting device 61G includes the conductive layer 171 and an EL layer 172G, and the EL layer 172G covers the top surface and the side surface of the conductive layer 171. A sacrificial layer 270G is positioned over the EL layer 172G. The light-emitting device 61B includes the conductive layer 171 and an EL layer 172B, and the EL layer 172B covers the top surface and the side surface of the conductive layer 171. A sacrificial layer 270B is positioned over the EL layer 172B.

The conductive layer 171 is electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

### [Protective Layer 271, Insulating Layer 278, Protective Layer 273, and Bonding Layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting device 61R, the light-emitting device 61G, and the light-emitting device 61B.

A bonding layer 122 attaches the protective layer 273 to a substrate 120.

### [Substrate 120]

The substrate 120 corresponds to a substrate 73 in FIG. 8. A light-blocking layer can be provided on the surface of the substrate 120 on the bonding layer 122 side, for example. A variety of optical members can be provided on the outer side of the substrate 120.

A film can be used as the substrate. In particular, a film with a low water absorption rate can be suitably used. For example, the water absorption rate is preferably lower than or equal to 1%, further preferably lower than or equal to 0.1%. Thus, a change in size of the film can be inhibited. Furthermore, generation of wrinkles or the like can be inhibited. Moreover, a change in shape of the display device can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, in other words, a material with a low birefringence index, is used for the substrate and a circularly polarizing plate is provided to overlap with the display device. For example, it is possible to use, for the substrate, a material that has an absolute value of a retardation (phase difference) less than or equal to 30 nm, preferably less than or equal to 20 nm, further preferably less than or equal to 10 nm. For example, a triacetyl cellulose (TAC, also referred to as cellulose triacetate) film, a cycloolefin polymer (COP) film, a cycloolefin copolymer (COC) film, an acrylic resin film, or the like can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiOₓ layer), DLC (diamond-like carbon), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### <<Display Device 100B>>

FIG. 9B is a cross-sectional view illustrating a structure of a display device 100B. The display device 100B can be used as the display device 100 of the display module 280, for example (see FIG. 8).

The display device 100B includes the substrate 301, a light-emitting device 61W, the capacitor 240, and the transistor 310. The light-emitting device 61W can emit white light, for example.

The display device 100B includes a coloring layer 183R, a coloring layer 183G, and a coloring layer 183B. The coloring layer 183R includes a region overlapping with one light-emitting device 61W, the coloring layer 183G includes a region overlapping with another light-emitting device 61W, and the coloring layer 183B includes a region overlapping with another light-emitting device 61W.

For example, the coloring layer 183R can transmit red light, the coloring layer 183G can transmit green light, and the coloring layer 183B can transmit blue light.

### <<Display Device 100C>>

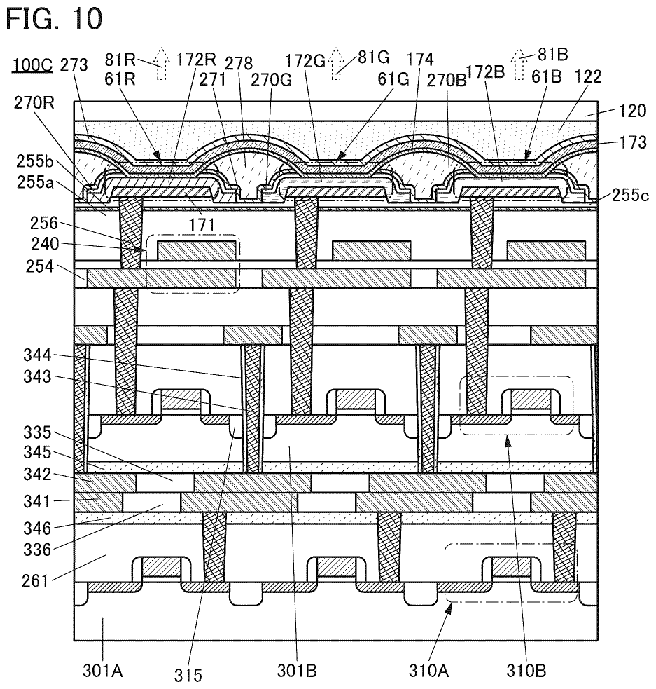

FIG. 10 is a cross-sectional view illustrating a structure of a display device 100C. The display device 100C can be used as the display device 100 of the display module 280, for example (see FIG. 8). Note that in the following description of display devices, the description of portions similar to those of the above-described display devices may be omitted.

The display device 100C includes a substrate 301B and the substrate 301A. The display device 100C includes a transistor 310B, the capacitor 240, the light-emitting device 61R, the light-emitting device 61G, the light-emitting device 61B, and a transistor 310A. A channel of the transistor 310A is formed in part of the substrate 301A, and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, an inorganic insulating film that can be used as the protective layer 273 can be used as the insulating layer 345 and the insulating layer 346. The insulating layer 345 and the insulating layer 346 function as protective layers and can inhibit a phenomenon in which impurities diffuse into the substrate 301B and the substrate 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit a phenomenon in which impurities diffuse into the substrate 301B.

### [Conductive Layer 342]

A conductive layer 342 is positioned between the insulating layer 345 and the insulating layer 346. The conductive layer 342 is embedded in an insulating layer 335, and a plane formed by the conductive layer 342 and the insulating layer 335 is preferably planarized. Note that the conductive layer 342 is electrically connected to the plug 343.

### [Conductive Layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be planarized. The conductive layer 341 is bonded to the conductive layer 342. Thus, the substrate 301A is electrically connected to the substrate 301B.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layer 341 and the conductive layer 342. In that case, it is possible to employ a Cu-to-Cu (copper-to-copper) direct bonding technique (a technique for achieving electrical continuity by connecting Cu (copper) pads).

### <<Display Device 100D>>

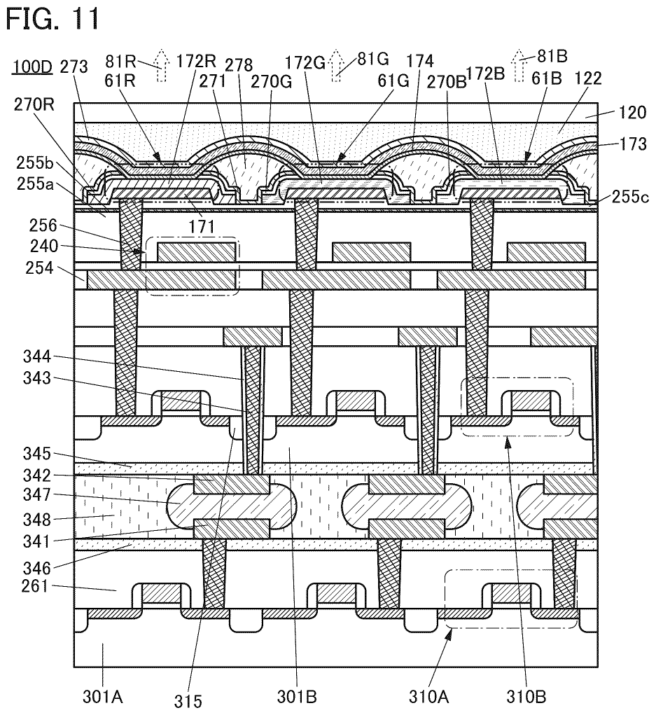

FIG. 11 is a cross-sectional view illustrating a structure of a display device 100D. The display device 100D can be used as the display device 100 of the display module 280, for example (see FIG. 8).

The display device 100D includes a bump 347, and the bump 347 bonds the conductive layer 341 to the conductive layer 342. The bump 347 electrically connects the conductive layer 341 to the conductive layer 342. A conductive material containing gold (Au), nickel (Ni), indium (In), tin (Sn), or the like can be used for the bump 347, for example. Solder can be used for the bump 347, for example.

The display device 100D includes a bonding layer 348. The bonding layer 348 attaches the insulating layer 345 to the insulating layer 346.

### <<Display Device 100E>>

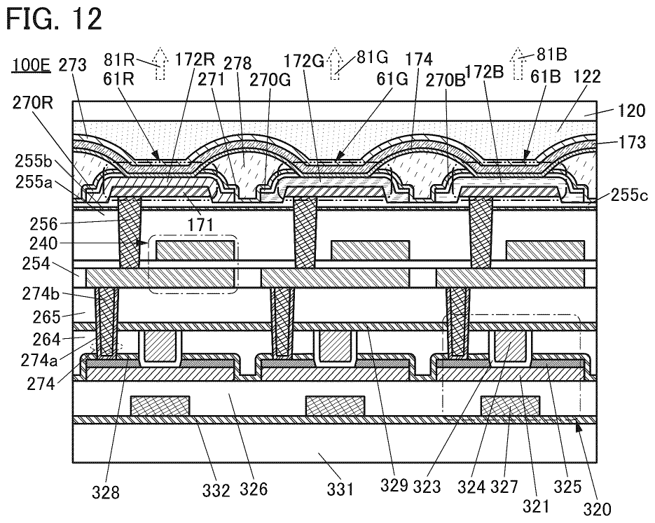

FIG. 12 is a cross-sectional view illustrating a structure of a display device 100E. The display device 100E can be used as the display device 100 of the display module 280, for example (see FIG. 8). A substrate 331 corresponds to the substrate 71 in FIG. 8. An insulating substrate or a semiconductor substrate can be used as the substrate 331. The display device 100E includes a transistor 320. Note that the display device 100E is different from the display device 100A in that the transistor is an OS transistor.

### [Insulating Layer 332]

An insulating layer 332 is provided over the substrate 331. For example, a film in which hydrogen or oxygen is less likely to diffuse than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent a phenomenon in which impurities such as water and hydrogen diffuse from the substrate 331 into the transistor 320. Furthermore, oxygen can be prevented from being released from a semiconductor layer 321 to the insulating layer 332 side.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332, and the conductive layer 327 functions as a first gate electrode of the transistor 320. The insulating layer 326 covers the conductive layer 327. Part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a planarized top surface. The semiconductor layer 321 is provided over the insulating layer 326. A metal oxide film having semiconductor characteristics can be used as the semiconductor layer 321. The pair of conductive layers 325 is provided over and in contact with the semiconductor layer 321, and functions as a source electrode and a drain electrode.

### [Insulating Layer 328 and Insulating Layer 264]

An insulating layer 328 covers the top surfaces and side surfaces of the pair of conductive layers 325, the side surface of the semiconductor layer 321, and the like. An insulating layer 264 is provided over the insulating layer 328 and functions as an interlayer insulating layer. The insulating layer 328 and the insulating layer 264 have an opening portion, and the opening portion reaches the semiconductor layer 321. For example, an insulating film similar to the insulating layer 332 can be used as the insulating layer 328. Thus, the insulating layer 328 can prevent a phenomenon in which impurities such as water and hydrogen diffuse from the insulating layer 264 into the semiconductor layer 321, for example. Furthermore, oxygen can be prevented from being released from the semiconductor layer 321.

### [Insulating Layer 323]

The insulating layer 323 is in contact with the side surfaces of the insulating layer 264, the insulating layer 328, and the conductive layer 325 and the top surface of the semiconductor layer 321 inside the opening portion.

### [Conductive Layer 324]

Inside the opening portion, the conductive layer 324 is embedded and in contact with the insulating layer 323. The conductive layer 324 has a top surface subjected to planarization treatment, and is level with or substantially level with the top surface of the insulating layer 323 and the top surface of the insulating layer 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324, the insulating layer 323, and the insulating layer 264. An insulating layer 265 is provided over the insulating layer 329 and functions as an interlayer insulating layer. For example, an insulating film similar to the insulating layer 328 and the insulating layer 332 can be used as the insulating layer 329. Thus, a phenomenon in which impurities such as water and hydrogen diffuse from the insulating layer 265 into the transistor 320 can be prevented, for example.

### [Plug 274]

A plug 274 is embedded in the insulating layer 265, the insulating layer 329, the insulating layer 264, and the insulating layer 328 and is electrically connected to one of the pair of conductive layers 325. The plug 274 includes a conductive layer 274a and a conductive layer 274b. The conductive layer 274a is in contact with the side surface of an opening in the insulating layer 265, the insulating layer 329, the insulating layer 264, and the insulating layer 328. In addition, the conductive layer 274a covers part of the top surface of the conductive layer 325. The conductive layer 274b is in contact with the top surface of the conductive layer 274a. For example, a conductive material in which hydrogen and oxygen are unlikely to diffuse can be suitably used for the conductive layer 274a.

### <<Display Device 100F>>

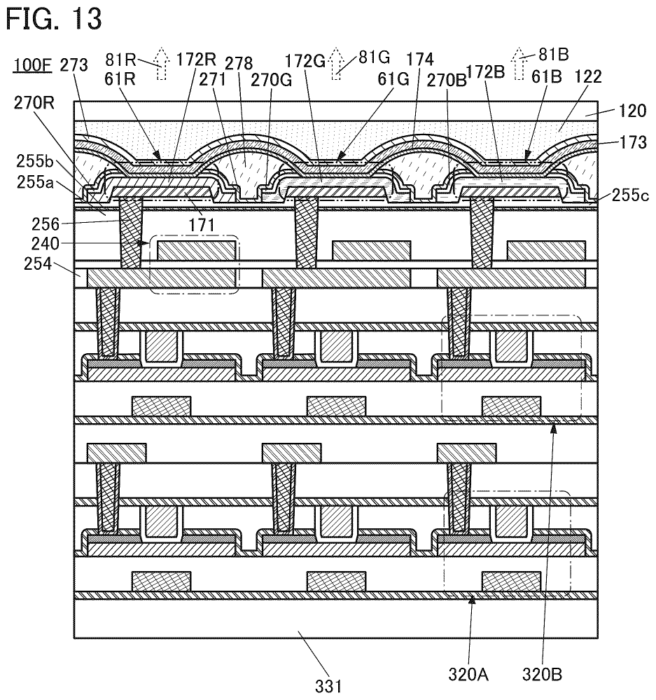

FIG. 13 is a cross-sectional view illustrating a structure of a display device 100F. The display device 100F has a structure in which a transistor 320A and a transistor 320B are stacked. Each of the transistor 320A and the transistor 320B includes an oxide semiconductor and a channel formed in the oxide semiconductor. Note that the structure of the display device 100F is not limited to the structure in which two transistors are stacked, and a structure in which three or more transistors are stacked may be employed, for example.

The structures of the transistor 320A and the peripheral components are the same as the structures of the transistor 320 and the peripheral components of the display device 100E. The structures of the transistor 320B and the peripheral components are the same as the structures of the transistor 320 and the peripheral components of the display device 100E.

### <<Display Device 100G>>

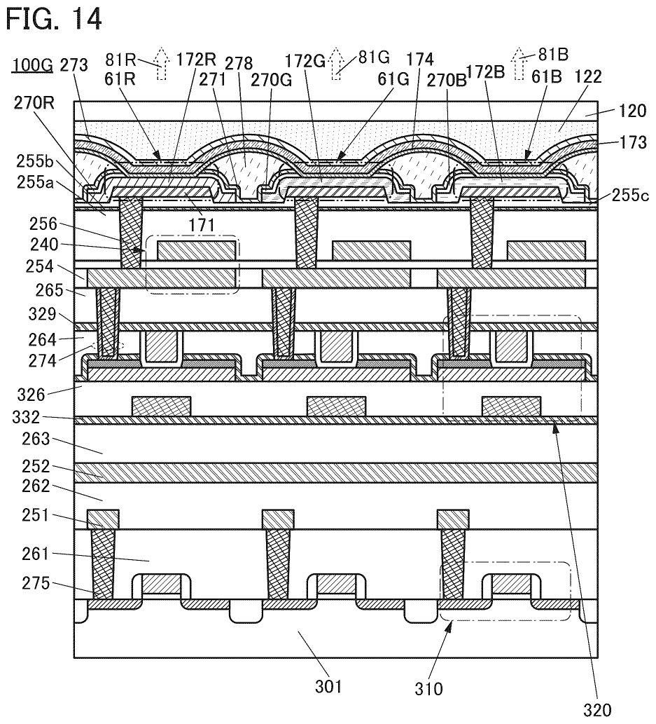

FIG. 14 is a cross-sectional view illustrating a structure of a display device 100G. The display device 100G has a structure in which the transistor 310 and the transistor 320 are stacked. The channel of the transistor 310 is formed in the substrate 301. The transistor 320 includes an oxide semiconductor and its channel is formed in the oxide semiconductor.

The insulating layer 261 covers the transistor 310, and a conductive layer 251 is provided over the insulating layer 261. An insulating layer 262 covers the conductive layer 251, and a conductive layer 252 is provided over the insulating layer 262. An insulating layer 263 and the insulating layer 332 cover the conductive layer 252. The conductive layer 251 and the conductive layer 252 each function as a wiring.

The transistor 320 is provided over the insulating layer 332, and the insulating layer 265 covers the transistor 320. The capacitor 240 is provided over the insulating layer 265, and the capacitor 240 is electrically connected to the transistor 320 through the plug 274.

For example, the transistor 320 can be used as a transistor included in a pixel circuit. For another example, the transistor 310 can be used as a transistor included in a pixel circuit or a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display device can be downsized as compared to the case where a driver circuit is provided around a display region.

At least part of this embodiment can be implemented in combination with the other embodiments described in this specification as appropriate.

### Embodiment 9

In this embodiment, a display device of one embodiment of the present invention will be described.

### <Display Module>

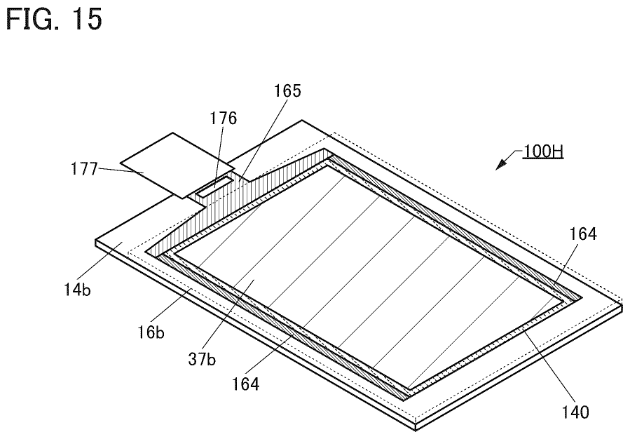

FIG. 15 is a perspective view illustrating a structure of a display module.

The display module includes a display device 100H, an IC (integrated circuit) 176, and an FPC 177 or a connector. The display device 100H is electrically connected to the IC 176 and the FPC 177. The FPC 177 is supplied with a signal and electric power from the outside and supplies the signal and the electric power to the display device 100H. Note that a connector is a mechanical component for electrical connection through a conductor, and the conductor can electrically connect the display device 100H to a component to be connected. For example, the FPC 177 can be used as the conductor. The connector can detach the display device 100H from the connected component.

The display module includes the IC 176. For example, the IC 176 can be provided for a substrate 14b by a COG (Chip On Glass) method or the like. Alternatively, the IC 176 can be provided for an FPC by a COF (Chip On Film) method or the like, for example. Note that a gate driver circuit, a source driver circuit, or the like can be used as the IC 176, for example.

### <<Display Device 100H>>

The display device 100H includes a display portion 37b, a connection portion 140, a circuit 164, a wiring 165, and the like.

FIG. 16A is a cross-sectional view illustrating a structure of the display device 100H. The display device 100H includes a substrate 16b and the substrate 14b, and the substrate 16b and the substrate 14b are attached to each other. The display device 100H includes one or more connection portions 140. The connection portion(s) 140 can be provided outside the display portion 37b. For example, the connection portion(s) 140 can be provided along one side of the display portion 37b. Alternatively, the connection portion(s) 140 can be provided along a plurality of sides, for example, can be provided to surround four sides. In the connection portion 140, a common electrode of a light-emitting device is electrically connected to a conductive layer, and the conductive layer supplies a predetermined potential to the common electrode.

The wiring 165 is supplied with a signal and electric power from the FPC 177 or the IC 176. The wiring 165 supplies a signal and electric power to the display portion 37b and the circuit 164.

For example, a gate driver circuit can be used as the circuit 164.

The display device 100H includes the substrate 14b, the substrate 16b, a transistor 201, a transistor 205, a light-emitting device 63R, a light-emitting device 63G, a light-emitting device 63B, and the like (see FIG. 16A). For example, the light-emitting device 63R emits red light 83R, the light-emitting device 63G emits green light 83G, and the light-emitting device 63B emits blue light 83B. Note that a variety of optical members can be provided outside the substrate 16b. For example, a polarizing plate, a retardation plate, a light diffusion layer (e.g., a diffusion film), an anti-reflection layer, a light-condensing film, or the like can be provided.

For example, the light-emitting device described in Embodiment 1 can be used as each of the light-emitting device 63R, the light-emitting device 63G, and the light-emitting device 63B.

The light-emitting devices include the conductive layer 171, and the conductive layer 171 functions as a pixel electrode. The conductive layer 171 has a depressed portion, and the depressed portion overlaps with an opening portion provided in an insulating layer 214, an insulating layer 215, and an insulating layer 213. The transistor 205 includes a conductive layer 222b, and the conductive layer 222b is electrically connected to the conductive layer 171.

The display device 100H includes an insulating layer 272. The insulating layer 272 covers an end portion of the conductive layer 171 to fill the depressed portion of the conductive layer 171 (see FIG. 16A).

The display device 100H includes the protective layer 273 and a bonding layer 142. The protective layer 273 covers the light-emitting device 63R, the light-emitting device 63G, and the light-emitting device 63B. The protective layer 273 and the substrate 16b are bonded to each other with the bonding layer 142. The bonding layer 142 fills a space between the substrate 16b and the protective layer 273. Note that the bonding layer 142 may be formed in a frame shape so as not to overlap with the light-emitting devices and a region surrounded by the bonding layer 142, the substrate 16b, and the protective layer 273 may be filled with a resin different from the material of the bonding layer 142, for example. Alternatively, a hollow sealing structure may be employed, in which the region is filled with an inert gas (e.g., nitrogen or argon). For example, the material that can be used for the bonding layer 122 can be used for the bonding layer 142.

The display device 100H includes the connection portion 140, and the connection portion 140 includes a conductive layer 168. Note that a power supply potential is supplied to the conductive layer 168. The light-emitting devices include a conductive layer 173, the conductive layer 168 is electrically connected to the conductive layer 173, and a power supply potential is supplied to the conductive layer 173. Note that the conductive layer 173 functions as a common electrode. For example, the conductive layer 171 and the conductive layer 168 can be formed by processing one conductive film.

The display device 100H has a top-emission structure. The light-emitting devices emit light to the substrate 16b side. The conductive layer 171 contains a material reflecting visible light, and the conductive layer 173 transmits visible light.

### [Insulating Layer 211, Insulating Layer 213, Insulating Layer 215, and Insulating Layer 214]

An insulating layer 211, the insulating layer 213, the insulating layer 215, and the insulating layer 214 are provided in this order over the substrate 14b. Note that the number of insulating layers is not limited and may be one or two or more.

For example, an inorganic insulating film can be used as each of the insulating layer 211, the insulating layer 213, and the insulating layer 215. A silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layer 215 and the insulating layer 214 cover the transistors. The insulating layer 214 functions as a planarization layer. For example, a material in which impurities such as water and hydrogen are unlikely to diffuse is preferably used for the insulating layer 215 or the insulating layer 214. This can effectively inhibit a phenomenon in which impurities diffuse into the transistors from the outside. Furthermore, the reliability of the display device can be increased.

For example, an organic insulating layer can be suitably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, a phenomenon in which a depressed portion is formed in the insulating layer 214 at the time of processing the conductive layer 171 into a predetermined shape can be inhibited.

### [Transistor 201 and Transistor 205]

The transistor 201 and the transistor 205 are formed over the substrate 14b. These transistors can be fabricated using the same material in the same process.

Each of the transistor 201 and the transistor 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate, and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate, and the insulating layer 213 functions as a second gate insulating layer. Here, a plurality of layers obtained by processing the same conductive film are shown with the same hatching pattern.

There is no particular limitation on the structure of the transistors included in the display device of this embodiment. For example, a planar transistor, a staggered transistor, an inverted staggered transistor, or the like can be used. A top-gate or bottom-gate transistor structure may be employed. Alternatively, gates may be provided above and below a semiconductor layer where a channel is formed.

The structure in which the semiconductor layer where a channel is formed is provided between two gates is employed for the transistor 201 and the transistor 205. The two gates may be connected to each other and supplied with the same signal to drive the transistor. Alternatively, the threshold voltage of the transistor may be controlled by supplying a potential for controlling the threshold voltage to one of the two gates and a potential for driving to the other.

There is no particular limitation on the crystallinity of the semiconductor layer of each of the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

The semiconductor layer of the transistor preferably contains a metal oxide. That is, an OS transistor is preferably used as the transistor included in the display device of this embodiment.

### [Semiconductor Layer]

For example, indium oxide, gallium oxide, and zinc oxide can be used for the semiconductor layer. The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the metal oxide used for the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

Alternatively, the semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M.

Alternatively, a stacked-layer structure of one selected from indium oxide, indium gallium oxide, and IGZO and one selected from IAZO, IAGZO, and ITZO (registered trademark) may be employed, for example.

Examples of the oxide semiconductor having crystallinity include a CAAC (c-axis-aligned crystalline)-OS and an nc (nanocrystalline)-OS.

Alternatively, a transistor using silicon in its channel formation region (a Si transistor) may be used. Examples of silicon include single crystal silicon, polycrystalline silicon, and amorphous silicon. In particular, a transistor containing low-temperature polysilicon (LTPS) in a semiconductor layer (such a transistor is referred to as an LTPS transistor) can be used. The LTPS transistor has high field-effect mobility and excellent frequency characteristics.

With the use of a Si transistor such as an LTPS transistor, a circuit required to be driven at a high frequency (e.g., a data driver circuit) can be formed on the same substrate as the display portion. Thus, external circuits mounted on the display device can be simplified, and parts costs and mounting costs can be reduced.

An OS transistor has much higher field-effect mobility than a transistor using amorphous silicon. In addition, an OS transistor has extremely low leakage current between a source and a drain in an off state (also referred to as off-state current), and electric charge accumulated in a capacitor that is connected in series to the transistor can be retained for a long period. Furthermore, the power consumption of the display device can be reduced with the use of an OS transistor.

To increase the emission luminance of the light-emitting device included in the pixel circuit, the amount of current flowing through the light-emitting device needs to be increased. For this, it is necessary to increase the source-drain voltage of a driving transistor included in the pixel circuit. Since an OS transistor has a higher withstand voltage between a source and a drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When a transistor is driven in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be minutely determined by controlling the gate-source voltage. Thus, the amount of current flowing through the light-emitting device can be controlled. Consequently, the number of gray levels in the pixel circuit can be increased.

Regarding saturation characteristics of current flowing when a transistor is driven in a saturation region, even in the case where the source-drain voltage of an OS transistor increases gradually, more stable current (saturation current) can be made flow through an OS transistor than through a Si transistor. Thus, by using an OS transistor as the driving transistor, stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the emission luminance of the light-emitting device can be stable.

As described above, with the use of an OS transistor as the driving transistor included in the pixel circuit, it is possible to inhibit black-level degradation, increase the emission luminance, increase the number of gray levels, and inhibit variations in light-emitting devices, for example.

The transistors included in the circuit 164 and the transistors included in a display portion 107 may have the same structure or different structures. The plurality of transistors included in the circuit 164 may have the same structure or two or more kinds of structures. Similarly, the plurality of transistors included in the display portion 107 may have the same structure or two or more kinds of structures.

All the transistors included in the display portion 107 may be OS transistors, or all the transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display device can have low power consumption and high driving capability. A structure in which an LTPS transistor and an OS transistor are used in combination is referred to as LTPO in some cases. For example, it is preferable to use an OS transistor as a transistor functioning as a switch for controlling electrical continuity between wirings and an LTPS transistor as a transistor for controlling current.

For example, one of the transistors included in the display portion 107 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML structure. This structure can significantly reduce leakage current that would flow through the transistor and leakage current that would flow between adjacent light-emitting devices. With the structure, a viewer can notice any one or more of the image crispness, the image sharpness, a high chroma, and a high contrast ratio in an image displayed on the display device. When leakage current that would flow through the transistor and lateral leakage current that would flow between light-emitting devices are extremely low, light leakage that might occur in black display (what is called black-level degradation) can be reduced as much as possible, for example.

In particular, current flowing between adjacent light-emitting devices having the MML structure can be significantly reduced.

### [Transistor 209 and Transistor 210]

FIG. 16B and FIG. 16C are cross-sectional views each illustrating another example of a cross-sectional structure of a transistor that can be used for the display device 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate, and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n, and the conductive layer 222b is electrically connected to the other of the pair of low-resistance regions 231n. The insulating layer 215 covers the conductive layer 223. An insulating layer 218 covers the transistor.

### [Structure Example 1 of Insulating Layer 225]

In the transistor 209, the insulating layer 225 covers the top surface and the side surface of the semiconductor layer 231 (see FIG. 16B). The insulating layer 225 and the insulating layer 215 have opening portions, and the conductive layer 222a and the conductive layer 222b are electrically connected to the low-resistance regions 231n through the opening portions. One of the conductive layer 222a and the conductive layer 222b functions as a source, and the other functions as a drain.

### [Structure Example 2 of Insulating Layer 225]

In the transistor 210, the insulating layer 225 overlaps with the channel formation region 231i of the semiconductor layer 231 and does not overlap with the low-resistance regions 231n (see FIG. 16C). For example, the insulating layer 225 can be processed into a predetermined shape with the use of the conductive layer 223 as a mask. The insulating layer 215 covers the insulating layer 225 and the conductive layer 223. The insulating layer 215 has opening portions, and the conductive layer 222a and the conductive layer 222b are electrically connected to the low-resistance regions 231n.

### [Connection Portion 204]

A connection portion 204 is provided for the substrate 14b. The connection portion 204 includes a conductive layer 166, and the conductive layer 166 is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Device 100I>>

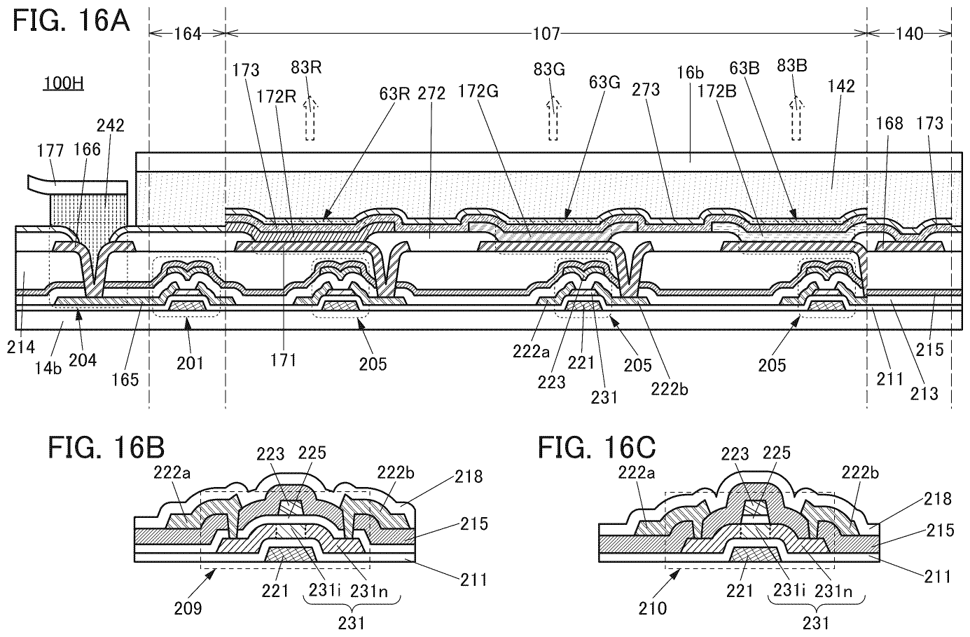

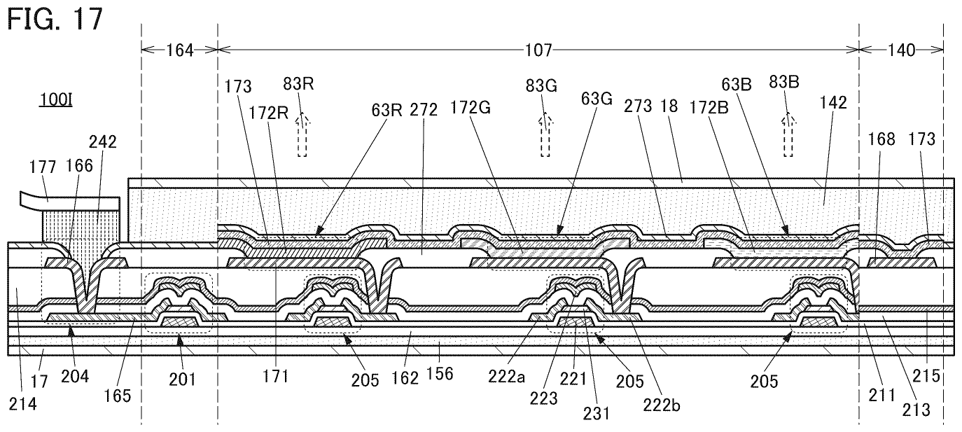

FIG. 17 is a cross-sectional view illustrating a structure of a display device 100I. The display device 100I is different from the display device 100H in having flexibility. In other words, the display device 100I is a flexible display. The display device 100I includes a substrate 17 instead of the substrate 14b, and includes a substrate 18 instead of the substrate 16b. The substrate 17 and the substrate 18 both have flexibility.

The display device 1001 includes a bonding layer 156 and an insulating layer 162. The insulating layer 162 and the substrate 17 are bonded to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistor 201 and the transistor 205 are provided over the insulating layer 162.

For example, the insulating layer 162 is formed over a formation substrate, and the transistors, the light-emitting devices, and the like are formed over the insulating layer 162. Then, the bonding layer 142 is formed over the light-emitting devices, and the formation substrate and the substrate 18 are bonded to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are bonded to each other with the bonding layer 156. In this manner, the components formed over the formation substrate can be transferred onto the substrate 17, whereby the display device 100I can be fabricated.

### <<Display Device 100J>>

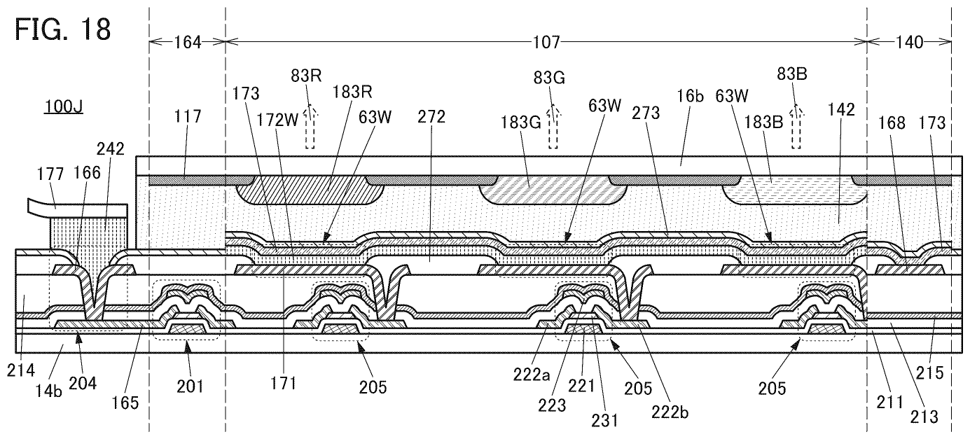

FIG. 18 is a cross-sectional view illustrating a structure of a display device 100J. The display device 100J is different from the display device 100H in including light-emitting devices 63W instead of the light-emitting device 63R, the light-emitting device 63G, and the light-emitting device 63B, and in including the coloring layer 183R, the coloring layer 183G, and the coloring layer 183B.

The display device 100J includes the coloring layer 183R, the coloring layer 183G, and the coloring layer 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display device 100J includes a light-blocking layer 117. For example, the light-blocking layer 117 is provided between the coloring layer 183R and the coloring layer 183G, between the coloring layer 183G and the coloring layer 183B, and between the coloring layer 183B and the coloring layer 183R. The light-blocking layer 117 includes a region overlapping with the connection portion 140 and a region overlapping with the circuit 164.

The light-emitting device 63W can emit white light, for example. The coloring layer 183R can transmit red light, the coloring layer 183G can transmit green light, and the coloring layer 183B can transmit blue light, for example. In this manner, the display device 100J can emit the red light 83R, the green light 83G, and the blue light 83B, for example, to perform full color display.

### <<Display Device 100K>>

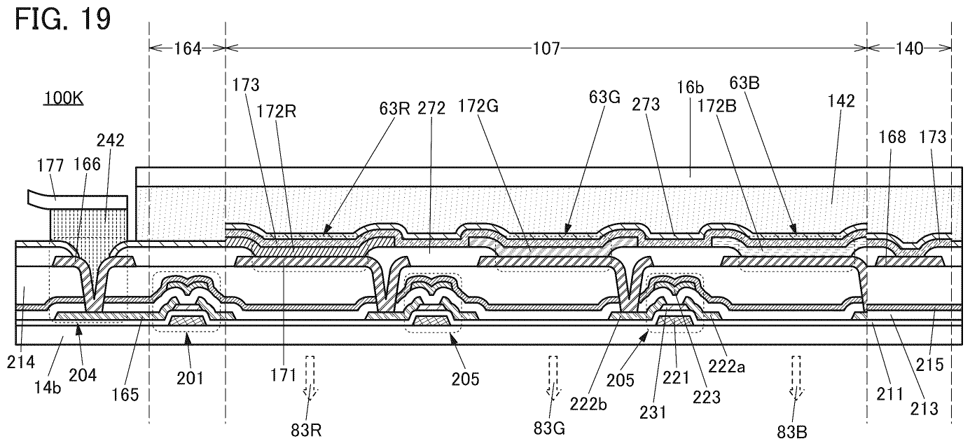

FIG. 19 is a cross-sectional view illustrating a structure of a display device 100K. The display device 100K is different from the display device 100H in having a bottom-emission structure. The light-emitting devices emit the light 83R, the light 83G, and the light 83B to the substrate 14b side. A visible-light-transmitting material is used for the conductive layer 171. A visible-light-reflecting material is used for the conductive layer 173.

### <<Display Device 100L>>

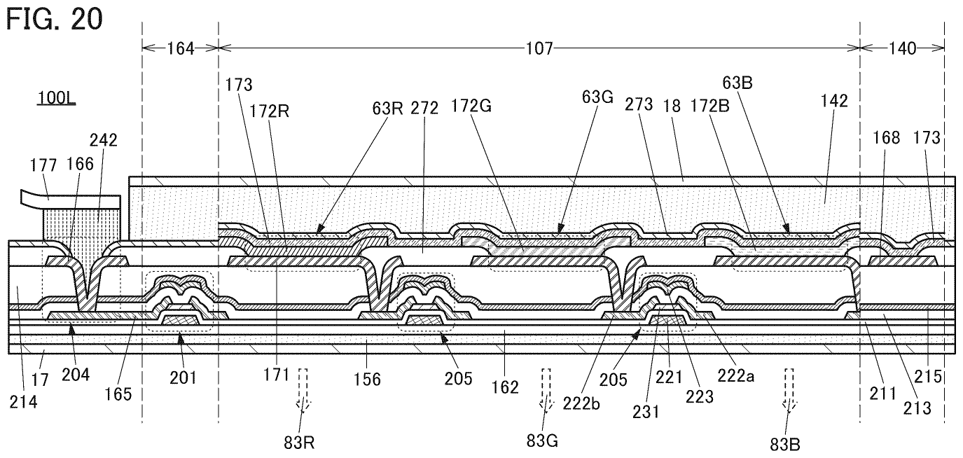

FIG. 20 is a cross-sectional view illustrating a structure of a display device 100L. The display device 100L is different from the display device 100H in having flexibility and a bottom-emission structure. The display device 100L includes the substrate 17 instead of the substrate 14b, and includes the substrate 18 instead of the substrate 16b. The substrate 17 and the substrate 18 both have flexibility. The light-emitting devices emit the light 83R, the light 83G, and the light 83B to the substrate 14b side.

The conductive layer 221 and the conductive layer 223 may have a property of transmitting visible light and a property of reflecting visible light. When the conductive layer 221 and the conductive layer 223 have a property of transmitting visible light, the visible-light transmittance in the display portion 107 can be improved. Meanwhile, when the conductive layer 221 and the conductive layer 223 have a property of reflecting visible light, the amount of visible light entering the semiconductor layer 231 can be reduced. In addition, damage to the semiconductor layer 231 can be reduced. Accordingly, the reliability of the display device 100K or the display device 100L can be increased.

Even in a top-emission display device such as the display device 100H or the display device 100I, at least some of the layers included in the transistor 205 may have a property of transmitting visible light. In that case, the conductive layer 171 also has a property of transmitting visible light. Accordingly, the visible-light transmittance in the display portion 107 can be improved.

### <<Display Device 100M>>

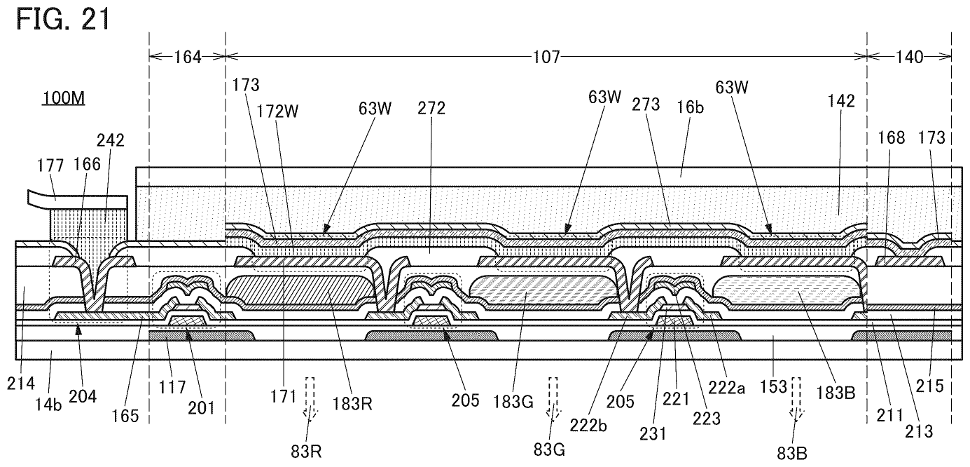

FIG. 21 is a cross-sectional view illustrating a structure of a display device 100M. The display device 100M is different from the display device 100H in including the light-emitting devices 63W instead of the light-emitting device 63R, the light-emitting device 63G, and the light-emitting device 63B, in including the coloring layer 183R, the coloring layer 183G, and the coloring layer 183B, and in having a bottom-emission structure.

The display device 100M includes the coloring layer 183R, the coloring layer 183G, and the coloring layer 183B. The display device 100M also includes the light-blocking layer 117.

### [Coloring Layer 183R, Coloring Layer 183G, and Coloring Layer 183B]

The coloring layer 183R is positioned between one light-emitting device 63W and the substrate 14b, the coloring layer 183G is positioned between another light-emitting device 63W and the substrate 14b, and the coloring layer 183B is positioned between another light-emitting device 63W and the substrate 14b. For example, the coloring layer 183R, the coloring layer 183G, and the coloring layer 183B can be provided between the insulating layer 215 and the insulating layer 214.

### [Light-Blocking Layer 117]

The light-blocking layer 117 is provided over the substrate 14b, and the light-blocking layer 117 is positioned between the substrate 14b and the transistor 205. An insulating layer 153 is positioned between the light-blocking layer 117 and the transistor 205. For example, the light-blocking layer 117 does not overlap with a light-emitting region of the light-emitting device 63W. For example, the light-blocking layer 117 overlaps with the connection portion 140 and the circuit 164.

The light-blocking layer 117 can also be provided in the display device 100K or the display device 100L. In that case, light emitted from the light-emitting device 63R, the light-emitting device 63G, and the light-emitting device 63B can be inhibited from being reflected by the substrate 14b and diffusing inside the display device 100K or the display device 100L, for example. Thus, the display device 100K and the display device 100L can be display devices with high display quality. Meanwhile, when the light-blocking layer 117 is not provided, the extraction efficiency of light emitted from the light-emitting device 63R, the light-emitting device 63G, and the light-emitting device 63B can be increased.

At least part of this embodiment can be implemented in combination with the other embodiments described in this specification as appropriate.

### Embodiment 10

In this embodiment, electronic devices of one embodiment of the present invention will be described.

Electronic devices of this embodiment each include the display device of one embodiment of the present invention in a display portion. The display device of one embodiment of the present invention is highly reliable and can be easily increased in resolution and definition. Thus, the display device of one embodiment of the present invention can be used for display portions of a variety of electronic devices.

Examples of electronic devices include a digital camera, a digital video camera, a digital photo frame, a mobile phone, a portable game machine, a portable information terminal, and an audio reproducing device, in addition to electronic devices with a relatively large screen, such as a television device, a desktop or laptop personal computer, a monitor of a computer, digital signage, and a large game machine such as a pachinko machine.

In particular, the display device of one embodiment of the present invention can have high resolution, and thus can be suitably used for an electronic device having a relatively small display portion. Examples of such an electronic device include watch-type and bracelet-type information terminal devices (wearable devices) and wearable devices that can be worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840× 2160), or 8K (number of pixels: 7680× 4320). In particular, the definition is preferably 4K, 8K, or higher. The pixel density (resolution) of the display device of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display device having one or both of high definition and high resolution, the electronic device can provide higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

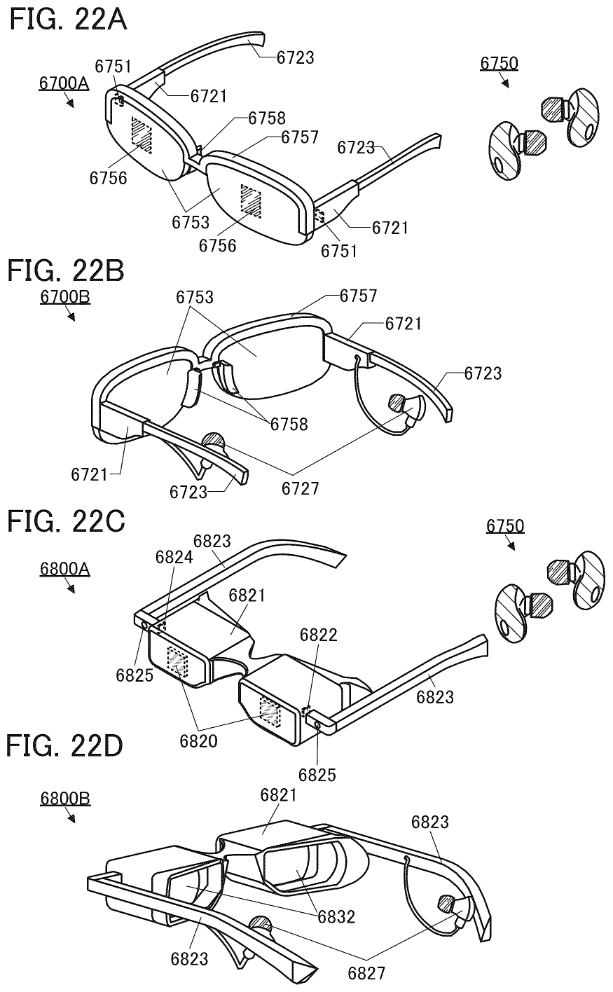

Examples of wearable devices that can be worn on the head are described with reference to FIG. 22A to FIG. 22D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to reach a higher level of immersion.

An electronic device 6700A illustrated in FIG. 22A and an electronic device 6700B illustrated in FIG. 22B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display device of one embodiment of the present invention can be used for the display panels 6751. Thus, a highly reliable electronic device can be obtained.

The electronic device 6700A and the electronic device 6700B can each project images displayed on the display panels 6751 onto display regions 6756 of the optical members 6753. Since the optical members 6753 have a light-transmitting property, the user can see images displayed on the display regions, which are superimposed on transmission images seen through the optical members 6753. Accordingly, the electronic device 6700A and the electronic device 6700B are electronic devices capable of AR display.

In each of the electronic device 6700A and the electronic device 6700B, a camera capable of capturing images of the front side may be provided as the image capturing portion. Furthermore, when the electronic device 6700A and the electronic device 6700B are each provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Note that instead of the wireless communication device or in addition to the wireless communication device, a connector to which a cable for supplying a video signal and a power supply potential can be connected may be provided.

The electronic device 6700A and the electronic device 6700B are each provided with a battery so that they can be charged wirelessly and/or by wire.

A touch sensor module may be provided in the housing 6721. The touch sensor module has a function of detecting a touch on the outer surface of the housing 6721. A tap operation, a slide operation, or the like by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 6721, so that the range of the operation can be increased.

Any of various touch sensors can be used for the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 22C and an electronic device 6800B illustrated in FIG. 22D each include a pair of display portions 6820, a housing 6821, a communication portion 6822, a pair of wearing portions 6823, a control portion 6824, a pair of image capturing portions 6825, and a pair of lenses 6832.

The display device of one embodiment of the present invention can be used for the display portions 6820. Thus, a highly reliable electronic device can be obtained.

The display portions 6820 are positioned inside the housing 6821 so as to be seen through the lenses 6832. When the pair of display portions 6820 display different images, three-dimensional display using parallax can also be performed.

The electronic device 6800A and the electronic device 6800B can be regarded as electronic devices for VR. The user who wears the electronic device 6800A or the electronic device 6800B can see images displayed on the display portions 6820 through the lenses 6832.

The electronic device 6800A and the electronic device 6800B each preferably include a mechanism for adjusting the lateral positions of the lenses 6832 and the display portions 6820 so that the lenses 6832 and the display portions 6820 are positioned optimally in accordance with the positions of the user's eyes. Moreover, the electronic device 6800A and the electronic device 6800B each preferably include a mechanism for adjusting focus by changing the distance between the lenses 6832 and the display portions 6820.

The electronic device 6800A or the electronic device 6800B can be mounted on the user's head with the wearing portions 6823. FIG. 22C illustrates an example in which the wearing portions 6823 have a shape like a temple (also referred to as a joint or the like) of glasses; however, one embodiment of the present invention is not limited thereto. The wearing portions 6823 can have any shape with which the user can wear the electronic device, for example, a shape of a helmet or a band.

The image capturing portion 6825 has a function of obtaining information on the external environment. Data obtained by the image capturing portion 6825 can be output to the display portions 6820. An image sensor can be used for the image capturing portion 6825. Moreover, a plurality of cameras may be provided so as to cover a plurality of fields of view, such as a telescope field of view and a wide field of view.

Although an example of including the image capturing portion 6825 is described here, a range sensor (also referred to as a sensing portion) that is capable of measuring a distance from an object may be provided. In other words, the image capturing portion 6825 is one embodiment of the sensing portion. As the sensing portion, an image sensor or a distance image sensor such as LIDAR (Light Detection and Ranging) can be used, for example. By using images obtained by the camera and images obtained by the distance image sensor, more pieces of information can be obtained and a gesture operation with higher accuracy is possible.

The electronic device 6800A may include a vibration mechanism that functions as bone-conduction earphones. For example, a structure including the vibration mechanism can be employed for any one or more of the display portions 6820, the housing 6821, and the wearing portions 6823. Thus, without additionally requiring an audio device such as headphones, earphones, or a speaker, the user can enjoy videos and sound only by wearing the electronic device 6800A.

The electronic device 6800A and the electronic device 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and have a wireless communication function. The earphones 6750 can receive information (e.g., audio data) from the electronic device with the wireless communication function. For example, the electronic device 6700A illustrated in FIG. 22A has a function of transmitting information to the earphones 6750 with the wireless communication function. For another example, the electronic device 6800A illustrated in FIG. 22C has a function of transmitting information to the earphones 6750 with the wireless communication function.

The electronic device may include earphone portions. The electronic device 6700B illustrated in FIG. 22B includes earphone portions 6727. For example, the earphone portions 6727 and the control portion can be connected to each other by wire. Part of a wiring that connects the earphone portions 6727 and the control portion may be positioned inside the housing 6721 or the wearing portions 6723.

Similarly, the electronic device 6800B illustrated in FIG. 22D includes earphone portions 6827. For example, the earphone portions 6827 and the control portion 6824 can be connected to each other by wire. Part of a wiring that connects the earphone portions 6827 and the control portion 6824 may be positioned inside the housing 6821 or the wearing portions 6823. Alternatively, the earphone portions 6827 and the wearing portions 6823 may include magnets. This is preferable because the earphone portions 6827 can be fixed to the wearing portions 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 6700A and the electronic device 6700B) and the goggles-type device (e.g., the electronic device 6800A and the electronic device 6800B) are preferable as the electronic device of one embodiment of the present invention.

The electronic device of one embodiment of the present invention can transmit information to earphones by wire or wirelessly.

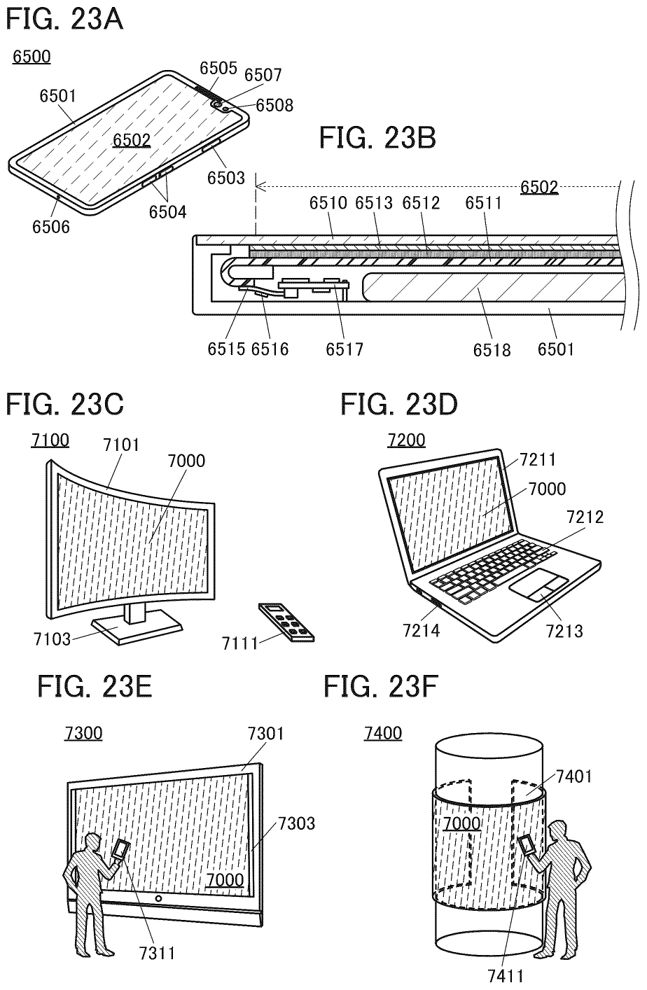

An electronic device 6500 illustrated in FIG. 23A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502. Thus, a highly reliable electronic device can be obtained.

FIG. 23B is a schematic cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The flexible display of one embodiment of the present invention can be used as the display panel 6511. Thus, an extremely lightweight electronic device can be achieved. Since the display panel 6511 is extremely thin, the battery 6518 with high capacity can be mounted while an increase in the thickness of the electronic device is suppressed. Moreover, part of the display panel 6511 is folded back such that a connection portion with the FPC 6515 is provided on the back side of a pixel portion, whereby an electronic device with a narrow bezel can be achieved.

FIG. 23C illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000. Thus, a highly reliable electronic device can be obtained.

The operation of the television device 7100 illustrated in FIG. 23C can be performed with an operation switch provided in the housing 7101 and a separate remote controller 7111. Alternatively, the display portion 7000 may include a touch sensor, and the television device 7100 may be operated by a touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 23D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000. Thus, a highly reliable electronic device can be obtained.

FIG. 23E and FIG. 23F illustrate examples of digital signage.

Digital signage 7300 illustrated in FIG. 23E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 23F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 23E and FIG. 23F. Thus, a highly reliable electronic device can be obtained.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, in the case of an application for providing information such as route information or traffic information, usability can be enhanced by intuitive operation.

As illustrated in FIG. 23E and FIG. 23F, it is preferable that the digital signage 7300 or the digital signage 7400 be capable of working with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

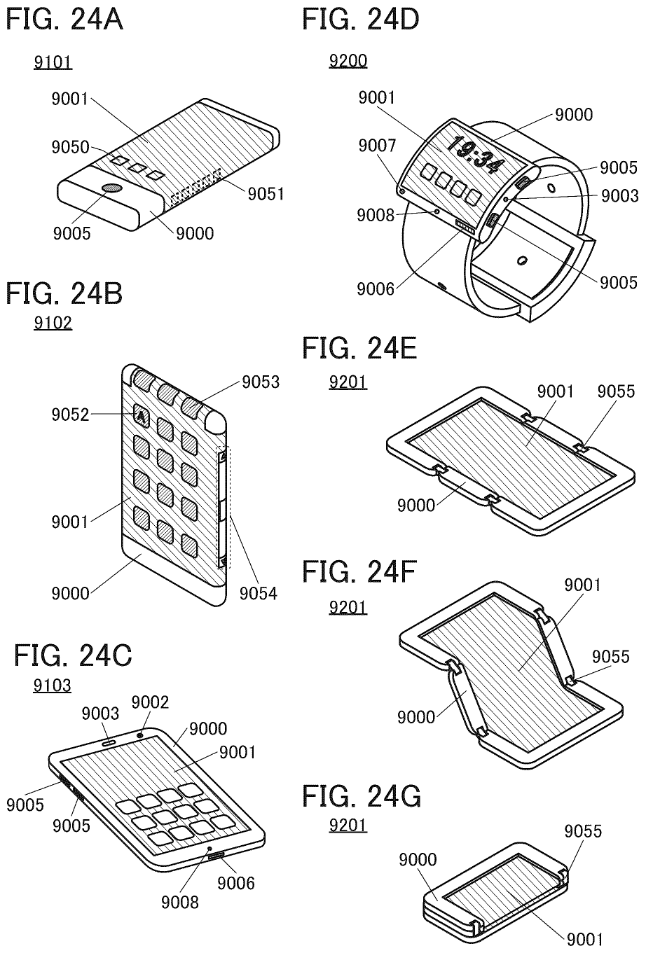

Electronic devices illustrated in FIG. 24A to FIG. 24G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radiation, a flow rate, humidity, gradient, oscillation, a smell, or infrared rays), a microphone 9008, and the like.

The electronic devices illustrated in FIG. 24A to FIG. 24G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of capturing a still image or a moving image, a function of storing the captured image in a recording medium (an external recording medium or a recording medium incorporated in the camera), a function of displaying the captured image on the display portion, and the like.

The electronic devices illustrated in FIG. 24A to FIG. 24G will be described in detail below.

FIG. 24A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 24A illustrates an example in which three icons 9050 are displayed. Information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, for example, the icon 9050 may be displayed at the position where the information 9051 is displayed.

FIG. 24B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 24C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 24D is a perspective view illustrating a watch-type portable information terminal 9200. For example, the portable information terminal 9200 can be used as a Smartwatch (registered trademark). The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 24E to FIG. 24G are perspective views illustrating a foldable portable information terminal 9201. FIG. 24E is a perspective view of an opened state of the portable information terminal 9201, FIG. 24G is a perspective view of a folded state thereof, and FIG. 24F is a perspective view of a state in the middle of change from one of FIG. 24E and FIG. 24G to the other. The portable information terminal 9201 is highly portable in the folded state and is highly browsable in the opened state because of a seamless large display region. The display portion 9001 of the portable information terminal 9201 is supported by three housings 9000 joined by hinges 9055. The display portion 9001 can be bent with a radius of curvature greater than or equal to 0.1 mm and less than or equal to 150 mm, for example.

This embodiment can be combined with any of the other embodiments as appropriate. In this specification, in the case where a plurality of structure examples are described in one embodiment, the structure examples can be combined as appropriate.

### Example 1

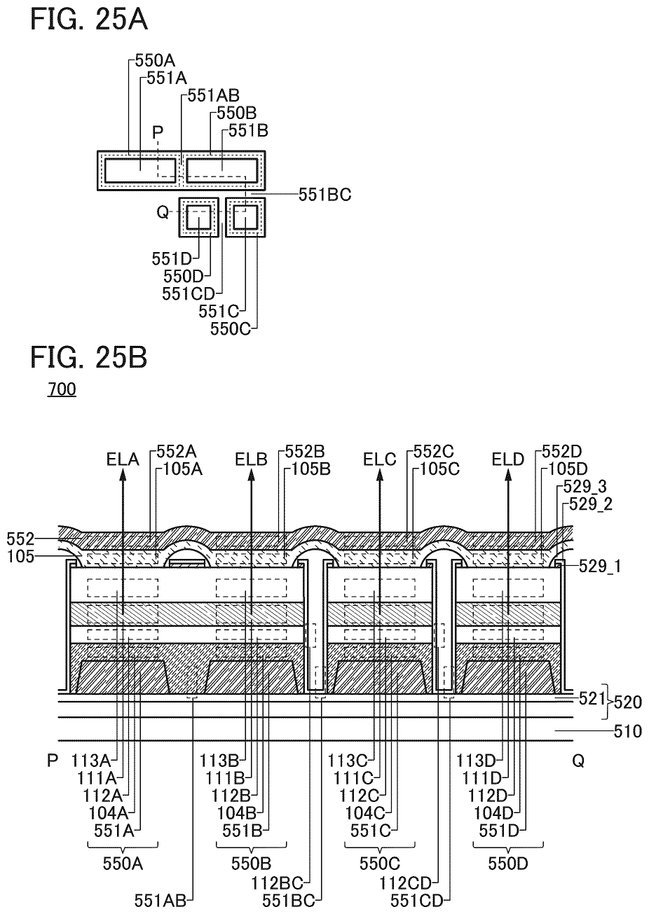

In this example, the display device of one embodiment of the present invention will be described with reference to FIG. 25 to FIG. 35.

FIG. 25A is a top view illustrating a structure of a fabricated display device, and FIG. 25B is a cross-sectional view illustrating a structure of a cross section along the cutting line P-Q.

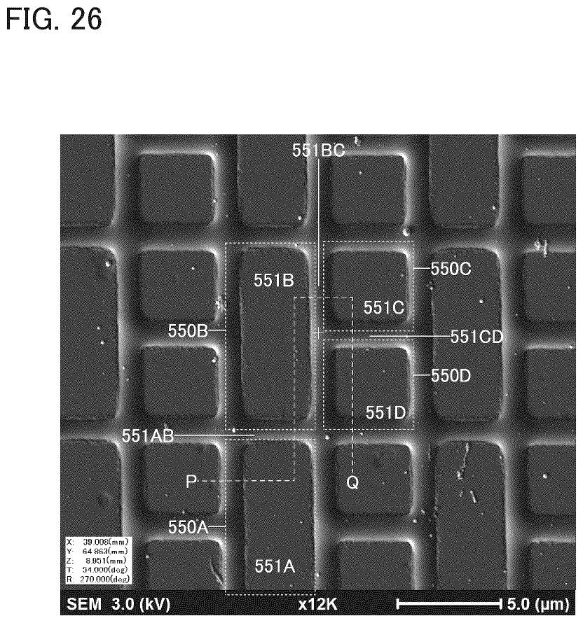

FIG. 26 is a scanning electron micrograph showing the structure of the fabricated display device. Note that a focused ion beam/scanning electron microscope composite apparatus (produced by Hitachi High-Tech Corporation) was used for observation.

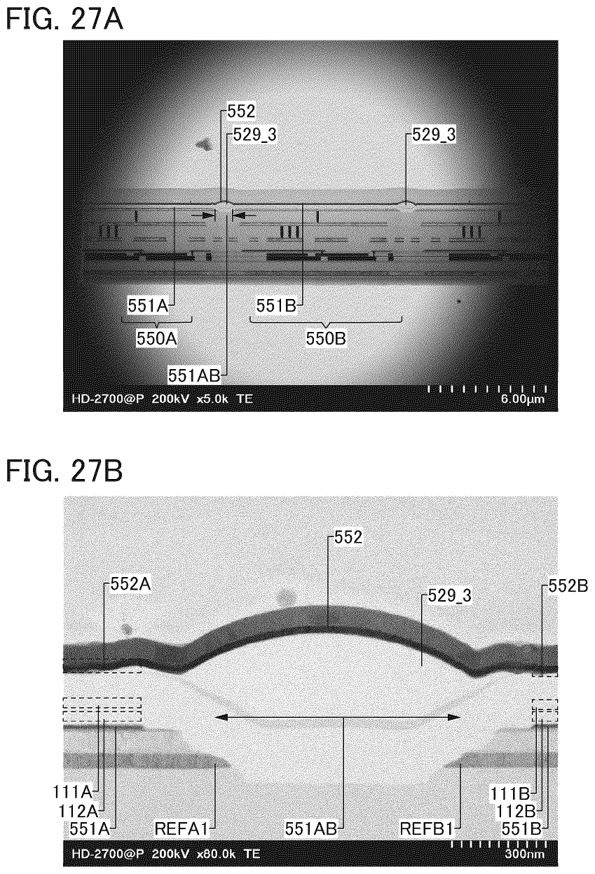

FIG. 27A is a scanning transmission electron micrograph showing a cross-sectional structure of the fabricated display device, and FIG. 27B is a scanning transmission electron micrograph showing the structure of part of FIG. 27A.

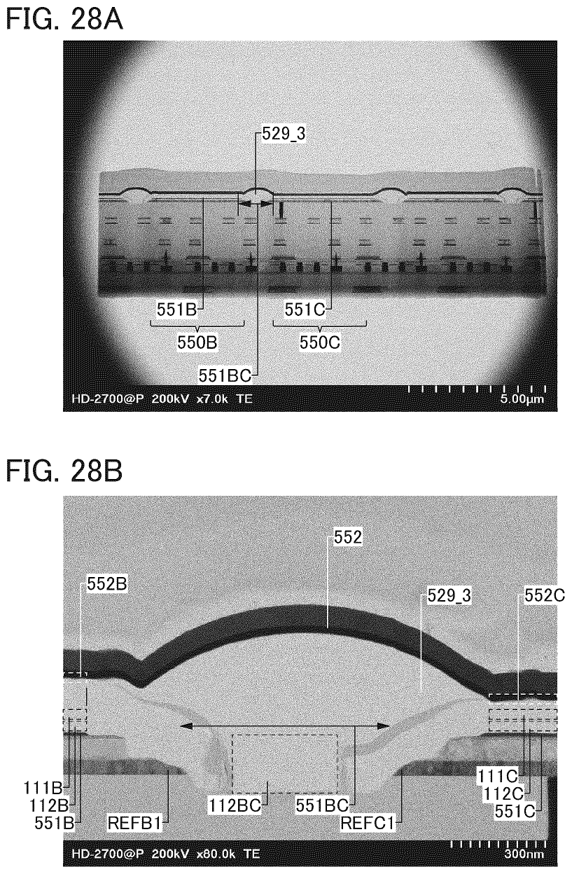

FIG. 28A is a scanning transmission electron micrograph showing a cross-sectional structure of the fabricated display device, and FIG. 28B is a scanning transmission electron micrograph showing the structure of part of FIG. 28A.

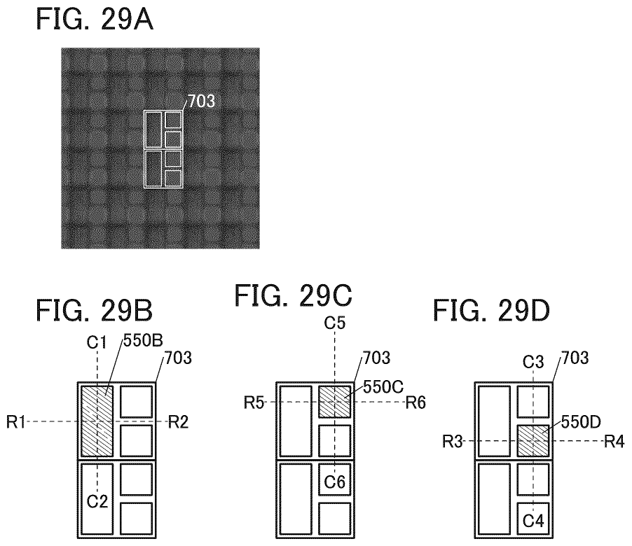

FIG. 29A is a micrograph showing a structure of a pixel of the fabricated display device, and FIG. 29B to FIG. 29D are diagrams each illustrating a state where part of FIG. 29A is made to emit light.

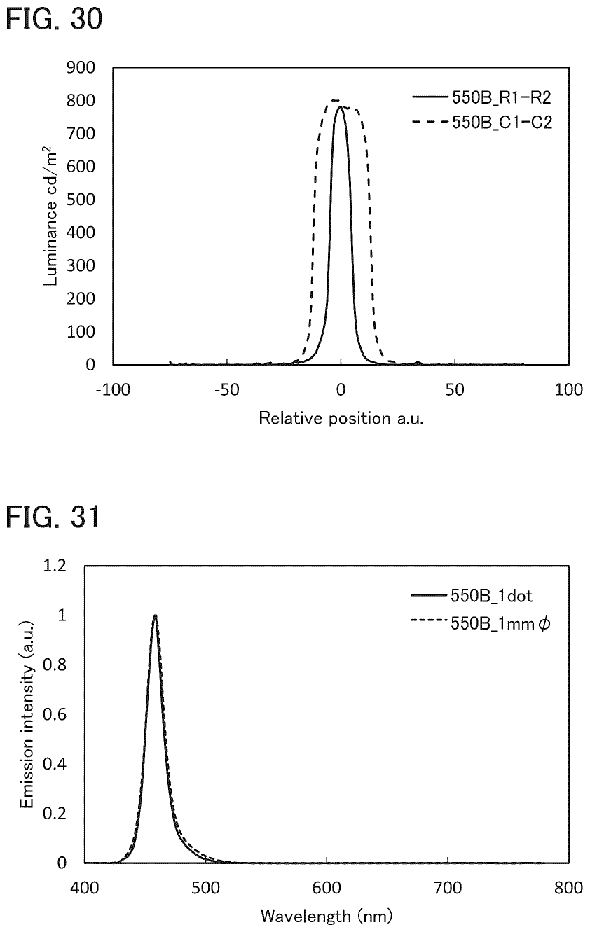

FIG. 30 is a graph showing the relative position-luminance characteristics of the light-emitting device 550B in the fabricated display device.

FIG. 31 is a graph showing emission spectra of the fabricated display device and the light-emitting device 550B.

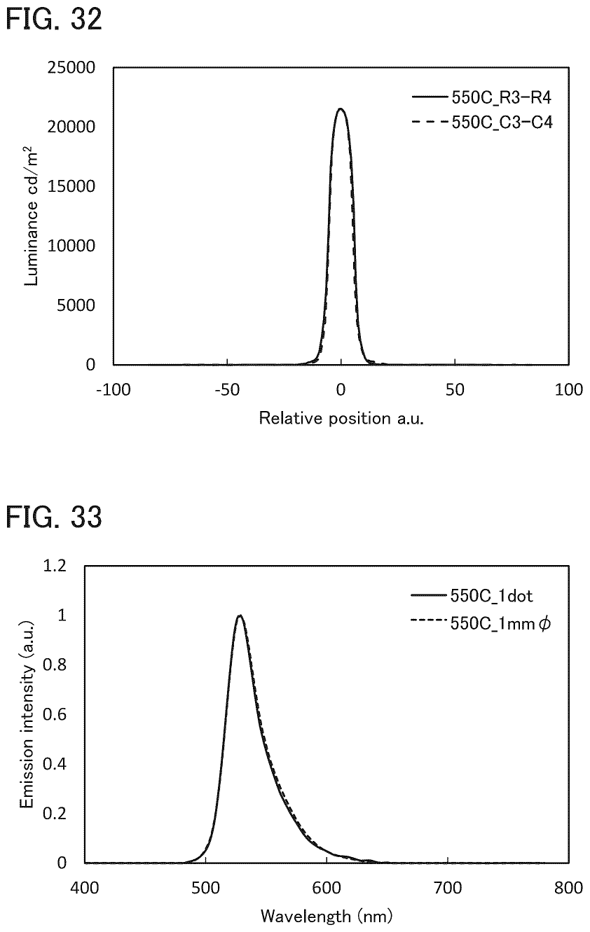

FIG. 32 is a graph showing the relative position-luminance characteristics of the light-emitting device 550C in the fabricated display device.

FIG. 33 is a graph showing emission spectra of the fabricated display device and the light-emitting device 550C.

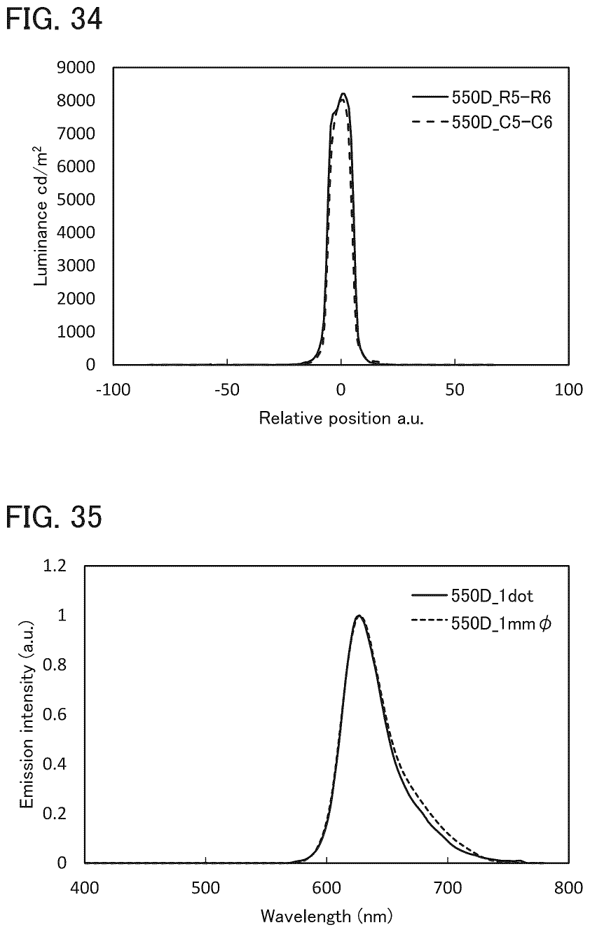

FIG. 34 is a graph showing the relative position-luminance characteristics of the light-emitting device 550D in the fabricated display device.

FIG. 35 is a graph showing emission spectra of the fabricated display device and the light-emitting device 550D.

### <Display Device 700>

The fabricated display device 700 described in this example includes the light-emitting device 550A, the light-emitting device 550B, the light-emitting device 550C, and the light-emitting device 550D (see FIG. 25 to FIG. 28).

### <<Structure of Light-Emitting Device 550A>>

The light-emitting device 550A includes the electrode 551A, the layer 111A, the layer 112A, and the electrode 552A (see FIG. 25 to FIG. 28). The layer 111A is sandwiched between the electrode 551A and the electrode 552A, and the layer 111A contains the light-emitting material EMA. The layer 112A is sandwiched between the layer 111A and the electrode 551A.

### <<Structure of Light-Emitting Device 550B>>

The light-emitting device 550B includes the electrode 551B, the layer 111B, the layer 112B, and the electrode 552B. The electrode 551B is adjacent to the electrode 551A, and the gap 551AB is positioned between the electrode 551B and the electrode 551A. The layer 111B is sandwiched between the electrode 551B and the electrode 552B, and the layer 111B contains the light-emitting material EMB. The layer 112B is sandwiched between the layer 111B and the electrode 551B, and the layer 112B is continuous with the layer 112A over the gap 551AB. Note that the electrode 551B is formed over a conductive film functioning as a reflective film REFB1, and the electrode 551A is formed over a conductive film functioning as a reflective film REFA1. The distance between the reflective film REFB1 and the reflective film REFA1 was 0.68 μm (see FIG. 27B).

### <<Structure of Light-Emitting Device 550C>>

The light-emitting device 550C includes the electrode 551C, the layer 111C, the layer 112C, and the electrode 552C (see FIG. 25, FIG. 26, and FIG. 28). The electrode 551C is adjacent to the electrode 551B, and the gap 551BC is positioned between the electrode 551C and the electrode 551B. The layer 111C is sandwiched between the electrode 551C and the electrode 552C, and the layer 111C contains the light-emitting material EMC. The layer 112C is sandwiched between the layer 111C and the electrode 551C, the gap 112BC is positioned between the layer 112C and the layer 112B, and the gap 112BC overlaps with the gap 551BC. Note that the electrode 551C is formed over a conductive film functioning as a reflective film REFC1, and the electrode 551B is formed over the conductive film functioning as the reflective film REFB1. The distance between the reflective film REFC1 and the reflective film REFB1 was 0.65 μm (see FIG. 28B).

### <<Structure of Light-Emitting Device 550D>>

The light-emitting device 550D includes the electrode 551D, the layer 111D, the layer 112D, and the electrode 552D (see FIG. 25 and FIG. 26). The electrode 551D is adjacent to the electrode 551C, and the gap 551CD is positioned between the electrode 551D and the electrode 551C. The layer 111D is sandwiched between the electrode 551D and the electrode 552D, and the layer 111D contains the light-emitting material EMD. The layer 112D is sandwiched between the layer 111D and the electrode 551D, the gap 112CD is positioned between the layer 112D and the layer 112C, and the gap 112CD overlaps with the gap 551CD.

### <<Operation Characteristics 1 of Display Device>>

When supplied with electric power and a display signal, the display device displayed an image. The operation characteristics of the display device were measured at room temperature. Note that the luminance, the CIE chromaticity, and the emission spectra were measured with a two-dimensional spectroradiometer (SR-5000HM, produced by TOPCON TECHNOHOUSE CORPORATION) connected to an optical microscope (MX50, produced by Olympus Corporation).

Table 1 shows the CIE chromaticity in a region with a radius of 1 μm in a state where only the light-emitting device 550B, the light-emitting device 550C, or the light-emitting device 550D is made to emit light (1-dot display). Table 1 also shows the CIE chromaticity in a region with a radius of 1 mm in a state where a plurality of light-emitting devices of the same color as the light-emitting device 550B are made to emit light, in a state where a plurality of light-emitting devices of the same color as the light-emitting device 550C are made to emit light, and in a state where a plurality of light-emitting devices of the same color as the light-emitting device 550D are made to emit light (display on the entire screen).

TABLE 1

| | Light-emitting device B | | Light-emitting device C | | Light-emitting device D | |
|---|---|---|---|---|---|---|
| | Chromaticity x | Chromaticity y | Chromaticity x | Chromaticity y | Chromaticity x | Chromaticity y |
| 1-dot display | 0.143 | 0.036 | 0.260 | 0.703 | 0.690 | 0.310 |
| 1 μmφ | | | | | | |
| Display on | 0.143 | 0.039 | 0.262 | 0.701 | 0.690 | 0.310 |
| entire screen | | | | | | |
| 1 mmφ | | | | | | |

Signals were supplied to the fabricated display device to make the blue-light-emitting device, the green-light-emitting device, and the red-light-emitting device emit light, so that white was expressed as a whole (see FIG. 29A).

The details will be described in Operation characteristics 2 of display device to Operation characteristics 4 of display device; the emission spectrum of the color expressed by the plurality of light-emitting devices of the same color agreed well with the emission spectrum of the color expressed by one light-emitting device. Thus, it was confirmed that occurrence of a phenomenon in which, when one light-emitting device was made to emit light, the other light-emitting devices emitted light at unintended luminance was able to be inhibited. The color gamut that could be expressed by the display device was able to be widened. The resolution of the display device was able to be increased. A high resolution (2731 ppi) was able to be achieved. A high pixel aperture ratio (43.3%) was able to be achieved. A film separation phenomenon during the fabrication process of the display device was able to be prevented. For example, a phenomenon in which the layer 111A or the layer 111B was separated during the fabrication process of the display device was able to be prevented.

### <<Operation Characteristics 2 of Display Device>>

A signal was supplied to the fabricated display device to make only the light-emitting device 550B included in the pixel set 703 emit light, and the luminance distribution between R1 and R2 and the luminance distribution between C1 and C2 in the figure were measured (see FIG. 29B and FIG. 30). Since the light-emitting device 550B had a rectangular light-emitting region, the width of the luminance distribution between C1 and C2 was greater than that of the luminance distribution between R1 and R2. It was confirmed that the other light-emitting devices adjacent to the light-emitting device 550B did not emit light.

Only the light-emitting device 550B was made to emit light. In the emission spectrum (550B—1dot) of light emitted from a region with a radius of 1 μm in this state, light emitted from the light-emitting devices of the other colors was not observed (see FIG. 31). In the emission spectrum (550B—1mmϕ) of light emitted from a region with a radius of 1 mm in a state where the plurality of light-emitting devices of the same color as the light-emitting device 550B included in the whole display device were made to emit light, light emitted from the light-emitting devices of the other colors was not observed (see FIG. 31).

Thus, it was confirmed that occurrence of a phenomenon in which, when the light-emitting device 550B was made to emit light, the other light-emitting devices emitted light at unintended luminance was able to be inhibited. The color gamut that could be expressed by the display device was able to be widened.

### <<Operation Characteristics 3 of Display Device>>

A signal was supplied to the fabricated display device to make only the light-emitting device 550C included in the pixel set 703 emit light, and the luminance distribution between R3 and R4 and the luminance distribution between C3 and C4 in the figure were measured (see FIG. 29C and FIG. 32). Since the light-emitting device 550C had a square light-emitting region, the luminance distribution between C3 and C4 was almost the same as the luminance distribution between R3 and R4. It was confirmed that the other light-emitting devices adjacent to the light-emitting device 550C did not emit light.

Only the light-emitting device 550C was made to emit light. In the emission spectrum (550C—1dot) of light emitted from a region with a radius of 1 μm in this state, light emitted from the light-emitting devices of the other colors was not observed (see FIG. 33). In the emission spectrum (550C—1mmϕ) of light emitted from a region with a radius of 1 mm in a state where the plurality of light-emitting devices of the same color as the light-emitting device 550C included in the whole display device were made to emit light, light emitted from the light-emitting devices of the other colors was not observed (see FIG. 33).

Thus, it was confirmed that occurrence of a phenomenon in which, when the light-emitting device 550C was made to emit light, the other light-emitting devices emitted light at unintended luminance was able to be inhibited. The color gamut that could be expressed by the display device was able to be widened.

### <<Operation Characteristics 4 of Display Device>>

A signal was supplied to the fabricated display device to make only the light-emitting device 550D included in the pixel set 703 emit light, and the luminance distribution between R5 and R6 and the luminance distribution between C5 and C6 in the figure were measured (see FIG. 29D and FIG. 34). Since the light-emitting device 550D had a square light-emitting region, the luminance distribution between C5 and C6 was almost the same as the luminance distribution between R5 and R6. It was confirmed that the other light-emitting devices adjacent to the light-emitting device 550D did not emit light.

Only the light-emitting device 550D was made to emit light. In the emission spectrum (550D—1dot) of light emitted from a region with a radius of 1 μm in this state, light emitted from the light-emitting devices of the other colors was not observed (see FIG. 35). In the emission spectrum (550D—1mmϕ) of light emitted from a region with a radius of 1 mm in a state where the plurality of light-emitting devices of the same color as the light-emitting device 550D included in the whole display device were made to emit light, light emitted from the light-emitting devices of the other colors was not observed (see FIG. 35).

Thus, it was confirmed that occurrence of a phenomenon in which, when the light-emitting device 550D was made to emit light, the other light-emitting devices emitted light at unintended luminance was able to be inhibited. The color gamut that could be expressed by the display device was able to be widened.

### Example 2

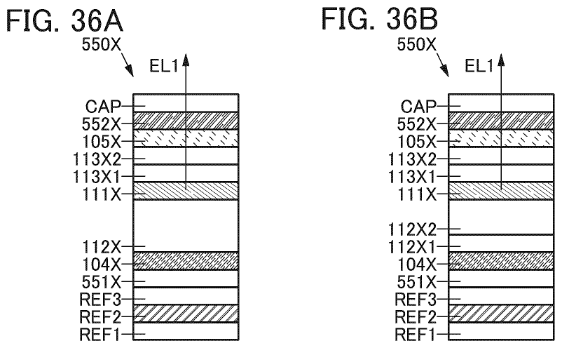

In this example, a light-emitting device 1 to a light-emitting device 3 that can be used for the fabricated display device of one embodiment of the present invention will be described with reference to FIG. 36 to FIG. 41.

FIG. 36A is a diagram illustrating a structure of the light-emitting device 550X, and FIG. 36B is a diagram illustrating a structure of the light-emitting device 550X that is different from the structure in FIG. 36A.

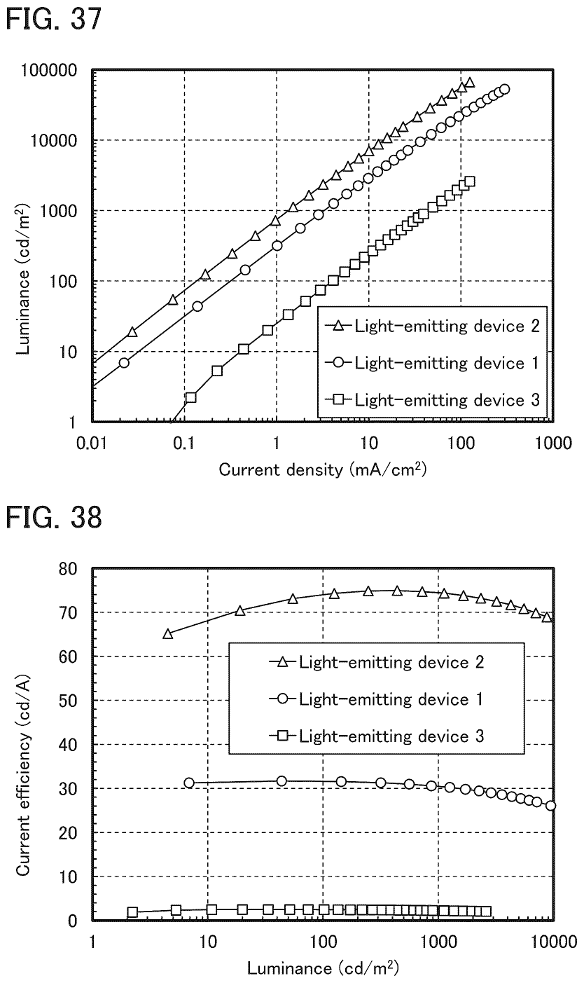

FIG. 37 is a graph showing the current density-luminance characteristics of the light-emitting device 1, the light-emitting device 2, and the light-emitting device 3.

FIG. 38 is a graph showing the luminance-current efficiency characteristics of the light-emitting device 1, the light-emitting device 2, and the light-emitting device 3.

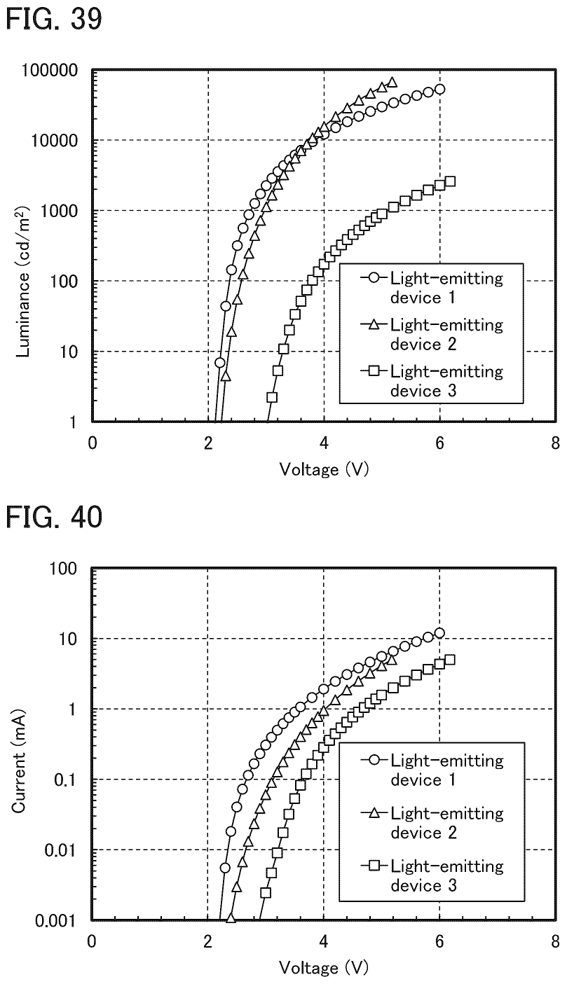

FIG. 39 is a graph showing the voltage-luminance characteristics of the light-emitting device 1, the light-emitting device 2, and the light-emitting device 3.

FIG. 40 is a graph showing the voltage-current characteristics of the light-emitting device 1, the light-emitting device 2, and the light-emitting device 3.

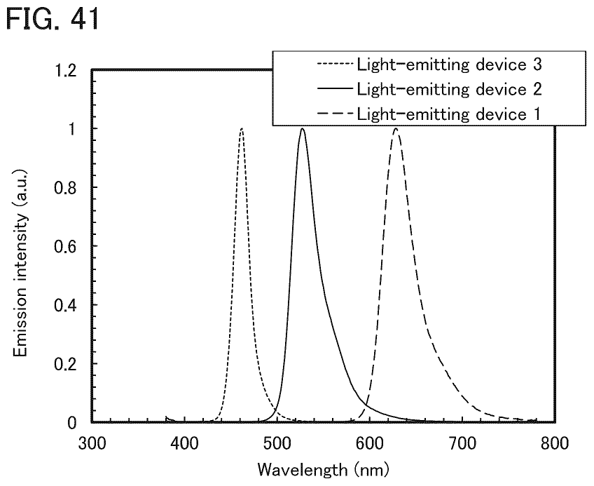

FIG. 41 is a graph showing emission spectra of the light-emitting device 1, the light-emitting device 2, and the light-emitting device 3 each emitting light at a luminance of 1000 cd/m².

### <Light-Emitting Device 1>

The fabricated light-emitting device 1 described in this example has a structure similar to that of the light-emitting device 550X (see FIG. 36A). Note that the light-emitting device 1 can be used as the light-emitting device 550C or the light-emitting device 550D of the display device described in Example 1.

### <<Structure of Light-Emitting Device 1>>

Table 2 shows the structure of the light-emitting device 1. Structural formulae of materials used in the light-emitting devices described in this example are shown below. Note that in the tables in this example, a subscript character and a superscript character are written in ordinary size for convenience. For example, a subscript character in an abbreviation or a superscript character in a unit are written in ordinary size in the tables. Such notations in the tables can be replaced by referring to the description in the specification.

TABLE 2

| | | | Com- | Thick |
|---|---|---|---|---|
| | Reference | | position | ness/ |
| Component | numeral | Material | ratio | nm |
| Layer | CAP | ITO | | 70 |
| Electrode | 552X | Ag:Mg | 1:0.1 | 25 |
| Layer | 105X | LiF:Yb | 1:0.5 | 1.5 |
| Layer | 113X2 | NBPhen | | 20 |
| Layer | 113X1 | 2mPCCzPDBq | | 20 |
| | | 11mDBtBPPnfpr: | 0.7: | |
| Layer | 111X | PCBBiF: | 0.3: | 40 |
| | | OCPG-006 | 0.05 | |
| Layer | 112X | PCBBiF | | 25 |
| Layer | 104X | PCBBiF:OCHD-003 | 1:0.03 | 10 |
| Electrode | 551X | ITSO | | 70 |
| Reflective film | REF3 | Ti | | 6 |
| Reflective film | REF2 | Al | | 70 |
| Reflective film | REF1 | Ti | | 50 |

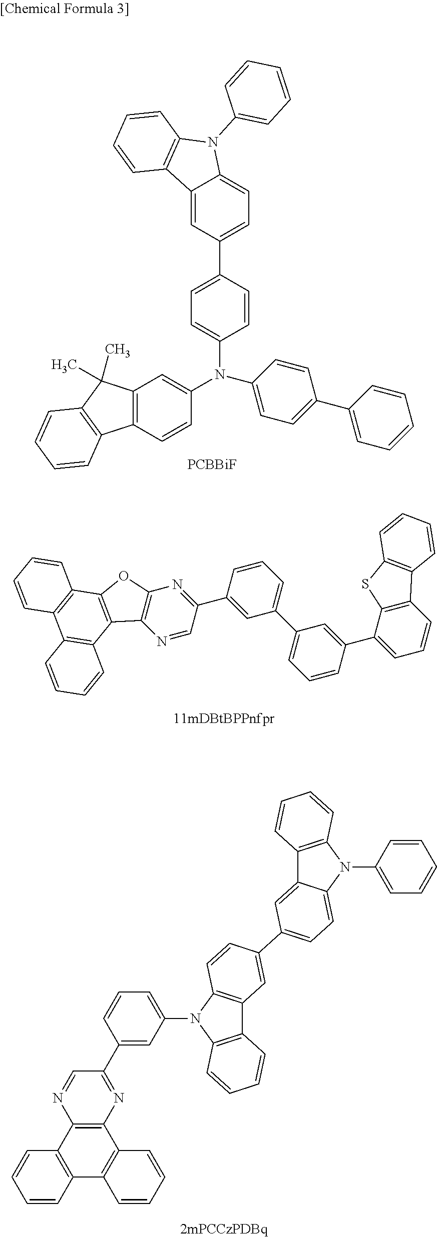

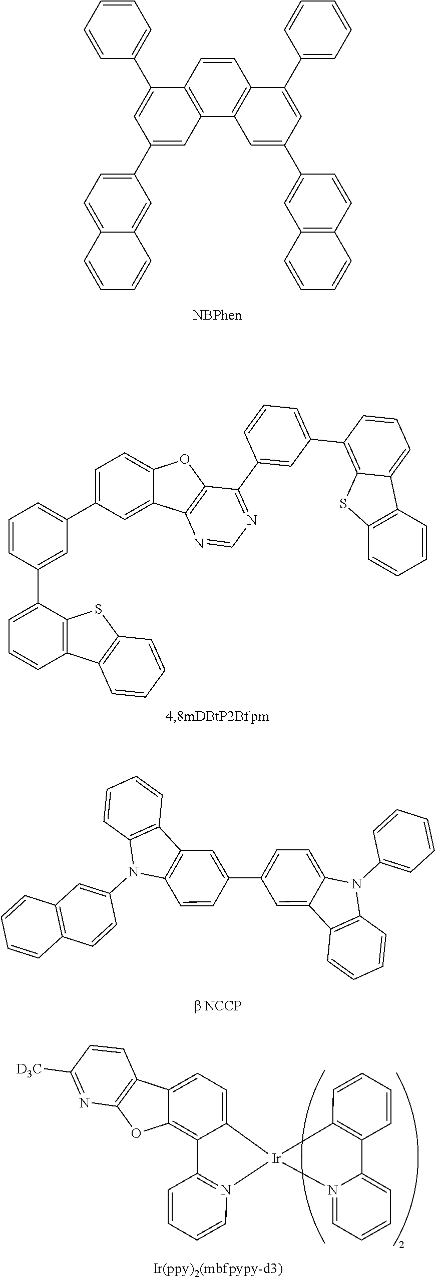

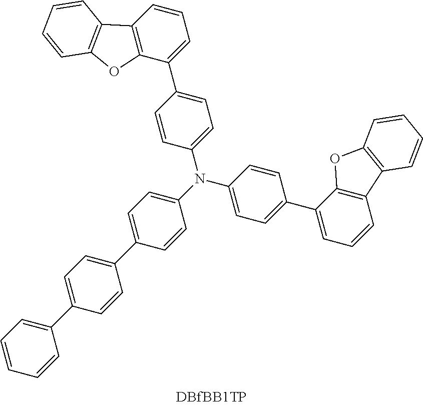 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

### <<Method for Fabricating Light-Emitting Device 1>>

The light-emitting device 1 described in this example was fabricated by a method including the following steps.

### [Step 1]

In Step 1, a reflective film REF1, a reflective film REF2, and a reflective film REF3 were stacked. Specifically, the reflective film REF1 was formed by a sputtering method using titanium (Ti) as a target. Note that the reflective film REF1 contains Ti and has a thickness of 50 nm. The reflective film REF2 was formed by a sputtering method using aluminum (Al) as a target. Note that the reflective film REF2 contains Al and has a thickness of 70 nm. The reflective film REF3 was formed by a sputtering method using titanium (Ti) as a target. Note that the reflective film REF3 contains Ti and has a thickness of 6 nm.

### [Step 2]

In Step 2, the electrode 551X was formed over the reflective film REF3. Specifically, the electrode 551X was formed by a sputtering method using indium oxide-tin oxide containing silicon or silicon oxide (abbreviation: ITSO) as a target. Note that the electrode 551X contains ITSO and has a thickness of 70 nm and an area of 4 mm² (2 mm×2 mm).

Next, a workpiece over which the electrode was formed was washed with water, baked at 200° C. for an hour, and then subjected to UV ozone treatment for 370 seconds. After that, the workpiece was transferred into a vacuum evaporation apparatus where the inside pressure was reduced to approximately 10-4 Pa, and vacuum baking was performed at 170° C. for 30 minutes in a heating chamber of the vacuum evaporation apparatus. Then, the workpiece was cooled down for approximately 30 minutes.

### [Step 3]

In Step 3, the layer 104X was formed over the electrode 551X. Specifically, materials were co-deposited by a resistance-heating method. Note that the layer 104X contains N-(biphenyl-4-yl)-N-[4-(9-phenyl-9H-carbazol-3-yl)phenyl]-9,9-dimethyl-9H-fluoren-2-amine (abbreviation: PCBBiF) and an electron-accepting material (OCHD-003) at PCBBiF: OCHD-003=1:0.03 (weight ratio) and has a thickness of 10 nm.

### [Step 4]

In Step 4, the layer 112X was formed over the layer 104X. Specifically, a material was deposited by a resistance-heating method. Note that the layer 112X contains PCBBiF and has a thickness of 25 nm.

### [Step 5]

In Step 5, the layer 111X was formed over the layer 112X. Specifically, materials were co-deposited by a resistance-heating method. Note that the layer 111X contains 11-[(3′-dibenzothiophen-4-yl) biphenyl-3-yl]phenanthro[9′,10′: 4,5]furo[2,3-b]pyrazine (abbreviation: 11mDBtBPPnfpr), PCBBiF, and a phosphorescent dopant (OCPG-006) at 11mDBtBPPnfpr:PCBBiF:OCPG-006=0.7:0.3:0.05 (weight ratio) and has a thickness of 40 nm.

### [Step 6]

In Step 6, a layer 113X1 was formed over the layer 111X. Specifically, a material was deposited by a resistance-heating method. Note that the layer 113X1 contains 2-{3-[3-(N-phenyl-9H-carbazol-3-yl)-9H-carbazol-9-yl]phenyl}dibenzo[f,h]quinoxaline (abbreviation: 2mPCCzPDBq) and has a thickness of 20 nm.

### [Step 7]

In Step 7, a layer 113X2 was formed over the layer 113X1. Specifically, a material was deposited by a resistance-heating method. Note that the layer 113X2 contains 2,9-di(2-naphthyl)-4,7-diphenyl-1,10-phenanthroline (abbreviation: NBPhen) and has a thickness of 20 nm.

### [Step 8]

In Step 8, the layer 105X was formed over the layer 113X2. Specifically, materials were co-deposited by a resistance-heating method. Note that the layer 105X contains lithium fluoride (LiF) and ytterbium (Yb) at LiF:Yb=1:0.5 (weight ratio) and has a thickness of 1.5 nm.

### [Step 9]

In Step 9, the electrode 552X was formed over the layer 105X. Specifically, materials were co-deposited by a resistance-heating method. Note that the electrode 552X contains Ag and magnesium (Mg) at Ag:Mg=1:0.1 (volume ratio) and has a thickness of 25 nm.

### [Step 10]

In Step 10, a layer CAP was formed over the electrode 552X. Specifically, the layer CAP was formed by a sputtering method using indium oxide-tin oxide (abbreviation: ITO) as a target. Note that the layer CAP contains ITO and has a thickness of 70 nm.

### <<Operation Characteristics of Light-Emitting Device 1>>

When supplied with electric power, the light-emitting device 1 emitted light EL1 (see FIG. 36A). The operation characteristics of the light-emitting device 1 were measured at room temperature (see FIG. 37 to FIG. 41). Note that the luminance, the CIE chromaticity, and the emission spectrum were measured with a spectroradiometer (SR-ULIR, produced by TOPCON TECHNOHOUSE CORPORATION).

Table 3 shows the main initial characteristics of the fabricated light-emitting device emitting light at a luminance of approximately 1000 cd/m². Table 3 also shows the characteristics of the other light-emitting devices whose structures are described later.

TABLE 3

| | | | Current | | | Current | Light emission |
|---|---|---|---|---|---|---|---|
| | Voltage | Current | density | Chromaticity | Chromaticity | efficiency | start voltage |
| | (V) | (mA) | (mA/cm2) | x | y | (cd/A) | (V) |
| Light-emitting device 1 | 2.7 | 0.11 | 2.9 | 0.69 | 0.31 | 30.6 | 2.2 |
| Light-emitting device 2 | 3.0 | 0.06 | 1.5 | 0.26 | 0.70 | 74.3 | 2.3 |
| Light-emitting device 3 | 5.0 | 1.57 | 39.2 | 0.14 | 0.05 | 2.3 | 3.3 |

The light-emitting device 1 was found to have excellent characteristics. For example, the light-emitting device 1 emitted red light at a high current efficiency. For another example, the light-emitting device 1 was able to express red with higher color purity than red of the NTSC standard (chromaticity x=0.67 and chromaticity y=0.33) for televisions. For another example, the light-emitting device 1 was able to express red with higher color purity than red of the DCI-P3 standard (chromaticity x=0.68 and chromaticity y=0.31) for digital cinemas. These indicate that the light-emitting device is suitable for a display device with a wide color gamut.

The light-emitting device 550C or the light-emitting device 550D of the display device described in Example 1 is separated from its adjacent light-emitting devices. For example, light-emitting devices having a high current efficiency higher than or equal to 10 cd/A and lower than 100 cd/A can be provided with a gap larger than or equal to 0.1 μm and smaller than or equal to 15 μm therebetween. Specifically, the light-emitting device 1 can be used as the light-emitting device 550C or the light-emitting device 550D of the display device described in Example 1.

### <Light-Emitting Device 2>

The fabricated light-emitting device 2 described in this example has a structure similar to that of the light-emitting device 550X (see FIG. 36A). The light-emitting device 2 can be used as the light-emitting device 550C or the light-emitting device 550D of the display device described in Example 1.

Note that the light-emitting device 2 has a different emission color from the light-emitting device 1. The structure of the light-emitting device 2 is different from that of the light-emitting device 1 in the layer 112X, the layer 111X, the layer 113X1, and the layer 113X2.

Specifically, the light-emitting device 2 is different from the light-emitting device 1 in that the layer 112X has a thickness of 10 nm instead of a thickness of 25 nm; the layer 111X contains, instead of 11mDBtBPPnfpr, PCBBiF, and OCPG-006, 4,8-bis[3-(dibenzothiophen-4-yl)phenyl]-[1]benzofuro[3,2-d]pyrimidine (abbreviation: 4,8mDBtP2Bfpm), 9-(2-naphthyl)-9′-phenyl-9H,9′H-3,3′-bicarbazole (abbreviation: BNCCP), and [2-d3-methyl-(2-pyridinyl-κN)benzofuro[2,3-b]pyridine-κC]bis[2-(2-pyridinyl-κN)phenyl-κC]iridium (III) (abbreviation: Ir(ppy)₂ (mbfpypy-d3)); the layer 113X1 has a thickness of 10 nm instead of a thickness of 20 nm; and the layer 113X2 has a thickness of 15 nm instead of a thickness of 20 nm.

### <<Structure of Light-Emitting Device 2>>

Table 4 shows the structure of the light-emitting device 2. Structural formulae of materials used in the light-emitting device described in this example are shown below.

TABLE 4

| | | | Com- | Thick- |
|---|---|---|---|---|
| | Reference | | position | ness/ |
| Component | numeral | Material | ratio | nm |
| Layer | CAP | ITO | | 70 |
| Electrode | 552X | Ag:Mg | 1:0.1 | 25 |
| Layer | 105X | LiF:Yb | 1:0.5 | 1.5 |
| Layer | 113X2 | NBPhen | | 15 |
| Layer | 113X1 | 2mPCCzPDBq | | 10 |
| | | 4,8mDBtP2Bfpm: | 0.6: | |
| Layer | 111X | βNCCP: | 0.4: | 40 |
| | | Ir(ppy)2(mbfpypy-d3) | 0.1 | |
| Layer | 112X | PCBBiF | | 10 |
| Layer | 104X | PCBBiF:OCHD-003 | 1:0.03 | 10 |
| Electrode | 551X | ITSO | | 70 |
| Reflective film | REF3 | Ti | | 6 |
| Reflective film | REF2 | Al | | 70 |
| Reflective film | REF1 | Ti | | 50 |

### <<Method for Fabricating Light-Emitting Device 2>>

The light-emitting device 2 described in this example was fabricated by a method including the following steps.

The method for fabricating the light-emitting device 2 is different from the method for fabricating the light-emitting device 1 in Step 4, Step 5, Step 6, and Step 7. Different portions are described in detail here, and the above description is referred to for portions formed by a similar method.

### [Step 4]

In Step 4, the layer 112X was formed over the layer 104X. Specifically, a material was deposited by a resistance-heating method. Note that the layer 112X contains PCBBiF and has a thickness of 10 nm.

### [Step 5]

In Step 5, the layer 111X was formed over the layer 112X. Specifically, materials were co-deposited by a resistance-heating method. Note that the layer 111X contains 4,8mDBtP2Bfpm, βNCCP, and Ir(ppy)₂ (mbfpypy-d3) at 4,8mDBtP2Bfpm: βNCCP: Ir(ppy)₂ (mbfpypy-d3)=0.6:0.4:0.1 (weight ratio) and has a thickness of 40 nm.

### [Step 6]

In Step 6, the layer 113X1 was formed over the layer 111X. Specifically, a material was deposited by a resistance-heating method. Note that the layer 113X1 contains 2-{3-[3-(N-phenyl-9H-carbazol-3-yl)-9H-carbazol-9-yl]phenyl}dibenzo[f,h]quinoxaline (abbreviation: 2mPCCzPDBq) and has a thickness of 10 nm.

### [Step 7]

In Step 7, the layer 113X2 was formed over the layer 113X1. Specifically, a material was deposited by a resistance-heating method. Note that the layer 113X2 contains NBPhen and has a thickness of 15 nm.

### <<Operation Characteristics of Light-Emitting Device 2>>

When supplied with electric power, the light-emitting device 2 emitted the light EL1 (see FIG. 36A). The operation characteristics of the light-emitting device 2 were measured at room temperature (see FIG. 37 to FIG. 41).

The light-emitting device 2 was found to have excellent characteristics. For example, the light-emitting device 2 emitted green light at a high current efficiency. For another example, the light-emitting device 2 was able to express green with color purity comparable to green of the NTSC standard (chromaticity x=0.210 and chromaticity y=0.710) for televisions and green of the DCI-P3 standard (chromaticity x=0.265 and chromaticity y=0.690). These indicate that the light-emitting device is suitable for a display device with a wide color gamut.

The light-emitting device 550C or the light-emitting device 550D of the display device described in Example 1 is separated from its adjacent light-emitting devices. For example, light-emitting devices having a high current efficiency higher than or equal to 10 cd/A and lower than 100 cd/A can be provided with a gap larger than or equal to 0.1 μm and smaller than or equal to 15 μm therebetween. Specifically, the light-emitting device 2 can be used as the light-emitting device 550C or the light-emitting device 550D of the display device described in Example 1.

### <Light-Emitting Device 3>

The fabricated light-emitting device 3 described in this example has a structure similar to that of the light-emitting device 550X (see FIG. 36B). The light-emitting device 3 can be used as each of the light-emitting device 550A and the light-emitting device 550B of the display device described in Example 1.

Note that the light-emitting device 3 has a different emission color from the light-emitting device 1. The structure of the light-emitting device 3 is different from that of the light-emitting device 1 in a layer 112X1, a layer 112X2, the layer 111X, and the layer 113X2.

Specifically, the light-emitting device 3 is different from the light-emitting device 1 in that the layer 112X1 has a thickness of 96 nm instead of a thickness of 25 nm; the layer 112X2 is provided between the layer 112X1 and the layer 111X; the layer 111X has a thickness of 25 nm instead of a thickness of 40 nm and contains, instead of 11mDBtBPPnfpr, PCBBiF, and OCPG-006, 9-(1-naphthyl)-10-[4-(2-naphthyl)phenyl]anthracene (abbreviation: αN-βNPAnth) and 3,10-bis[N-(9-phenyl-9H-carbazol-2-yl)-N-phenylamino]naphtho[2,3-b; 6,7-b′]bisbenzofuran (abbreviation: 3,10PCA2Nbf (IV)-02); and the layer 113X2 has a thickness of 15 nm instead of a thickness of 20 nm.

### <<Structure of Light-Emitting Device 3>>

Table 5 shows the structure of the light-emitting device 3. Structural formulae of materials used in the light-emitting device described in this example are shown below.

TABLE 5

| | | | Com- | Thick |
|---|---|---|---|---|
| | Reference | | position | ness/ |
| Component | numeral | Material | ratio | nm |
| Layer CAP | | ITO | | 70 |
| Electrode | 552X | Ag:Mg | 1:0.1 | 25 |
| Layer | 105X | LiF:Yb | 1:0.5 | 1.5 |
| Layer | 113X2 | NBPhen | | 15 |
| Layer | 113X1 | 2mPCCzPDBq | | 20 |
| Layer | 111X | αN-βNP Anth: | 1:0.015 | 25 |
| | | 3,10PCA2Nbf(IV)-02 | | |
| Layer | 112X2 | DBfBB1TP | | 10 |
| Layer | 112X1 | PCBBiF | | 96 |
| Layer | 104X | PCBBiF:OCHD-003 | 1:0.03 | 10 |
| Electrode | 551X | ITSO | | 70 |
| Reflective film | REF3 | Ti | | 6 |
| Reflective film | REF2 | Al | | 70 |
| Reflective film | REF1 | Ti | | 50 |

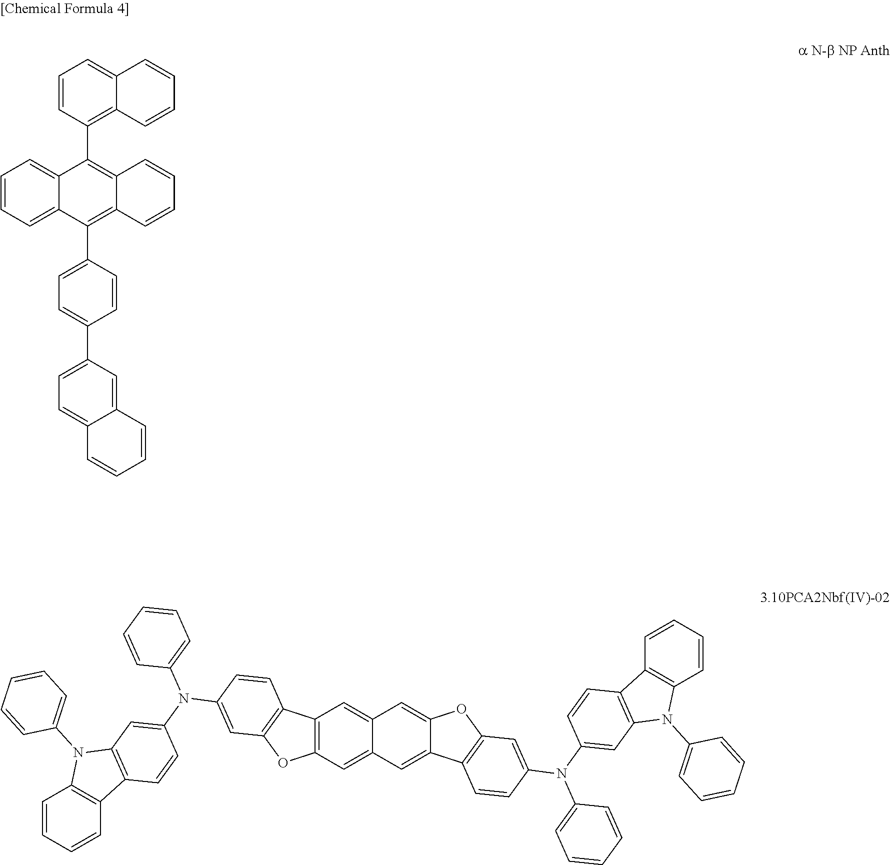

### <<Method for Fabricating Light-Emitting Device 3>>

The light-emitting device 3 described in this example was fabricated by a method including the following steps.

The method for fabricating the light-emitting device 2 is different from the method for fabricating the light-emitting device 1 in Step 4, Step 4-2, Step 5, and Step 7. Different portions are described in detail here, and the above description is referred to for portions formed by a similar method.

### [Step 4]

In Step 4, the layer 112X1 was formed over the layer 104X. Specifically, a material was deposited by a resistance-heating method. Note that the layer 112X1 contains PCBBiF and has a thickness of 96 nm.

### [Step 4-2]

In Step 4-2 followed by Step 4, the layer 112X2 was formed over the layer 112X1. Specifically, a material was deposited by a resistance-heating method. Note that the layer 112X2 contains N,N-bis[4-(dibenzofuran-4-yl)phenyl]-4-amino-p-terphenyl (abbreviation: DBfBB1TP) and has a thickness of 10 nm.

### [Step 5]

In Step 5 followed by Step 4-2, the layer 111X was formed over the layer 112X2. Specifically, materials were co-deposited by a resistance-heating method. Note that the layer 111X contains αN-βNPAnth and 3,10PCA2Nbf (IV)-02 at αN-βNPAnth: 3,10PCA2Nbf (IV)-02=1:0.015 (weight ratio) and has a thickness of 25 nm.

### [Step 6]

In Step 6, the layer 113X1 was formed over the layer 111X. Specifically, a material was deposited by a resistance-heating method. Note that the layer 113X1 contains 2mPCCzPDBq and has a thickness of 20 nm.

### <<Operation Characteristics of Light-Emitting Device 3>>

When supplied with electric power, the light-emitting device 3 emitted the light EL1 (see FIG. 36B). The operation characteristics of the light-emitting device 3 were measured at room temperature (see FIG. 37 to FIG. 41). Note that the luminance, the CIE chromaticity, and the emission spectrum were measured with a spectroradiometer (SR-ULIR, produced by TOPCON TECHNOHOUSE CORPORATION).

The light-emitting device 3 was found to have excellent characteristics. For example, the light-emitting device 3 emitted blue light. For another example, the light-emitting device 3 was able to express blue with higher color purity than blue of the NTSC standard (chromaticity x=0.140 and chromaticity y=0.08) for televisions. For another example, the light-emitting device 3 was able to express blue with higher color purity than blue of the DCI-P3 standard (chromaticity x=0.150 and chromaticity y=0.06) for digital cinemas. These indicate that the light-emitting device is suitable for a display device with a wide color gamut.

The light-emitting device 550B includes the layer continuous with the layer of the light-emitting device 550A in the display device described in Example 1. For example, light-emitting devices having a current efficiency higher than or equal to 1 cd/A and lower than 10 cd/A can be provided with a gap larger than or equal to 0.1 μm and smaller than or equal to 15 μm therebetween without separation of the light-emitting devices. Specifically, the light-emitting device 3 can be used as each of the light-emitting device 550A and the light-emitting device 550B of the display device described in Example 1.

### Example 3

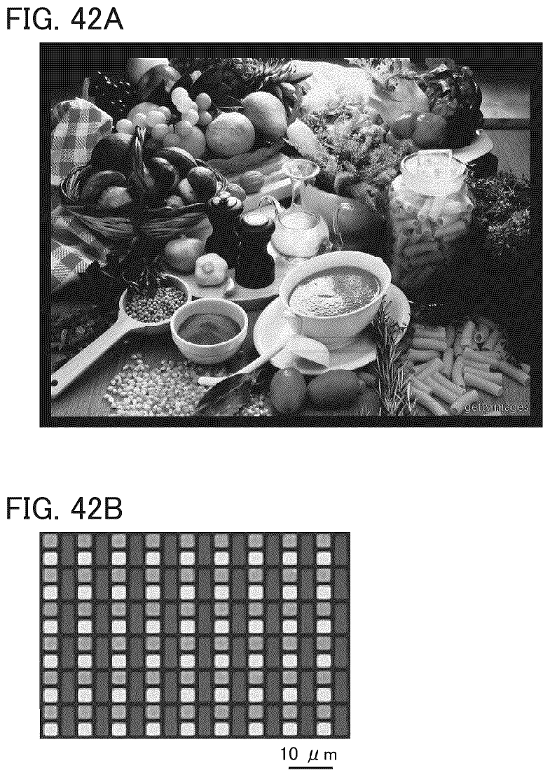

In this example, a display device of one embodiment of the present invention will be described with reference to FIG. 42 to FIG. 48.

FIG. 42A is a photograph showing a display state of a fabricated display device, and FIG. 42B is an optical micrograph of a pixel in a state of expressing white.

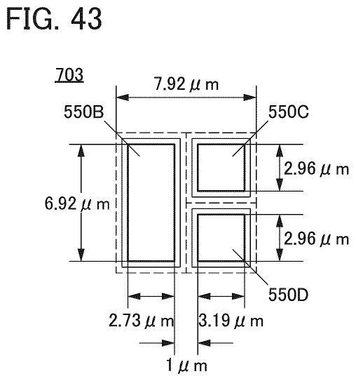

FIG. 43 is a top view illustrating a structure of a pixel of the fabricated display device.

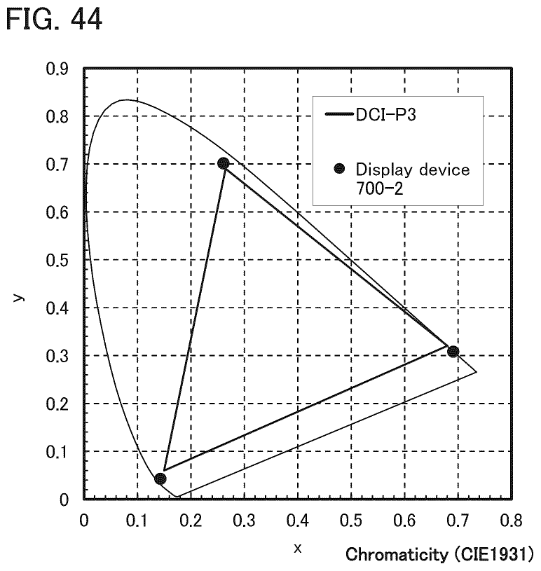

FIG. 44 is a graph showing a color gamut that can be expressed by the fabricated display device.

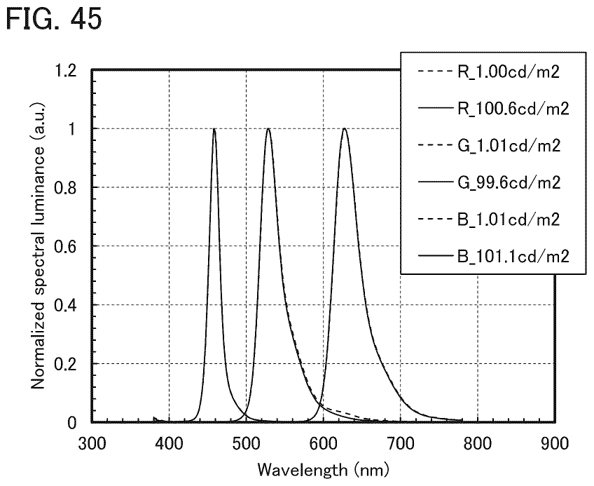

FIG. 45 is a graph showing emission spectra of the fabricated display device.

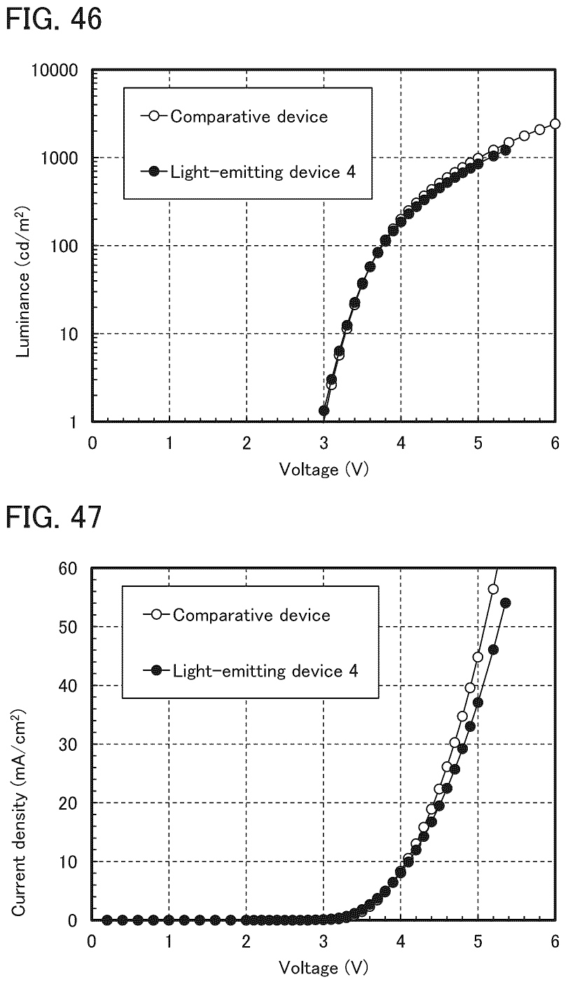

FIG. 46 is a graph showing the voltage-luminance characteristics of a blue-light-emitting device included in the fabricated display device.

FIG. 47 is a graph showing the voltage-current density characteristics of the blue-light-emitting device included in the fabricated display device.

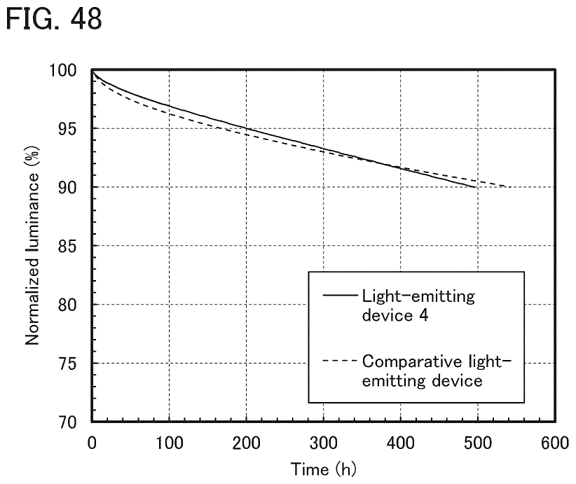

FIG. 48 is a graph showing normalized luminance changes over time of the blue-light-emitting devices emitting light at a constant current density (50 mA/cm²).

### <Display Device 700-2>

The specifications of the fabricated display device described in this example are shown below. An OS transistor using an oxide semiconductor was used in a pixel circuit.

FIG. 42A shows the photograph of the display device in the state of displaying an image. FIG. 42B shows the optical micrograph of the pixel in the state of expressing white.

TABLE 6

| | Specifications |
|---|---|
| Screen size | 1.50 inch |
| Panel size | 30.41 mm (H) × 22.81 mm (V) |
| Structure | OLED/OS |
| Pixel count | 3840 (H) × 2880 (V) |
| Pixel density | 3207 ppi |
| Pixel size | 7.92 μm (H) × 7.92 μm (V) |
| Pixel arrangement | RGB S-stripe |
| Aperture ratio | 61.0% |
| Coloring method | SBS (by a photolithography method) |
| Emission type | Top emission |
| Source driver | IC bonding |
| Gate driver | Integrated |

### <<Structure of Pixel>>

A display device 700-2 fabricated in this example includes the pixel set 703, and the pixel set 703 includes the light-emitting device 550A, the light-emitting device 550B, the light-emitting device 550C, and the light-emitting device 550D (see FIG. 43). Note that the blue-light-emitting device, the green-light-emitting device, and the red-light-emitting device are finely processed by a photolithography method to have a side-by-side (SBS) structure in which they are adjacent to each other. Each of the light-emitting devices includes a film that contains a light-emitting organic compound and is finely processed by a photolithography method.

<<Color Gamut that can be Expressed>>

Blue, green, and red were expressed by the display device 700-2 fabricated in this example to obtain chromaticity coordinates in the CIE1931 color space. The chromaticity coordinates of blue, green, and red are plotted on the chromaticity diagram to show the color gamut that can be expressed by the display device 700-2 (see FIG. 44).

With the use of the display device 700-2 fabricated in this example, the emission spectrum in a state where blue was expressed at a luminance of approximately 100 cd/m² and the emission spectrum in a state where blue was expressed at a luminance of approximately 1 cd/m² were compared (see FIG. 45). A spectrum having a peak at around 460 nm was observed. In the normalized spectral luminance obtained by normalizing the maximum luminance, the emission spectrum in the state where blue was expressed at a luminance of approximately 1 cd/m² (dashed line) agreed with the emission spectrum in the state where blue was expressed at a luminance of approximately 100 cd/m² (solid line).

Similarly, the emission spectrum in a state where green was expressed at a luminance of approximately 100 cd/m² and the emission spectrum in a state where green was expressed at a luminance of approximately 1 cd/m² were compared (see FIG. 45). A spectrum having a peak at around 530 nm was observed. In the normalized spectral luminance obtained by normalizing the maximum luminance, the emission spectrum in the state where green was expressed at a luminance of approximately 1 cd/m² (dashed line) substantially agreed with the emission spectrum in the state where green was expressed at a luminance of approximately 100 cd/m² (solid line).

Similarly, the emission spectrum in a state where red was expressed at a luminance of approximately 100 cd/m² and the emission spectrum in a state where red was expressed at a luminance of approximately 1 cd/m² were compared (see FIG. 45). A spectrum having a peak at around 630 nm was observed. In the normalized spectral luminance obtained by normalizing the maximum luminance, the emission spectrum in the state where red was expressed at a luminance of approximately 1 cd/m² (dashed line) agreed with the emission spectrum in the state where red was expressed at a luminance of approximately 100 cd/m² (solid line).

### <<Operation Characteristics of Light-Emitting Device 550B>>

The light-emitting device 550B exhibits blue light. A light-emitting device 4 having the same structure as the light-emitting device 550B was fabricated, and its operation characteristics were evaluated. The light-emitting devices 4 are arranged at a resolution of 3207 ppi (at a 7.92-μm pitch in the longitudinal direction and at a 7.92-μm pitch in the lateral direction), and the light-emitting devices 4 have an aperture ratio of 34.7%. As in the method for fabricating the display device 700-2, a film containing an organic compound was finely processed by a photolithography method to fabricate the light-emitting device 4.

A comparative device having the same structure as the light-emitting device 550B was also fabricated, and the operation characteristics were compared. Note that the comparative device is different from the light-emitting device 4 in that the size is 2 mm×2 mm, the aperture ratio is 100%, and the film containing a light-emitting organic compound is not processed by a photolithography method.

The operation characteristics of the light-emitting devices were measured at room temperature (see FIG. 46 and FIG. 47). Note that the luminance, the CIE chromaticity, and the emission spectra were measured with a spectroradiometer (SR-ULIR, produced by TOPCON TECHNOHOUSE CORPORATION).

The light-emitting devices were made to emit light at a constant current density (50 mA/cm²), and luminance changes over time were observed (see FIG. 48).

The light-emitting device 4 was found to have excellent characteristics. In addition, the light-emitting device 4 had characteristics comparable to those of the comparative device.

### REFERENCE NUMERALS

ANO: conductive film, C21: capacitor, C22: capacitor, CAP: layer, CP: conductive material, EMA: material, EMB: material, EMC: material, EMD: material, GD: driver circuit, M21: transistor, N21: node, N22: node, SD: driver circuit, SW21: switch, SW22: switch, SW23: switch, 14b: substrate, 16b: substrate, 17: substrate, 18: substrate, 37b: display portion, 61B: light-emitting device, 61G: light-emitting device, 61R: light-emitting device, 61W: light-emitting device, 63B: light-emitting device, 63G: light-emitting device, 63R: light-emitting device, 63W: light-emitting device, 71: substrate, 73: substrate, 83B: light, 83G: light, 83R: light, 100A: display device, 100B: display device, 100C: display device, 100D: display device, 100E: display device, 100F: display device, 100G: display device, 100H: display device, 100I: display device, 100J: display device, 100K: display device, 100L: display device, 100M: display device, 100: display device, 103X: unit, 104A: layer, 104B: layer, 104C: layer, 104D: layer, 104X: layer, 105A: layer, 105B: layer, 105C: layer, 105D: layer, 105X: layer, 105: layer, 106X: intermediate layer, 107: display portion, 111A: layer, 111B: layer, 111C: layer, 111D: layer, 111X: layer, 112A: layer, 112B: layer, 112BC: gap, 112C: layer, 112CD: gap, 112D: layer, 112X: layer, 113A: layer, 113B: layer, 113C: layer, 113D: layer, 113X: layer, 117: light-blocking layer, 120: substrate, 122: bonding layer, 140: connection portion, 142: bonding layer, 153: insulating layer, 156: bonding layer, 162: insulating layer, 164: circuit, 165: wiring, 166: conductive layer, 168: conductive layer, 171: conductive layer, 172B: EL layer, 172G: EL layer, 172R: EL layer, 173: conductive layer, 176: IC, 177: FPC, 183B: coloring layer, 183G: coloring layer, 183R: coloring layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 255: insulating layer, 256: plug, 261: insulating layer, 262: insulating layer, 263: insulating layer, 264: insulating layer, 265: insulating layer, 270B: sacrificial layer, 270G: sacrificial layer, 270R: sacrificial layer, 271: protective layer, 272: insulating layer, 273: protective layer, 274a: conductive layer, 274b: conductive layer, 274: plug, 275: plug, 278: insulating layer, 280: display module, 290: FPC, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: bonding layer, 510: substrate, 519B: terminal, 520: functional layer, 521: insulating film, 529_1: film, 529_2: film, 529_3: insulating film, 529_3A: opening portion, 529_3B: opening portion, 529_3C: opening portion, 529_3D: opening portion, 530B: pixel circuit, 530C: pixel circuit, 540: functional layer, 550A: light-emitting device, 550B: light-emitting device, 550C: light-emitting device, 550D: light-emitting device, 550X: light-emitting device, 551A: electrode, 551AB: gap, 551B: electrode, 551BC: gap, 551C: electrode, 551CD: gap, 551D: electrode, 551X: electrode, 552A: electrode, 552B: electrode, 552C: electrode, 552D: electrode, 552X: electrode, 552: conductive film, 591B: opening portion, 591C: opening portion, 700: display device, 702B: pixel, 702C: pixel, 702D: pixel, 703: pixel, 731: region, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 6700A: electronic device, 6700B: electronic device, 6721: housing, 6723: wearing portion, 6727: earphone portion, 6750: earphone, 6751: display panel, 6753: optical member, 6756: display region, 6757: frame, 6758: nose pad, 6800A: electronic device, 6800B: electronic device, 6820: display portion, 6821: housing, 6822: communication portion, 6823: wearing portion, 6824: control portion, 6825: image capturing portion, 6827: earphone portion, 6832: lens, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising:
a first light-emitting device comprising a first electrode, a second electrode, a first layer between the first electrode and the second electrode, and a second layer between the first electrode and the first layer;
a second light-emitting device comprising a third electrode adjacent to the first electrode, a fourth electrode, a third layer between the third electrode and the fourth electrode, and a fourth layer between the third electrode and the third layer;
a third light-emitting device comprising a fifth electrode adjacent to the third electrode, a sixth electrode, a fifth layer between the fifth electrode and the sixth electrode, and a sixth layer between the fifth electrode and the fifth layer; and
a fourth light-emitting device comprising a seventh electrode adjacent to the fifth electrode, an eighth electrode, a seventh layer between the seventh electrode and the eighth electrode, and an eighth layer between the seventh electrode and the seventh layer,
wherein the first layer, the third layer, the fifth layer, and the seventh layer comprise a first light-emitting material, a second light-emitting material, a third light-emitting material, and a fourth light-emitting material, respectively,
wherein a first gap is provided between the third electrode and the first electrode,
wherein the fourth layer is continuous with the second layer over the first gap,
wherein a second gap is provided between the fifth electrode and the third electrode,
wherein a third gap is provided between the sixth layer and the fourth layer,
wherein the third gap overlaps with the second gap,
wherein a fourth gap is provided between the seventh electrode and the fifth electrode,
wherein a fifth gap is provided between the eighth layer and the sixth layer, and
wherein the fifth gap overlaps with the fourth gap.

2. The display device according to claim 1,
wherein the first light-emitting device has a current efficiency higher than or equal to 1 cd/A and lower than 10 cd/A,
wherein the second light-emitting device has a current efficiency higher than or equal to 1 cd/A and lower than 10 cd/A,
wherein the third light-emitting device has a current efficiency higher than or equal to 10 cd/A and lower than 100 cd/A, and
wherein the fourth light-emitting device has a current efficiency higher than or equal to 10 cd/A and lower than 100 cd/A.

3. The display device according to claim 1,
wherein the first light-emitting device has a light emission start voltage in a range higher than or equal to 3 V and lower than 4 V,
wherein the second light-emitting device has a light emission start voltage in a range higher than or equal to 3 V and lower than 4 V,
wherein the third light-emitting device has a light emission start voltage in a range higher than or equal to 2 V and lower than 3 V, and
wherein the fourth light-emitting device has a light emission start voltage in a range higher than or equal to 2 V and lower than 3 V.

4. The display device according to claim 1,
wherein the first light-emitting material emits fluorescent light,
wherein the second light-emitting material emits fluorescent light,
wherein the third light-emitting material emits phosphorescent light, and
wherein the fourth light-emitting material emits phosphorescent light.

5. The display device according to claim 1,
wherein the first light-emitting material has an emission spectrum having a maximum peak in a range greater than or equal to 380 nm and less than or equal to 480 nm,
wherein the second light-emitting material has an emission spectrum having a maximum peak in a range greater than or equal to 380 nm and less than or equal to 480 nm,
wherein the third light-emitting material has an emission spectrum having a maximum peak in a range greater than or equal to 500 nm and less than or equal to 550 nm, and
wherein the fourth light-emitting material has an emission spectrum having a maximum peak in a range greater than or equal to 600 nm and less than or equal to 780 nm.

6. The display device according to claim 1, wherein the first gap, the second gap, and the fourth gap are each larger than or equal to 0.1 μm and smaller than or equal to 15 μm.

7. The display device according to claim 1, further comprising a first insulating film; a conductive film; and a second insulating film,
wherein the second electrode, the fourth electrode, and the sixth electrode are in a conductive film,
wherein the first electrode, the third electrode, and the fifth electrode are between the first insulating film and the conductive film,
wherein the second insulating film is between the conductive film and the first insulating film,
wherein the second insulating film overlaps with the first gap and the second gap and fills the third gap,
wherein the second insulating film comprises a first opening portion, a second opening portion, and a third opening portion,
wherein the first opening portion overlaps with the first electrode,
wherein the second opening portion overlaps with the third electrode, and
wherein the third opening portion overlaps with the fifth electrode.

8. A display module comprising:
the display device according to claim 1; and
at least one of a connector and an integrated circuit.

9. An electronic device comprising:
the display device according to claim 1; and
at least one of a battery, a camera, a speaker, and a microphone.

10. A display device comprising:
a first light-emitting device comprising a first electrode, a second electrode, a first layer between the first electrode and the second electrode, and a second layer between the first electrode and the first layer;
a second light-emitting device comprising a third electrode adjacent to the first electrode, a fourth electrode, a third layer between the third electrode and the fourth electrode, and a fourth layer between the third electrode and the third layer; and
a third light-emitting device comprising a fifth electrode adjacent to the third electrode, a sixth electrode, a fifth layer between the fifth electrode and the sixth electrode, and a sixth layer between the fifth electrode and the fifth layer,
wherein the first layer, the third layer, and the fifth layer comprise a first light-emitting material, a second light-emitting material, and a third light-emitting material, respectively,
wherein a first gap is provided between the third electrode and the first electrode,
wherein the fourth layer is continuous with the second layer over the first gap,
wherein a second gap is provided between the fifth electrode and the third electrode,
wherein a third gap is provided between the sixth layer and the fourth layer, and
wherein the third gap overlaps with the second gap.

11. The display device according to claim 10,
wherein the first gap and the second gap are each larger than or equal to 0.1 μm and smaller than or equal to 15 μm.

12. The display device according to claim 10, further comprising a first insulating film and a second insulating film,
wherein the second electrode, the fourth electrode, and the sixth electrode are in a conductive film,
wherein the first electrode, the third electrode, and the fifth electrode are between the first insulating film and the conductive film,
wherein the second insulating film is between the conductive film and the first insulating film,
wherein the second insulating film overlaps with the first gap and the second gap and fills the third gap,
wherein the second insulating film comprises a first opening portion, a second opening portion, and a third opening portion,
wherein the first opening portion overlaps with the first electrode,
wherein the second opening portion overlaps with the third electrode, and
wherein the third opening portion overlaps with the fifth electrode.

13. A display module comprising:
the display device according to claim 10; and
at least one of a connector and an integrated circuit.

14. An electronic device comprising:
the display device according to claim 10; and
at least one of a battery, a camera, a speaker, and a microphone.
